(19) United States
(12) Patent Application Publication
(10) Pub. No.: US 2014/0016404 A1
(43) Pub. Date: Jan. 16, 2014

(54) MAGNETIC RANDOM ACCESS MEMORY

(71) Applicants: Chan-kyung Kim, Hwaseong-si (KR); Soo-ho Cha, Seoul (KR); Dong-seok Kang, Seoul (KR); Chul-woo Park, Yongin-si (KR); Dong-hyun Sohn, Hwaseong-si (KR); Yun-sang Lee, Yongin-si (KR); Hye-jin Kim, Seoul (KR)

(72) Inventors: Chan-kyung Kim, Hwaseong-si (KR); Soo-ho Cha, Seoul (KR); Dong-seok Kang, Seoul (KR); Chul-woo Park, Yongin-si (KR); Dong-hyun Sohn, Hwaseong-si (KR); Yun-sang Lee, Yongin-si (KR); Hye-jin Kim, Seoul (KR)

(21) Appl. No.: 13/937,236

(22) Filed: Jul. 9, 2013

(30) Foreign Application Priority Data
Jul. 11, 2012 (KR) 10-2012-0075744

(51) Int. Cl. G11C 11/16

(52) U.S. Cl. CPC G11C 11/165
USPC 365/158

(57) ABSTRACT

A magnetic memory device such as a magnetic random access memory (MRAM), and a memory module and a memory system on which the magnetic memory device is mounted are disclosed. The MRAM includes magnetic memory cells each of which varies between at least two states according to a magnetization direction and an interface unit that provides various interface functions. The memory module includes a module board and at least one MRAM chip mounted on the module board, and further includes a buffer chip that manages an operation of the at least one MRAM chip. The memory system includes the MRAM and a memory controller that communicates with the MRAM, and may communicate an electric-to-optical conversion signal or an optical-to-electric conversion signal by using an optical link that is connected between the MRAM and the memory controller.

### CROSS-REFERENCE TO RELATED APPLICATIONS

This application claims the benefit of priority to Korean Patent Application No. 10-2012-0075744, filed on Jul. 11, 2012, in the Korean Intellectual Property Office, the disclosure of which is incorporated herein in its entirety by reference.

### BACKGROUND

This disclosure relates to a semiconductor memory device, and more particularly, to an interface technology of a magnetic memory device, such as a magnetic random access memory (MRAM), including a nonvolatile magnetic layer.

Semiconductor products are developing to have smaller sizes and process more data. Accordingly, there is a demand to increase an operating speed and an integration degree of memory devices used in semiconductor products. To meet this demand, MRAMs that operate based on a change in resistance as a polarity of a magnetic body changes have been suggested.

MRAMs are used by being integrated into various electronic devices. Some of these electronic devices may be existing or legacy systems. In order to receive various external signals and apply internal data signals to the outside, MRAMs may need various interface functions.

### SUMMARY

The disclosed embodiments provide a magnetic random access memory (MRAM) that supports various interface functions, and a memory module and a memory system on which the MRAM is mounted.

According to an aspect of the inventive concept, there is provided a magnetic random access memory (MRAM) including: magnetic memory cells each of which varies between at least two states according to a magnetization direction; and an interface circuit that inputs/outputs as a data input/output signal (referred to as a DQ signal) data read from or written to the magnetic memory cell in accordance with a rising edge and a falling edge of a clock signal.

The interface circuit may be set to input/output the DQ signal in accordance with a rising edge in one cycle of the clock signal.

The interface circuit may be set to input/output the DQ signal in accordance with a rising edge and a falling edge of the clock signal.

The MRAM may further include a clock generator that generates a first internal clock signal having the same phase as that of the clock signal, a second internal clock signal whose phase is delayed by 90 degrees from that of the clock signal, a third internal clock signal that is obtained by inverting the first internal clock signal, and a fourth internal clock signal that is obtained by inverting the second internal clock signal. The interface circuit may be set to input/output the DQ signal in accordance with rising edges of the first through fourth internal clock signals.

The MRAM may further include a clock generator that generates a first internal clock signal whose frequency is two times that of the clock signal, a second internal clock signal whose phase is delayed by 90 degrees from that of the first internal clock signal, a third internal clock signal that is obtained by inverting the first internal clock signal, and a fourth internal clock signal that is obtained by inverting the second internal clock signal. The interface circuit may be set to input/output the DQ signal in accordance with rising edges of the first through fourth internal clock signals.

The interface circuit may be set to input/output a command packet, a write data packet, or a read data packet which is synchronized with the rising and falling edges of the clock signal as the DQ signal.

The interface circuit may be set to latch the DQ signal in response to a data strobe signal that is generated along with the DQ signal, generate a clock synchronization signal satisfying a skew specification between the clock signal and the data strobe signal, and generate an edge of the clock signal in a window center of the latched DQ signal.

The interface circuit may be set to sample the DQ signal by using a differential data clock signal whose frequency is two times a frequency of the clock signal that samples a command and an address signal.

The interface circuit may support single-ended signaling that compares a voltage level of the DQ signal received through one channel with a reference voltage. The channel may support pseudo open drain (POD) interface that is pull-up terminated.

The interface circuit may support differential-ended signaling that inputs the DQ signal and an inverted DQ signal received through two channels. Each of the two channels may support POD interface that is pull-up terminated.

The two channels may be connected to each other through a resistor and support low voltage differential signaling (LVDS), and the DQ signal and the inverted DQ signal may have small swings.

The interface circuit may receive the DQ signal through one channel, and the channel may support a multi-level signaling interface that converts a voltage corresponding to a plurality of bits of the DQ signal into a multi-level voltage signal.

The interface circuit may receive a voltage corresponding to a plurality of bits of the DQ signal to a multi-level voltage signal pair through two channels that support multi-level signaling interface.

According to another aspect of the disclosed embodiments, there is provided a magnetic random access memory (MRAM) including: magnetic memory cells each of which varies between at least two states according to a magnetization direction; a delay-locked loop (DLL) that receives an external clock signal that synchronizes an operation of the MRAM, delays by a predetermined period of time the external clock signal by using delay elements, and generates an internal clock signal that is synchronized with the external clock signal; and a data input/output buffer (referred to as a DQ buffer) that latches data read from or written to the magnetic memory cell in response to the internal clock signal.

The DLL may operate such that the external clock signal is prevented from being received when the MRAM is in a power down mode.

The DLL may generate a first internal clock signal whose frequency is the same as that of the external clock signal and generate a second internal clock signal whose frequency is two times that of the external clock signal, wherein the first internal clock signal is used to clock the DQ buffer and the second internal clock signal is used to clock the data read from or written to the magnetic memory cell.

The DLL may further include phase delay detectors that respectively receive a plurality of delayed clock signals output from the delay elements in response to the external clock signal, wherein each of the phase delay detectors compares a phase of each of the delayed clock signals with a phase of a carry output terminal of the phase delay detector at a front end and outputs a comparison result to the carry output terminal of the corresponding phase delay detector, wherein when a phase of the external clock signal and the phase of the delayed clock signal are matched to each other, the phase delay detector outputs the delayed clock signal as the internal clock signal and disables the carry output terminal.

The DLL may include: a phase detector that compares a phase of the external clock signal with a phase of a feedback clock signal; a charge pump that generates a voltage control signal in response to a comparison result of the phase detector; a loop filter that generates the voltage control signal by integrating a phase difference; the delay elements each of which inputs the external clock signal and outputs the internal clock signal in response to the voltage control signal; and a compensation delay circuit that inputs the internal clock signal, and outputs the feedback clock signal by compensating for a load on a line path through which the read data is transmitted.

According to another embodiment, there is provided a magnetic random access memory (MRAM) including: magnetic memory cells each of which varies between at least two states according to a magnetization direction; a data bus inverter that minimizes bit switching between data words read from or written to the magnetic memory cell; and a data input/output pad (referred to as a DQ pad) that transmits the data words to a data bus.

The data bus inverter may perform the bit switching in order to minimize a number of logic low bits in a data pattern of the data words.

The data bus inverter may perform the bit switching in order to minimize a change from a previous data pattern of the data words.

According to another embodiment, there is provided a magnetic random access memory (MRAM) including: magnetic memory cells each of which varies between at least two states according to a magnetization direction; a data driver that transmits/receives data read from or written to the magnetic memory cell to a data input/output terminal (referred to as a DQ terminal) through an external data bus; and an on-die termination circuit that controls a termination resistance of the DQ terminal in order to achieve impedance matching with the external data bus.

The MRAM may further include: a calibration terminal (referred to as a ZQ terminal) to which an external resistor is connected; and calibration resistors that are connected to the ZQ terminal, wherein the on-die termination circuit controls the terminal resistance of the DQ terminal in response to calibration codes when a resistance value of each of the calibration resistors is the same as a resistance value of the external resistor.

### BRIEF DESCRIPTION OF THE DRAWINGS

Exemplary embodiments will be more clearly understood from the following detailed description taken in conjunction with the accompanying drawings in which:

FIG. 1 is a block diagram illustrating a semiconductor memory system including a magnetic random access memory (MRAM), according to an exemplary embodiment;

FIG. 2 is a block diagram illustrating the MRAM according to an exemplary embodiment;

FIG. 3 is a block diagram illustrating an exemplary memory cell array in a memory bank of FIG. 2, according to one exemplary embodiment;

FIG. 4 is a stereogram illustrating an exemplary spin transfer torque (STT)-MRAM cell of FIG. 3, according to one exemplary embodiment;

FIGS. 5A and 5B are block diagrams for explaining a magnetization direction according to data written to a magnetic tunnel junction (MTJ), for example, of FIG. 4;

FIG. 6 is a block diagram for explaining a write operation of the STT-MRAM cell, for example, of FIG. 4;

FIGS. 7A and 7B are block diagrams illustrating exemplary MTJs in the STT-MRAM cell of FIG. 4, according to certain embodiments;

FIG. 8 is a block diagram illustrating an exemplary MTJ in the STT-MRAM cell of FIG. 4, according to another embodiment;

FIGS. 9A and 9B are block diagrams illustrating exemplary dual MTJs in the STT-MRAM cell of FIG. 4, according to other embodiments;

FIG. 10 is a block diagram illustrating an exemplary clock generator of the MRAM, according to one embodiment;

FIG. 11 is a diagram illustrating exemplary operation waveforms of the clock generator of FIG. 10, according to one embodiment;

FIG. 12 is a diagram for explaining a protocol for packets in the MRAM, according to an exemplary embodiment;

FIG. 13 is a block diagram for explaining source synchronous interface of the MRAM, according to an exemplary embodiment;

FIG. 14 is a timing diagram for explaining an exemplary operation on a data input path of FIG. 13, according to one embodiment;

FIGS. 15 through 17 are diagrams for explaining an exemplary tDQSS timing margin on the data input path of FIG. 13, according to one embodiment;

FIG. 18 is a block diagram illustrating a semiconductor memory system including an MRAM, according to an exemplary embodiment;

FIG. 19 is a diagram for explaining the MRAM interface of FIG. 18, according to one exemplary embodiment;

FIG. 20 is a block diagram illustrating an exemplary semiconductor memory system including an MRAM, according to another embodiment;

FIG. 21 is a block diagram illustrating an exemplary semiconductor memory system including an MRAM, according to another embodiment;

FIG. 22 is a block diagram illustrating an exemplary semiconductor memory system including an MRAM, according to another embodiment;

FIG. 23 is a block diagram illustrating an exemplary semiconductor memory system including an MRAM, according to another embodiment;

FIGS. 24 and 25 are tables for explaining operations of multi-level converters of FIG. 23, according to exemplary embodiments;

FIG. 26 is a diagram illustrating a voltage level of a multi-level voltage signal according to a data signal in the multi-level single-ended signaling interface of FIG. 23, according to one exemplary embodiment;

FIG. 27 is a block diagram illustrating an exemplary semiconductor memory system including an MRAM, according to another embodiment;

FIG. 28 is a diagram illustrating a voltage level of a multi-level voltage signal according to a data signal in the multi-level differential-ended signaling interface of FIG. 27, according to one exemplary embodiment;

FIG. 29 is a block diagram illustrating an exemplary semiconductor memory system including an MRAM, according to another embodiment;

FIG. 30 is a circuit diagram illustrating an exemplary output driver of FIG. 29;

FIG. 31 is a circuit diagram illustrating an exemplary input driver of FIG. 29;

FIG. 32 is a block diagram illustrating an exemplary semiconductor memory system including an MRAM, according to another embodiment;

FIGS. 33 through 35 are block diagrams illustrating exemplary semiconductor memory systems including MRAMs, according to other embodiments;

FIG. 36 is a block diagram illustrating an exemplary system including an MRAM, according to one embodiment;

FIG. 37 is a block diagram illustrating a delay-locked loop (DLL) included in an MRAM, according to an exemplary embodiment;

FIG. 38 is a circuit diagram illustrating a DLL included in an MRAM, according to another exemplary embodiment;

FIG. 39 is a circuit diagram illustrating a control signal generator that generates a standby signal of FIG. 38, according to one exemplary embodiment;

FIG. 40 is a diagram illustrating a mode register that applies a signal MRSET of FIG. 39, according to one exemplary embodiment;

FIG. 41 is a block diagram illustrating an exemplary DLL included in an MRAM, according to another embodiment;

FIG. 42 is a block diagram illustrating an exemplary phase-locked loop (PLL) included in an MRAM, according to one embodiment;

FIG. 43 is a timing diagram for explaining an operation of the MRAM of FIG. 42, according to one exemplary embodiment;

FIG. 44 is a circuit diagram illustrating an exemplary DLL included in an MRAM, according to another embodiment;

FIG. 45 is a diagram for explaining an operation of the DLL of FIG. 44, according to one exemplary embodiment;

FIG. 46 is a circuit diagram illustrating an exemplary DLL included in an MRAM, according to another embodiment;

FIG. 47 is a timing diagram for explaining an operation of the DLL of FIG. 46, according to one exemplary embodiment;

FIG. 48 is a circuit diagram illustrating an exemplary DLL included in an MRAM, according to another embodiment;

FIG. 49 is a circuit diagram illustrating delay elements in an analog delay line of FIG. 48, according to one exemplary embodiment;

FIG. 50 is a block diagram illustrating an exemplary MRAM according to another embodiment;

FIGS. 51 and 52 are diagrams for explaining an operation of a read/write circuit of FIG. 50, according to one exemplary embodiment;

FIGS. 53 and 54 are diagrams illustrating a mode register included in a control logic unit of FIG. 50, according to one exemplary embodiment;

FIG. 55 is a block diagram illustrating an exemplary MRAM according to another embodiment;

FIG. 56 is a block diagram illustrating a memory system including MRAMs, according to an embodiment of the inventive concept;

FIG. 57 is a block diagram illustrating an exemplary memory system including MRAMs, according to another embodiment;

FIG. 58 is a diagram illustrating a mode register included in a control logic unit of FIG. 57, according to one exemplary embodiment;

FIG. 59 is a timing diagram for explaining dynamic termination of FIG. 57, according to one exemplary embodiment;

FIGS. 60 and 61 are diagrams illustrating a termination control unit of FIG. 57, according to one exemplary embodiment;

FIG. 62 is a circuit diagram illustrating an exemplary MRAM according to another embodiment;

FIGS. 63 through 69 views and diagrams for explaining an MRAM package, MRAM pin structures, and MRAM modules, according to exemplary embodiments;

FIG. 70 is a perspective view illustrating a semiconductor device having a stacked structure including MRAM semiconductor layers, according to an exemplary embodiment;

FIG. 71 is a block diagram illustrating an exemplary memory system including an MRAM, according to another embodiment;

FIG. 72 is a block diagram illustrating an exemplary data processing system including MRAMs, according to one embodiment;

FIG. 73 is a block diagram illustrating an exemplary server system on which an MRAM is mounted, according to one embodiment; and

FIG. 74 is a block diagram illustrating an exemplary computer system on which an MRAM is mounted, according to one embodiment.

### DETAILED DESCRIPTION OF THE EMBODIMENTS

As used herein, the term “and/or” includes any and all combinations of one or more of the associated listed items. Expressions such as “at least one of,” when preceding a list of elements, modify the entire list of elements and do not modify the individual elements of the list.

The attached drawings for illustrating exemplary embodiments of the inventive concept are referred to in order to gain a sufficient understanding of the inventive concept, the merits thereof, and the objectives accomplished by the implementation of the inventive concept.

As the inventive concept allows for various changes and numerous embodiments, particular embodiments will be illustrated in the drawings and described in detail in the written description. However, this is not intended to limit the inventive concept to particular modes of practice, and it is to be appreciated that all changes, equivalents, and substitutes that do not depart from the spirit and technical scope of the inventive concept are encompassed in the inventive concept. In the drawings, similar elements are denoted by similar reference numerals. In the drawings, sizes of structures are exaggerated for clarity.

The terms used in the present specification are merely used to describe particular embodiments, and are not intended to limit the inventive concept. As used herein, the singular forms “a,” “an” and “the” are intended to include the plural forms as well, unless the context clearly indicates otherwise. It will be further understood that the terms “comprises” and/or “comprising,” or “includes” and/or “including,” used herein specify the presence of stated features, integers, steps, operations, members, components, and/or groups thereof, but do not preclude the presence or addition of one or more other features, integers, steps, operations, members, components, and/or groups thereof.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. Unless indicated otherwise, these terms are only used to distinguish one element from another. For example, a first chip could be termed a second chip, and, similarly, a second chip could be termed a first chip without departing from the teachings of the disclosure.

Embodiments described herein will be described referring to plan views, perspective views, and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures have schematic properties, and shapes of regions shown in figures exemplify specific shapes of regions of elements, and the specific properties and shapes do not limit aspects of the invention.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

All terms including technical and scientific terms used herein have meanings which can be generally understood by those of ordinary skill in the art, if the terms are not particularly defined. General terms defined by dictionaries should be understood to have meanings which can be contextually understood in the art and should not have ideally or excessively formal meanings, if the terms are not defined particularly herein.

A magnetic random access memory (MRAM) is a nonvolatile computer memory based on magnetoresistance. An MRAM is different from a volatile RAM in many aspects. Since an MRAM is nonvolatile, the MR.AM may retain all stored data even when power is turned off.

Although a nonvolatile RAM is generally slower than a volatile RAM, an MRAM has read and write response times comparable with read and write response times of a volatile RAM. Unlike a conventional RAM that stores data as electric charge, an MRAM stores data by using magnetoresistance elements. In general, a magnetoresistance element is made of two magnetic layers each having magnetization.

An MRAM is a nonvolatile memory device that reads and writes data by using a magnetic tunnel junction pattern including two magnetic layers and an insulating film disposed between the two magnetic layers. A resistance value of the magnetic tunnel junction pattern may vary according to a magnetization direction of each of the magnetic layers. The MRAM may program or remove data by using the variation of the resistance value.

An MRAM using a spin transfer torque (STT) phenomenon uses a method in which when a spin-polarized current flows in one direction, a magnetization direction of the magnetic layer is changed due to the spin transfer of electrons. A magnetization direction of one magnetic layer (pinned layer) may be fixed and a magnetization direction of the other magnetic layer (free layer) may vary according to a magnetic field generated by a program current.

The magnetic field of the program current may arrange the magnetization directions of the two magnetic layers in parallel or anti-parallel. In one embodiment, if the magnetization directions of the two magnetic layers are parallel, a resistance between the two magnetic layers is in a low (“0”) state. If the magnetization directions of the two magnetic layers are anti-parallel, a resistance between the two magnetic layers is in a high (“1”) state. Switching of the magnetization direction of the free layer and the high or low state of the resistance between the two magnetic layers result in write and read operations of the MRAM.

Although the MRAM is nonvolatile and provides a quick response time, an MRAM cell has a limited scale and is sensitive to write disturbance. The program current applied to switch the high and low states of the resistance between the magnetic layers of the MRAM is typically high. Accordingly, when a plurality of cells are arranged in an MRAM array, a program current applied to one memory cell changes a magnetic field of a free layer of an adjacent cell. Such a write disturbance may be prevented by using an STT phenomenon.

A typical STT-MRAM may include a magnetic tunnel junction (MTJ), which is a magnetoresistive data storage device including two magnetic layers (a pinned layer and a free layer) and an insulating layer disposed between the two magnetic layers.

A program current typically flows through the MTJ. The pinned layer spin-polarizes electrons of the program current, and a torque is generated as the spin-polarized electron current passes through the MTJ. The spin-polarized electron current applies the torque to the free layer while interacting with the free layer.

When the torque of the spin-polarized electron current passing through the MTJ is greater than a threshold switching current density, the torque applied by the spin-polarized electron current is sufficient to switch a magnetization direction of the free layer. Accordingly, the magnetization direction of the free layer may be parallel or anti-parallel to the pinned layer, and a resistance state in the MTJ is changed.

The STT-MRAM removes a requirement of an external magnetic field for the spin-polarized electron current to switch the free layer in the magnetoresistive device. In addition, the STT-MRAM improves scaling as a cell size is reduced and the program current is reduced, and prevents the write disturbance. In addition, the STT-MRAM may have a high tunnel magnetoresistance ratio, and improves a read operation in a magnetic domain by allowing a high ratio between the high and low states.

An MRAM is an all-round memory device that is low cost and has high capacity (like a dynamic random access memory (DRAM), operates at high speed (like a static random access memory (SRAM), and is nonvolatile (like a flash memory).

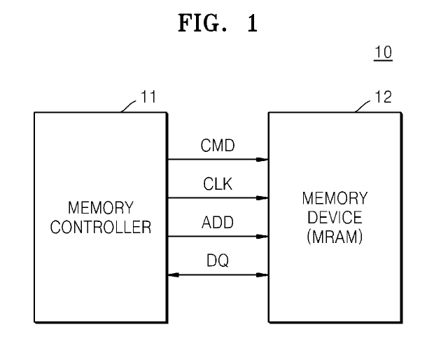

FIG. 1 is a block diagram illustrating a semiconductor memory system 10 including an MRAM, according to one exemplary embodiment.

Referring to FIG. 1, the semiconductor memory system 10 includes a memory controller 11 and a memory device 12. The memory controller 11 applies various signals for controlling the memory device 12, for example, a command signal CMD, a clock signal CLK, and an address signal ADD. Also, the memory controller 11 communicates with the memory device 12 to apply a data signal DQ to the memory device 12 or receive the data signal DQ from the memory device 12.

The memory device 12 may include a cell array in which a plurality of memory cells, for example, MRAM cells, are arranged. For convenience of explanation, the memory device 12 is referred to as an MRAM. A DRAM interface that observes a DRAM protocol may exist between the memory controller 11 and the MRAM 12.

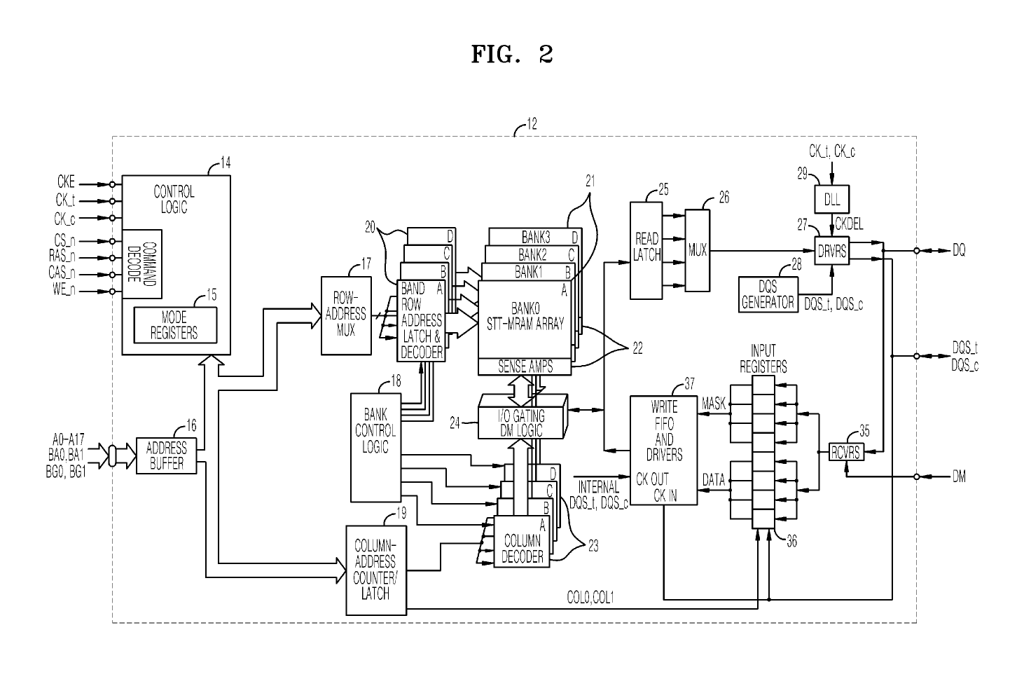

FIG. 2 is a block diagram illustrating the MRAM 12 according to an exemplary embodiment.

Referring to FIG. 2, the MRAM 12 is a double data rate device that operates in synchronization with a rising edge/falling edge of a clock signal CK. The MRAM 12 supports various data rates according to an operation frequency of the clock signal CK. For example, in one embodiment, when the operation frequency of the clock signal CK is 800 MHz, the MRAM 12 supports a 1600 MT/s data rate. In certain embodiments, the MRAM 12 may support 1600, 1867, 2133, and 2400 MT/s data rates.

The MRAM 12 includes a control logic and command decoder 14 that receives a plurality of command signals and clock signals from an external device such as the memory controller 11, via a control bus. The command signals include, for example, a chip select signal CS_n, a write enable signal WE_n, a column address strobe (CAS) signal CAS_n, and a row address strobe signal RAS_n. The clock signals include a clock enable signal CKE and complementary clock signals CK_t and CK_c. Here, _n denotes an active low signal and _t and _c denote a signal pair. The command signals CS_n, WE_n CAS_n, and RAS_n may be driven by a logic value corresponding to a specific command such as a read command or a write command.

The control logic and command decoder 14 includes a mode register 15 that provides a plurality of operation options of the MRAM 12. The mode register 15 may program various functions, characteristics, and modes of the MRAM 12. For example, the mode register 15 may control a burst length, a read burst type, CAS latency (CL), a test mode, delay-locked loop (DLL) reset, write recovery and read command-to-precharge command features, and DLL use during precharge power down. The mode register 15 may store data for controlling DLL enable/disable, output drive intensity, additive latency (AL), write leveling enable/disable, termination data strobe (TDQS) enable/disable, and output buffer enable/disable. The mode register 15 may store data for controlling CAS write latency (CWL), dynamic termination, and write cyclic redundancy check (CRC).

The mode register 15 may store data for controlling a multi purpose register (MPR) location function, an MRP operation function, a gear down mode, a per MRAM addressing mode, and an MPR read format. The mode register 15 may store data for controlling a power down mode, reference voltage (Vref) monitoring, a CS-to-command/address latency mode, a read preamble training mode, a read preamble function, and a write preamble function. The mode register 15 may store data for controlling a command and address (C/A) parity function, a CRC error state, a C/A parity error state, an on-die termination (ODT) input buffer power down function, a data mask (DM) function, a write data bus inversion (DBI) function, and a read DBI function. In one embodiment, the mode register 15 stores data for controlling a VrefDQ training value, a VrefDQ training range, VrefDQ training enable, and tCCD timing that means a CAS_n to CAS_n command delay.

The control logic and command decoder 14 latches and decodes a command applied in response to the clock signals CK_t and CK_c. The control logic and command decoder 14 generates a sequence of clock and control signals by using internal blocks for performing a function of an applied command.

The MRAM 12 further includes an address buffer 16 that receives row, column, and bank addresses A0 through A17, BA0, and BA1 and bank group addresses BG0 and BG1 from the memory controller 11 (see FIG. 1) via an address bus. The address buffer 16 receives a row address, a bank address, and a bank group address applied to a row address multiplexer 17 and a bank control logic unit 18.

The row address multiplexer 17 applies the row address received from the address buffer 16 to a plurality of address latch and decoders 20A through 20D. The bank control logic unit 18 activates the address latch and decoders 20A through 20D corresponding to a bank group signal BG1:BG0 and a bank group signal BA1:BA0 received from the address buffer 16.

In order to activate rows of memory cells corresponding to decoded row addresses, the activated address latch and decoders 20A through 20D apply various signals to corresponding memory banks 21A through 21D (collectively denoted by 21). Each of the memory banks 21A through 21D includes a memory cell array including a plurality of memory cells. Data stored in the memory cells of the activated rows is detected and amplified by sense amplifiers 22A through 22D.

A column address is applied to an address bus after row and bank addresses are applied. The address buffer 16 applies the column address to a column address counter and latch 19. The column address counter and latch 19 latches the column address and applies the latched column address to a plurality of column decoders 23A through 23D. The bank control logic unit 18 activates the column decoders 23A through 23D corresponding to the received bank address and bank group address, and the activated column decoders 23A through 23D decode the column address.

According to an operation mode of the MRAM 12, the column address counter and latch 19 may directly apply the latched column address to the column decoders 23A through 23D, or apply a column address sequence starting with the column address applied by the address buffer 16 to the column decoders 23A through 23D. The column decoders 23A through 23D, which are activated in response to the column address from the column address counter and latch 19, apply decode and control signals to an input/output (I/O) gating and DM logic unit 24. The I/O gating and DM logic unit 24 accesses memory cells corresponding to the decoded column address from among the rows of memory cells activated in the accessed memory banks 21A through 21D.

According to a read command of the MRAM 12, data is read from the addressed memory cells and is transmitted to a read latch 25 through the I/O gating and DM logic unit 24. The I/O gating and DM logic unit 24 transmits N bit data to the read latch 25, and the read latch 25 transmits, for example, 4 N/4 bits, to a multiplexer 26.

The MRAM 12 may have an N prefetch architecture in each memory access. For example, the MRAM 12 may have a 4n prefetch architecture that retrieves 4 pieces of n-bit data. Alternatively, the MRAM 12 may have an 8n prefetch architecture. If the MRAM 12 has a 4n prefetch architecture and an x4 data width, the I/O gating and DM logic unit 24 transmits 16 bits to the read latch 25, and transmits 4 pieces of 4-bit data to the multiplexer 26.

A data driver 27 sequentially receives N/4-bit data from the multiplexer 26. Also, the data driver 27 receives data strobe signals DQS_t and DQS_s from a strobe signal generator 28, and receives a delayed clock signal CKDEL from a DLL 29. A data strobe (DQS) signal is used by an external device such as the memory controller 11 (see FIG. 1) for synchronized reception of read data during a read operation. The DLL 29 generates clock signals CK_t and CK_c and the data strobe signal DQS and/or the clock signal CKDEL delayed by being synchronized with a DQ signal.

In response to the delayed clock signal CKDEL, the data driver 27 sequentially outputs received data to a data terminal DQ according to a corresponding data word. Each data word is output to one data bus by being synchronized with rising and falling edges of the applied clock signals CK_t and CK_c. A first data word is output at a time according to CL programmed after a read command. Also, the data driver 27 outputs the data strobe signals DQS_t and DQS_c having rising and falling edges synchronized with the rising and falling edges of the clock signals CK_t and CK_c.

During a write operation of the MRAM 12, the external device such as the memory controller 11 (see FIG. 1) applies, for example, N/4-bit data words, to the data terminal DQ and applies a data strobe signal DQS and a corresponding DM signal to the data bus. A data receiver 35 receives each data word and a related DM signal, and applies the signals to input registers 36 that are clocked to the data strobe signal DQS.

The input registers 36 latch a first N/4-bit data word and a related DM signal in response to a rising edge of the data strobe signal DQS, and latch a second N/4-bit data word and a related DM signal in response to a falling edge of the data strobe signal DQS. The input registers 36 apply 4 latched N/4-bit data words and related DM signals to a write first in first out (FIFO) and driver 37 in response to the data strobe signal DQS. The write FIFO and driver 37 receives an N-bit data word.

The data word is clocked out in the write FIFO and driver 37 and is applied to the I/O gating and DM logic unit 24. The I/O gating and DM logic unit 24 transmits the data word to memory cells addressed in the memory banks 21A through 21D upon receiving the DM signal. The DM signal selectively masks predetermined bits or a predetermined bit group from among data words to be written to the addressed memory cells.

In the MRAM 12, the data driver 27, the DLL 29, and the data receiver 35 may constitute an interface circuit, also referred to herein as an interface unit IF that supports various interface functions with external devices connected to the MRAM 12. The interface unit IF includes circuitry that is configured to perform certain functionality. For example, the interface unit IF may support single data rate (SDR), double data rate (DDR), quad data rate (QDR), or octal data rate (ODR) interface, packet protocol interface, source synchronous interface, single-ended signaling interface, differential-ended signaling interface, pseudo open drain (POD) interface, multi-level single-ended signaling interface, multi-level differential-ended signaling interface, low voltage differential signaling (LVDS) interface, bidirectional interface, and center tap termination (CTT) interface. The interface unit IF may provide a write DBI function and a read DBI function in order to minimize bit switching between data words. The interface unit IF may provide an ODT function for impedance matching and may control a termination resistance by using a ZQ calibration operation. Although certain examples are given with regard to exemplary interface units IFs described herein, this description is not intended to limit the interface unit IF to these specific examples.

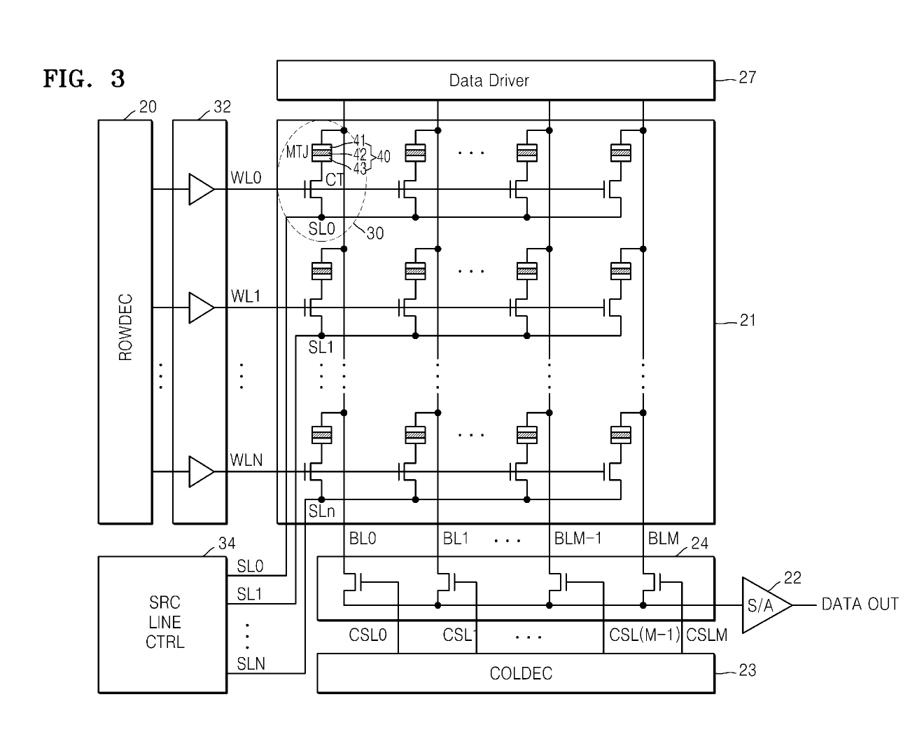

FIG. 3 is a block diagram illustrating a memory cell array in the memory bank 21 of FIG. 2, according to one exemplary embodiment.

Referring to FIG. 3, the memory bank 21 includes a plurality of word lines WL0 through WLN (where N is a natural number equal to or greater than 1), a plurality of bit lines BL0 through BLM (where M is a natural number equal to or greater than 1), a plurality of source lines SL0 through SLN (where N is a natural number equal to or greater than 1), and a plurality of memory cells 30 disposed at intersections between the word lines WL0 through WLN and the bit lines BL0 through BLM. Each of the memory cells 30 may be an STT-MRAM cell. The memory cell 30 may include an MTJ 40 having a magnetic material.

Each of the memory cells 30 may include a cell transistor CT and the MTJ 40. In one memory cell 30, a drain of the cell transistor CT is connected to a pinned layer 43 of the MTJ 40. A free layer 41 of the MTJ 40 is connected to the bit line BL0, and a source of the cell transistor CT is connected to the source line SL0. A gate of the cell transistor CT is connected to the word line WL0.

The MTJ 40 may be replaced by a resistive device such as a phase change random access memory (PRAM) using a phase change material, a resistive random access memory (RRAM) using a variable resistive material such as a complex metal oxide, or a magnetic random access memory (MRAM) using a ferromagnetic material. Materials forming the resistive devices have resistance values that vary according to a size and/or a direction of a current or a voltage, and are nonvolatile and thus may maintain the resistance values even when the current or the voltage is cut off.

The word line WL0 is enabled by a row decoder 20, and is connected to a word line driver 32 that drives a word line select voltage. The word line select voltage activates the word line WL0 in order to read or write a logic state of the MTJ 40.

The source line SL0 is connected to a source line circuit 34. The source line circuit 34 receives and decodes an address signal and a read/write signal, and generates a source line select signal in the selected source line SL0. A ground reference voltage is supplied to the unselected source lines SL1 through SLN.

The bit line BL0 is connected to a column select circuit 24 that is driven by column select signals CSL0 through CSLM. The column select signals CSL0 through CSLM are selected by a column decoder 23. For example, the selected column select signal CSL0 turns on a column select transistor in the column select circuit 24, and selects the bit line BL0. A logic state of the MTJ 40 is read from the bit line BL0 through a sense amplifier 22. Alternatively, a write current applied through the data driver 27 is transmitted to the selected bit line BL0 and is written to the MTJ 40.

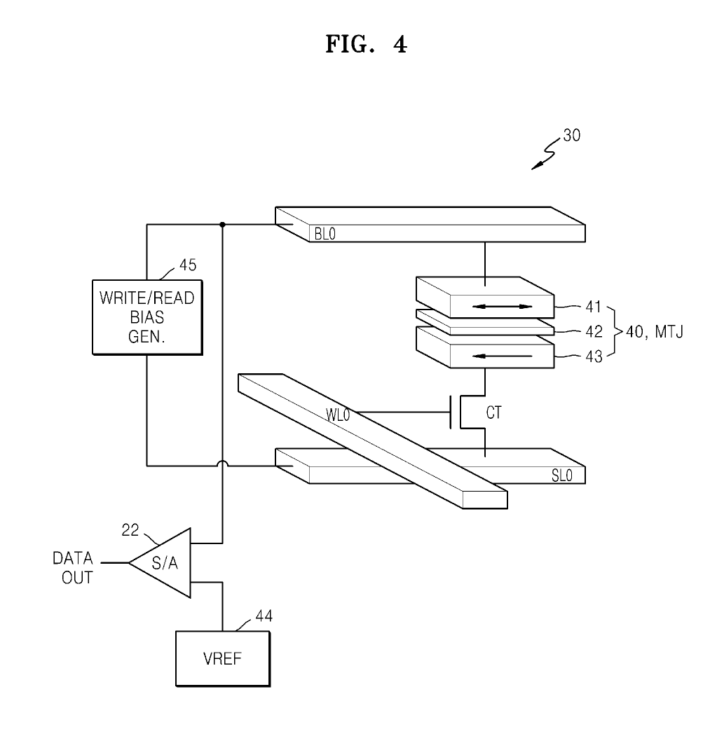

FIG. 4 is a stereogram illustrating the memory cell 30 (referred to as STT-MRAM cell) of FIG. 3, according to one exemplary embodiment.

Referring to FIG. 4, the STT-MRAM cell 30 may include the MTJ 40 and the cell transistor CT. A gate of the cell transistor CT is connected to a word line (for example, the word line WL0), and one electrode of the cell transistor CT is connected through the MTJ 40 to a bit line (for example, the bit line BL0). Also, the other electrode of the cell transistor CT is connected to a source line (for example, the source line SL0).

The MTJ 40 may include the free layer 41, the pinned layer 43, and a tunnel layer 42 disposed between the free layer 41 and the pinned layer 43. A magnetization direction of the pinned layer 43 may be fixed, and a magnetization direction of the free layer 41 may be parallel to or anti-parallel to the magnetization direction of the pinned layer 43 according to written data. In order to fix the magnetization direction of the pinned layer 43, for example, an anti-ferromagnetic layer (not shown) may be further provided.

In order to perform a write operation of the STT-MRAM cell 30, a logic high voltage is applied to the word line WL0 to turn on the cell transistor CT. A program current, that is, a write current, supplied by a write/read bias generator 42 is applied to the bit line BL0 and the source line SL0. A direction of the write current is determined by a logic state of the MTJ 40.

In order to perform a read operation of the STT-MRAM cell 30, a logic high voltage is applied to the word line WL0 to turn on the cell transistor CT, and a read current is supplied to the bit line BL0 and the source line SL0. Accordingly, a voltage is developed at both ends of the MTJ 40, is detected by the sense amplifier 22, and is compared with a reference voltage from a reference voltage generator 44 to determine a logic state of the MTJ 40. Accordingly, data stored in the MTJ 40 may be detected.

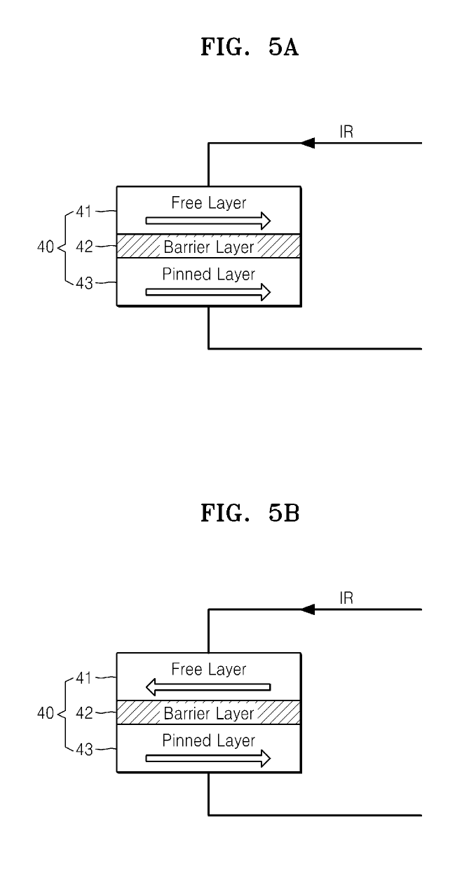

FIGS. 5A and 5B are block diagrams for explaining a magnetization direction according to data written to the MTJ 40 of FIG. 4. A resistance value of the MTJ 40 varies according to a magnetization direction of the free layer 41. When a read current IR flows through the MTJ 40, a data voltage is output according to the resistance value of the MTJ 40. Since the read current IR is much smaller than a write current, a magnetization direction of the free layer 41 is not changed by the read current IR.

Referring to FIG. 5A, a magnetization direction of the free layer 41 and a magnetization direction of the pinned layer 43 of the MTJ 40 are parallel. Accordingly, the MTJ 40 has a high resistance value. In this case, the MTJ 40 may read “0”.

Referring to FIG. 5B, a magnetization direction of the free layer 41 and a magnetization direction of the pinned layer 43 of the MTJ 40 are anti-parallel. Accordingly, the MTJ 40 has a high resistance value. In this case, the MTJ 40 may read “1”.

Although the free layer 41 and the pinned layer 43 of the MTJ 40 are horizontal magnetic layers, the present embodiment is not limited thereto and the free layer 41 and the pinned layer 43 may be, for example, vertical magnetic layers.

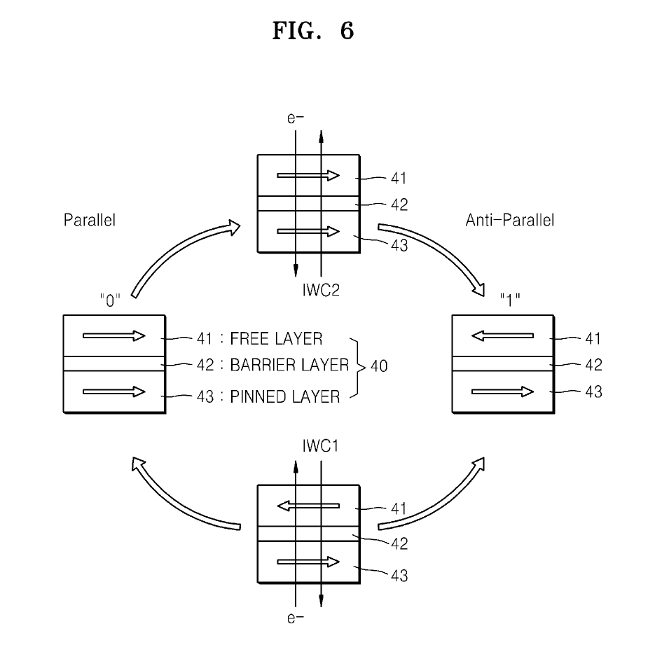

FIG. 6 is a block diagram for explaining a write operation of the STT-MRAM cell 30 of FIG. 4, according to one exemplary embodiment.

Referring to FIG. 6, a magnetization direction of the free layer 41 may be determined based on a direction of a write current IW flowing through the MTJ 40. For example, when a first write current IWC1 is supplied from the free layer 41 to the pinned layer 43, free electrons having the same spin direction as that of the pinned layer 43 apply a torque to the free layer 41. Accordingly, the free layer 41 is magnetized parallel to the pinned layer 43.

When a second write current IWC2 is applied from the pinned layer 43 to the free layer 41, electrons having a spin direction opposite to that of the pinned layer 41 return to the free layer 43 and apply a torque. Accordingly, the free layer 41 is magnetized anti-parallel to the pinned layer 43. That is, a magnetization direction of the free layer 41 of the MTJ 40 may be changed by an STT.

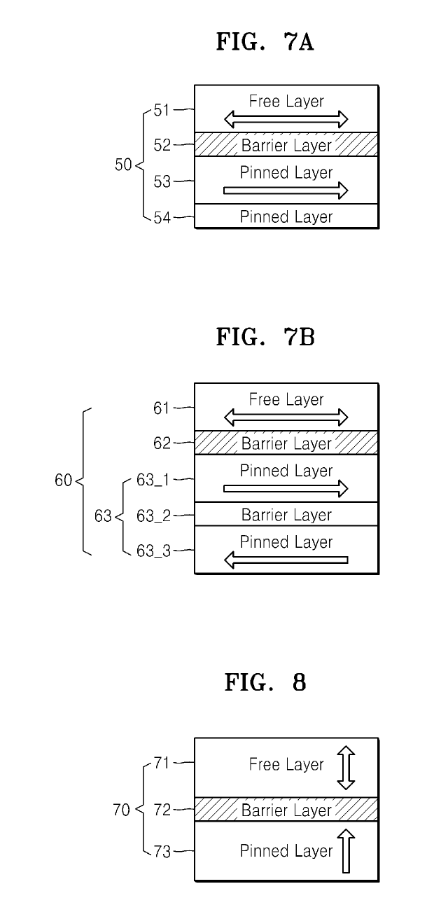

FIGS. 7A and 7B are block diagrams illustrating MTJs 50 and 60 in the STT-MRAM cell 30 of FIG. 4, according to exemplary embodiments.

Referring to FIG. 7A, the MTJ 50 may include a free layer 51, a tunnel layer 52, a pinned layer 53, and an anti-ferromagnetic layer 54. The free layer 51 may include a material having a variable magnetization direction. A magnetization direction of the free layer 51 may vary according to electrical/magnetic factors provided outside and/or inside of a memory cell. The free layer 51 may include a ferromagnetic material including, for example, at least one of cobalt (Co), iron (Fe), and nickel (Ni). For example, the free layer 51 may include at least one selected from the group consisting of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂.

The tunnel layer 52, also referred to as a barrier layer 52, may have a thickness less than a spin diffusion distance. The tunnel layer 52 may include a non-magnetic material. For example, the tunnel layer 52 may include at least one selected from the group consisting of magnesium (Mg), titanium (Ti), aluminum (Al), a magnesium-zinc (MgZn) oxide, a magnesium-boron (MgB) oxide, a Ti nitride, and a vanadium (V) nitride.

The pinned layer 53 may have a magnetization direction fixed by the anti-ferromagnetic layer 54. Also, the pinned layer 53 may include a ferromagnetic material. For example, the pinned layer 53 may include at least one selected from the group consisting of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂.

The anti-ferromagnetic layer 54 may include an anti-ferromagnetic material. For example, the anti-ferromagnetic layer 54 may include at least one selected from the group consisting of PtMn, IrMn, MnO, MnS, MnTe, MnF₂, FeCl₂, FeO, CoCl₂, CoO, NiCl₂, NiO, and Cr.

Since each of the free layer 51 and the pinned layer 53 of the MTJ 50 is formed of a ferromagnetic material, a stray field may be generated at an edge of the ferromagnetic material. The stray field may reduce magnetoresistance or increase resistive magnetism of the free layer 51. In addition, the stray field may affect switching characteristics, thereby resulting in asymmetric switching. Accordingly, a structure for reducing or controlling a stray field generated at the ferromagnetic material in the MTJ 50 may be used.

Referring to FIG. 7B, a pinned layer 63 of the MTJ 60 may be formed of a synthetic anti-ferromagnetic (SAF) material. The pinned layer 63 may include a first ferromagnetic layer 63_1, a coupling layer 63_2, and a second ferromagnetic layer 63_3. Each of the first and second ferromagnetic layers 63_1 and 63_3 may include at least one selected from the group consisting of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂. In this case, a magnetization direction of the first ferromagnetic layer 63_1 and a magnetization direction of the second ferromagnetic layer 63_3 are different from each other, and are fixed. The coupling layer 63_2 may include ruthenium (Ru), for example.

FIG. 8 is a block diagram illustrating an MTJ 70 in the STT-MRAM cell 30 of FIG. 4, according to another exemplary embodiment.

Referring to FIG. 8, a magnetization direction of the MTJ 70 is vertical and a moving direction of a current and a magnetization easy-axis are substantially parallel to each other. The MTJ 70 includes a free layer 71, a tunnel layer 72, and a pinned layer 73. A resistance value is small when a magnetization direction of the free layer 71 and a magnetization direction of the pinned layer 73 are parallel to each other, and, is large when a magnetization direction of the free layer 71 and a magnetization direction of the pinned layer 73 are anti-parallel to each other. Data may be stored in the MTJ 70 according to the resistance value.

In order to realize the MTJ 70 having a vertical magnetization direction, each of the free layer 71 and the pinned layer 73 may be formed of a material having high magnetic anisotropy energy. Examples of the material having high magnetic anisotropy energy include an amorphous rare earth element alloy, a multi-layer thin film such as (Co/Pt)n or (Fe/Pt)n, and an ordered lattice material having an L10 crystal structure. For example, the free layer 71 may be formed of an ordered alloy, and may include at least one selected from the group consisting of Fe, Co, Ni, palladium (Pa), and platinum (Pt). Alternatively, the free layer 71 may include at least one selected from the group consisting of a Fe—Pt alloy, a Fe—Pd alloy, a Co—Pd alloy, a Co—Pt alloy, a Fe—Ni—Pt alloy, a Co—Fe—Pt alloy, and a Co—Ni—Pt alloy. Such alloys may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀ in terms of quantitative chemistry.

The pinned layer 73 may be formed of an ordered alloy, and may include at least one selected from the group consisting of Fe, Co, Ni, Pa, and Pt. For example, the pinned layer 73 may include at least one selected from the group consisting of a Fe—Pt alloy, a Fe—Pd alloy, a Co—Pd alloy, a Co—Pt alloy, a Fe—Ni—Pt alloy, a Co—Fe—Pt alloy, and a Co—Ni—Pt alloy. Such alloys may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀ in terms of quantitative chemistry.

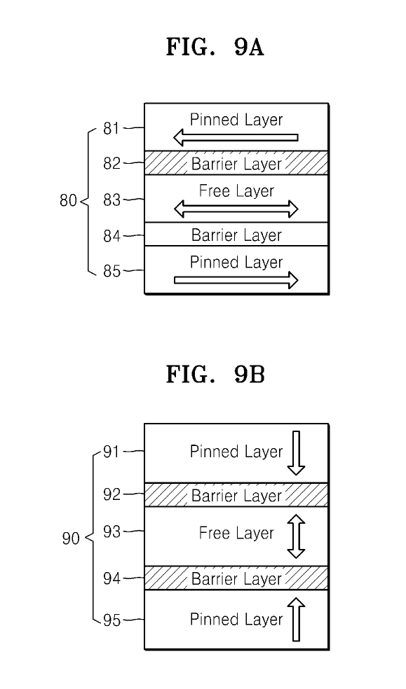

FIGS. 9A and 9B are block diagrams illustrating dual MTJs 80 and 90 in the STT-MRAM cell 30 of FIG. 4, according to other exemplary embodiments. A dual MTJ is configured such that a tunnel layer and a pinned layer are disposed at both ends of a free layer.

Referring to FIG. 9A, the dual MTJ 80 having a horizontal magnetization direction may include a first pinned layer 81, a first tunnel layer 82, a free layer 83, a second tunnel layer 84, and a second pinned layer 85. Materials of the first and second pinned layers 81 and 85 are similar to that of the pinned material 53 of FIG. 7A, materials of the first and second tunnel layers 82 and 84 are similar to that of the tunnel layer 52 of FIG. 7A, and a material of the free layer 83 is similar to that of the free layer 51 of FIG. 7A.

When a magnetization direction of the first pinned layer 81 and a magnetization direction of the second pinned layer 85 are fixed to opposite directions, magnetic forces by the first and second pinned layers 81 and 85 substantially counterbalance. Accordingly, the dual MTJ 80 may perform a write operation by using a smaller current than a general MTJ.

Since the dual MTJ 80 provides a higher resistance during a read operation due to the second tunnel layer 84, an accurate data value may be obtained.

Referring to FIG. 9B, the dual MTJ 90 having a vertical magnetization direction includes a first pinned layer 91, a first tunnel layer 92, a free layer 93, a second tunnel layer 94, and a second pinned layer 95. Materials of the first and second pinned layers 91 and 95 are similar to that of the pinned layer 73 of FIG. 8, materials of the first and second tunnel layers 92 and 94 are similar to that of the tunnel layer 72 of FIG. 8, and a material of the free layer 93 is similar to that of the free layer 71 of FIG. 8.

In this case, when a magnetization direction of the first pinned layer 91 and a magnetization direction of the second pinned layer 95 are fixed to opposite directions, magnetic forces by the first and second pinned layers 91 and 95 substantially counterbalance. Accordingly, the dual MTJ 90 may perform a write operation by using a smaller current than a general MTJ.

The MRAM 12 of FIG. 2 includes the mode register 15 that may program various functions, characteristics, and modes for application flexibility. The mode register 15 may be programmed by a mode register set (MRS) command, and by user defined variables. The mode register 15 generates a corresponding mode signal MRS according to a programmed operation mode.

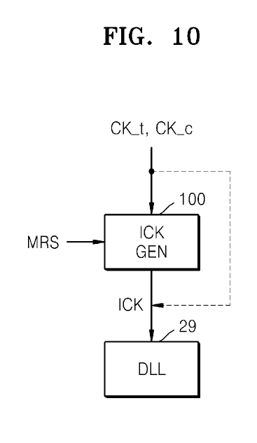

FIG. 10 is a block diagram illustrating a clock generator of the MRAM 12, according to one exemplary embodiment.

Referring to FIG. 10, the clock generator 100 is included in the MRAM 12 of FIG. 2. The clock generator 100 generates clock signals CK_t and CK_c, and generates an internal clock signal ICK in response to the mode signal MRS. The internal clock signal ICK is applied to the DLL 29, and the DLL 29 may generate a delayed clock signal CKDEL by synchronizing the internal clock signal ICK with a data strobe signal DQS and/or a DQ signal. Alternatively, the DLL 29 may generate the clock signal CKDEL delayed by synchronizing the clock signals CK_t and CK_c and the data strobe signal DQS and/or the DQ signal.

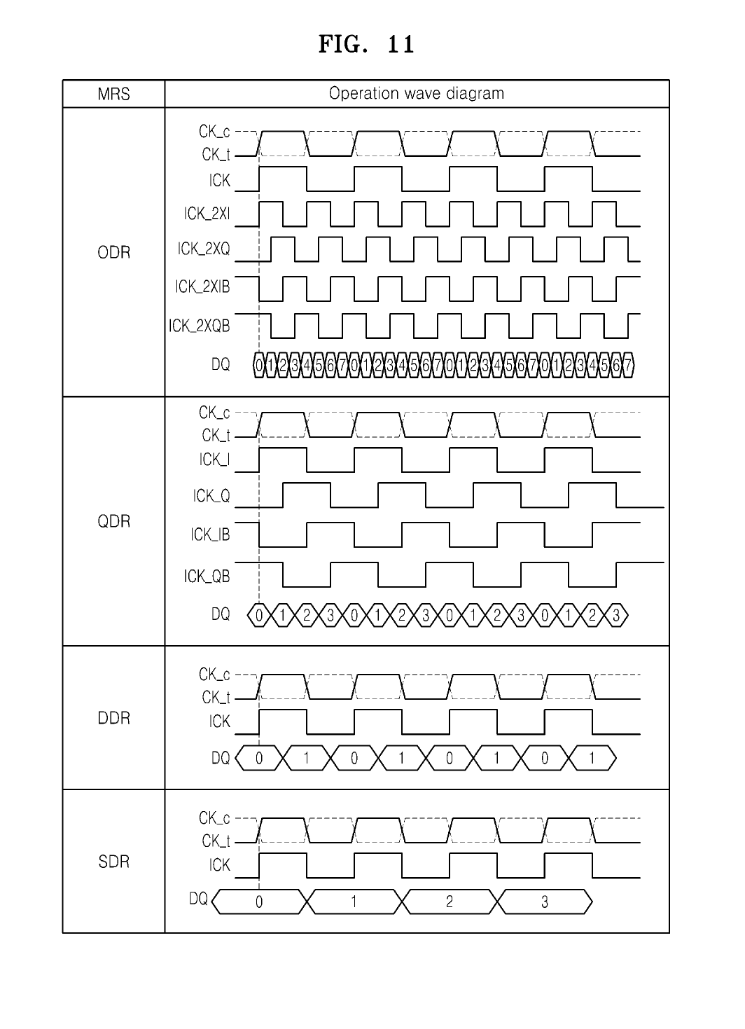

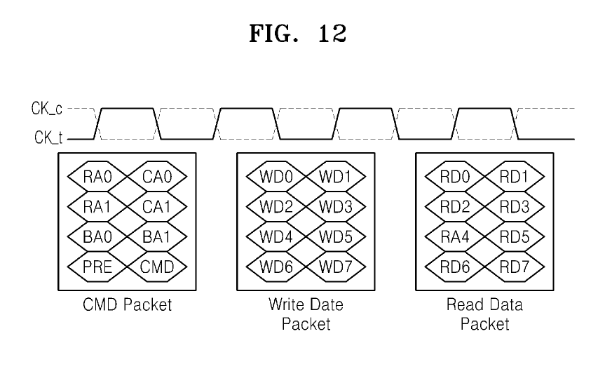

The clock generator 100 may generate operation waveforms of the internal clock signal ICK, as shown in FIG. 11, in response to various mode signals MRS. FIG. 11 illustrates examples of the internal clock signal ICK according to an SDR mode signal, a DDR mode signal, a QDR mode signal, or an ODR mode signal.

The same internal clock signal ICK as the clock signal CK_t is generated in response to the SDR mode signal. One DQ signal is input/output in accordance with a rising edge in one cycle of the clock signal CK_t.

The same internal clock signal ICK as the clock signal CK_t is generated in response to the DDR mode signal. The DQ signal is input/output in accordance with a rising edge and a falling edge of the internal clock signal ICK. Accordingly, two DQ signals are input/output in one cycle of the clock signal CK_t. As shown in FIG. 11, in one embodiment, the rising and falling edges of the clock signal CK_t occur in a window center of the latched DQ signal.

A first internal clock signal ICK_I having the same phase as that of the clock signal CK_t and a second internal clock signal ICK_Q whose phase is delayed by 90 degrees from that of the clock signal CK_t are generated in response to the QDR mode signal. A third internal clock signal ICK_IB obtained by inverting the first internal clock signal ICK_I and a fourth internal clock signal ICK_QB obtained by inverting the second internal clock signal ICK_Q are generated. A DQ signal is input/output in accordance with rising edges of the first through fourth internal clock signals ICK_I, ICK_Q, ICK_IB, and ICK_QB. Accordingly, 4 DQ signals are input/output in one cycle of the clock signal CK_t. As shown in FIG. 11, in one embodiment, edges of the different clock signals ICK_I, ICK_Q, ICK_IB, and ICK_QB each occur in a window center of the latched DQ signal.

A first internal clock signal ICK_{—}2XI whose frequency is two times a frequency of the clock signal CK_t and a second internal clock signal ICK_{—}2XQ whose phase is delayed by 90 degrees from that of the first internal clock signal ICK_{—}2XI are generated in response to the ODR mode signal. A third internal clock signal ICK_{—}2XIB obtained by inverting the first internal clock signal ICK_{—}2XI and a fourth internal clock signal ICK_{—}2XQB obtained by inverting the second internal clock signal ICK_{—}2XQ are generated. A DQ signal is input/output in accordance with rising edges of the first through fourth internal clock signals ICK_I, ICK_Q, ICK_IB, and ICK_QB. Accordingly, 8 DQ signals are input/output in one cycle of the clock signal CK_t. As shown in FIG. 11, in one embodiment, edges of the different clock signals ICK_{—}2XI, ICK_{—}2XQ, ICK 2XIB, and ICK 2XQB each occur in a window center of the latched DQ signal.

The MRAM 12 (see FIG. 2) is a device that transmits or receives a digital signal via a bus according to a request of the memory controller 11 (see FIG. 1). FIG. 11 is a diagram for explaining bit transmission of the MRAM 12. Although the type of bit transmission used is important, accurate and efficient transmission of data is also important. It may be more efficient to transmit a data unit having a predetermined size (hereinafter, referred to as a “packet”) than a signal having a bit unit. Accordingly, an MRAM interface using a packet transmission method may be used.

FIG. 12 is a diagram for explaining a protocol for packets in the MRAM 12, according to an exemplary embodiment.

Referring to FIG. 12, a command packet, a write data packet, and a read data packet are synchronized with rising/falling edges of clock signals CK_t and CK_c. The command packet performs a precharge operation in a bank and/or a memory cell array according to a precharge command PRE and a specific command CMD, and indicates which operation is to be performed. Pieces of write data WD0 through WD7 of the write data packet are written to a bank and/or memory cell array corresponding to bank addresses BA0 and BA1, row addresses RA0 and RA1, and column addresses CA0 and CA1. Alternatively, pieces of read data RD0 through RD7 of the read data packet are read from a bank and/or memory cell array corresponding to the bank addresses BA0 and BA1, the row addresses RA0 and RA1, and the column addresses CA0 and CA1.

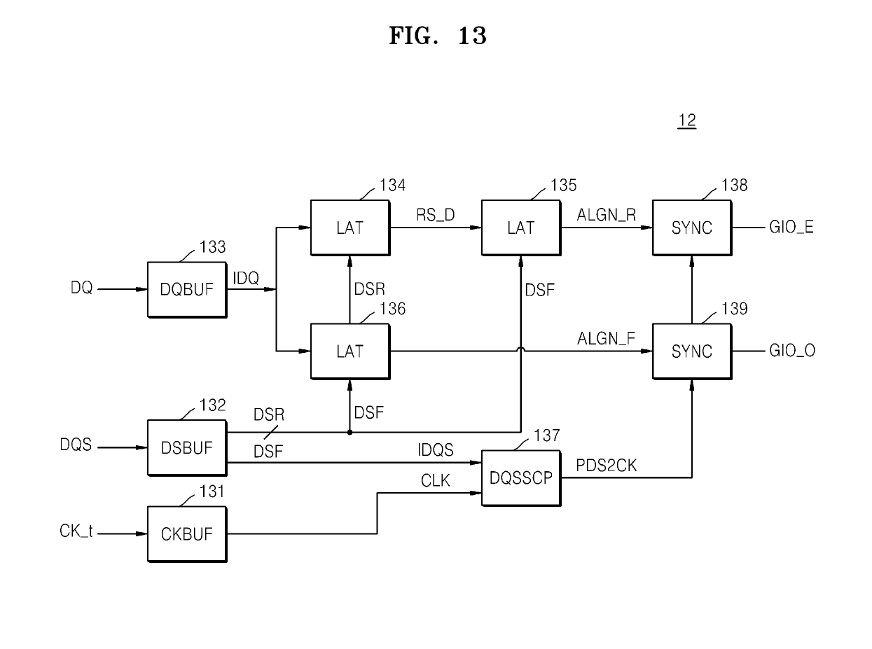

FIG. 13 is a block diagram for explaining source synchronous interface of the MRAM 12, according to an exemplary embodiment. The MRAM 12 performs source synchronous interface in which data is input/output in synchronization with a data strobe signal DQS generated along with data DQ in a data source.

Referring to FIG. 13, the MRAM 12 inputs the data DQ synchronized with the data strobe signal DQS and outputs internal data IDQ controlled by a clock signal CK_t. The MRAM 12 is required to have a tDQSS timing margin required by a skew specification between the clock signal CK_T and the data strobe signal DQS. A tDQSS timing is a time between a rising edge of the data strobe signal DQS and a rising edge of the clock signal CK_t. The MRAM 12 includes a clock buffer 131, a data strobe buffer 132, and a data input buffer 133 on a data input path.

The clock buffer 131 inputs the clock signal CK_t. The data strobe buffer 132 receives the data strobe signal DQS and generates first and second latch signals DSR and DSF and an internal data strobe signal IDQS. The first latch signal DSR is a pulse signal generated at every rising edge of the internal data strobe signal IDQS and the second latch signal DSF is a pulse signal generated at every falling edge of the internal data strobe signal IDQS. The data input buffer 133 receives a data input signal and generates the internal DQ signal IDQ.

The internal DQ signal IDQ is applied to a first latch 134 and a third latch 136. The first latch 134 latches the internal DQ signal IDQ in response to the first latch signal DSR. An output signal RS_D of the first latch 134 is applied to a second latch 135. The second latch 135 latches the output signal RS_D of the first latch 134 in response to the second latch signal DSF and generates first align data ALGN_R. The third latch 136 latches the internal DQ signal IDQ in response to the second latch signal DSF and generates second align data ALGN_F.

The first and second align data ALGN_R and ALGN_F are applied to first and second clock synchronizers 138 and 139. The internal data strobe signal IDQS and an output signal CLK of the clock buffer 131 are applied to a skew compensator 137. The skew compensator 137 generates a clock synchronization signal PDS2CK having a tDQSS timing margin required by a skew specification between the clock signal CK_t and the data strobe signal DQS. A tDQSS timing is set to ±0.25tCK as a skew between the clock signal CK_t and the data strobe signal DQS when one cycle of the clock signal CK_t is 1 tCK.

The first synchronizer 138 latches the first align data ALGN_R and outputs a first output signal GIO_E in response to the clock synchronization signal PDS2CK. The second clock synchronizer 139 latches the second align signal ALGN_F and outputs a second output signal GIO_O in response to the clock synchronization signal PDS2CK.

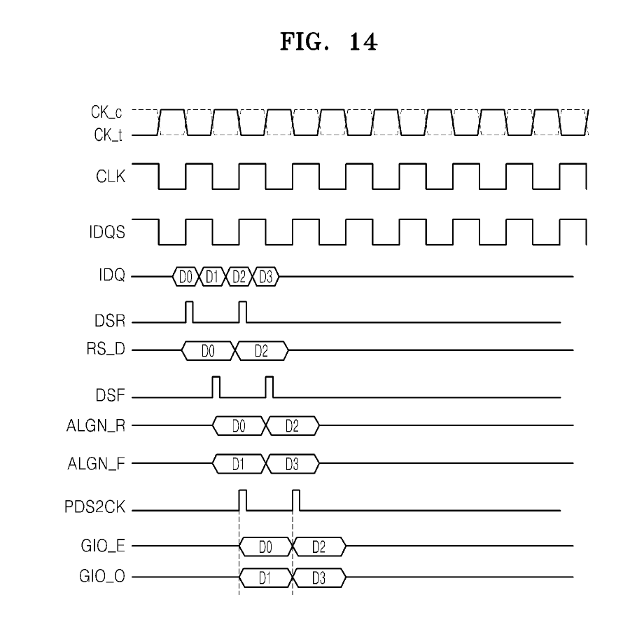

FIG. 14 is an exemplary timing diagram for explaining an operation on a data input path of FIG. 13, according to one embodiment.

Referring to FIG. 14, a case where the clock signal CK_t and the data strobe signal DQS are accurately matched to each other is presented. When a burst length (BL) is 4 (BL=4), pieces of DQ data D0, D1, D2, and D3 which are externally applied are synchronized with the internal data strobe signal IDQS and are transmitted as the internal DQ signal IDQ. The first latch signal DSR is generated at every rising edge of the internal data strobe signal IDQS, and D0 and D2 internal DQ signals are latched in response to the first latch signal DSR.

The second latch signal DSF is generated at every falling edge of the internal data strobe signal IDQS, and D1 and D3 internal DQ signals are latched and output as the second align data ALGN_F in response to the second latch signal DSF. Also, the latched D0 and D2 internal DQ signals are also output as the first align data ALGN_R in response to the second latch signal DSF. The first and second align data ALGN_R and ALGN_F are output as the first and second output signals GIO_E and GIO_O in response to the clock synchronization signal PDS2CK. The clock synchronization signal PDS2CK is controlled to generate a rising edge in a window center of the first and second align data ALGN_R and ALGN_F.

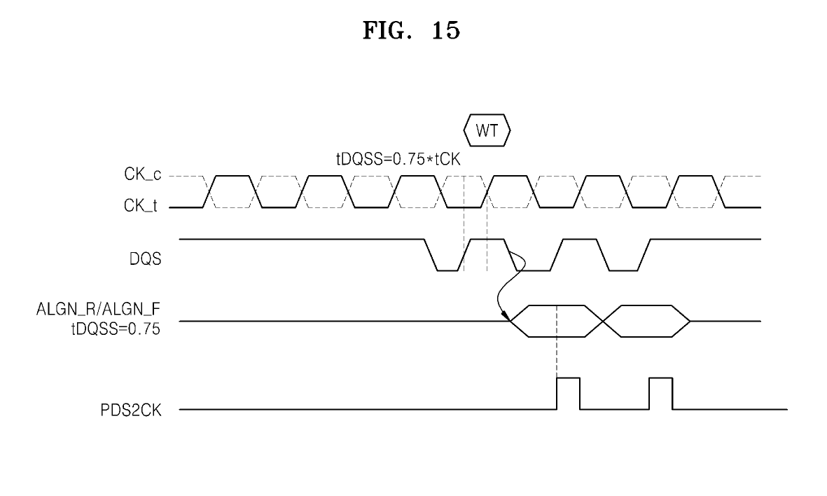

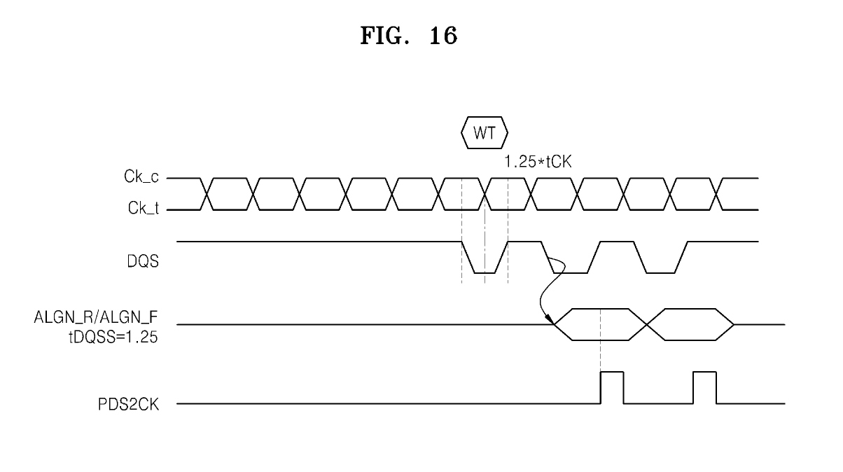

When a tDQSS timing required by a specification is ±0.25tCK, a case where a rising edge of the data strobe signal DQS precedes a rising edge of the clock signal CK_t, that is, tDQSS=0.75tCK, is illustrated in FIG. 15. A case where a rising edge of the clock signal CK_t precedes a rising edge of the data strobe signal DQS, that is, tDQSS=1.25tCK, is illustrated in FIG. 16.

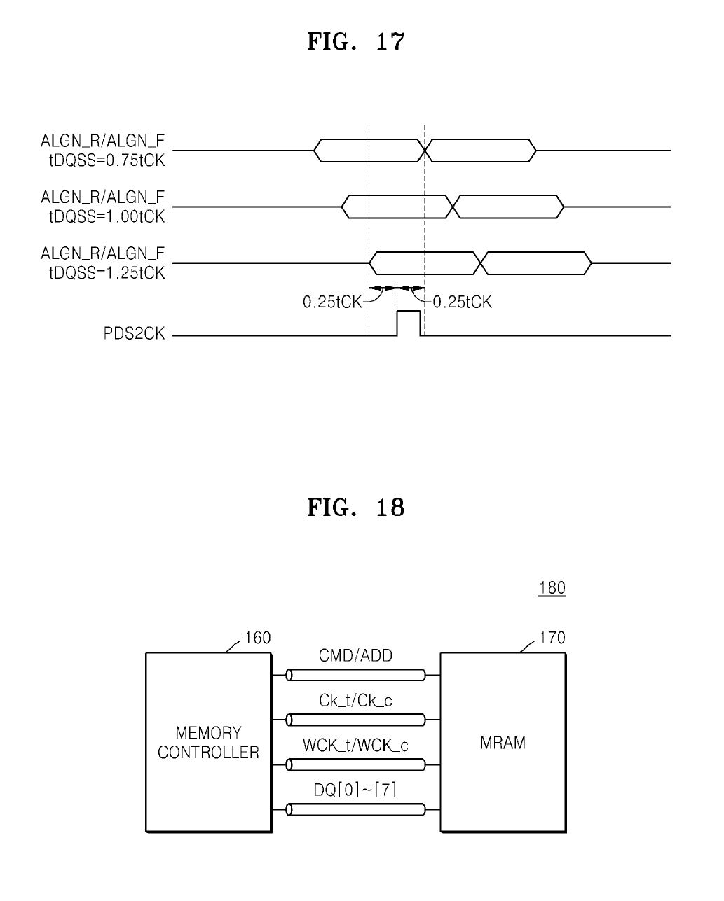

Referring to FIG. 15, the first and second align data ALGN_R and ALGN_F are output in response to a falling edge of the data strobe signal DQS that is earlier than the clock signal CK_t by 0.25tCK, and the clock synchronization signal PDS2CK is generated in a window center of the first and second align data ALGN_R and ALGN_F. Referring to FIG. 16, the first and second align data ALGN_R and ALGN_F are output in response to a falling edge of the data strobe signal DQS that is later than the clock signal CK_T by 0.25tCK, and the clock synchronization signal PDS2CK is generated in a window center of the first and second align data ALGN_R and ALGN_F. A timing margin between the clock synchronization signal PDS2CK and the first and second align data ALGN_R and ALGN_F according to the tDQSS timing of ±0.25tCK required by the specification is illustrated in FIG. 17.

Referring to FIG. 17, the tDQSS timing margin corresponds to a portion where the first and second align data ALGN_R and ALGN_F when the data strobe signal DQS precedes the clock signal CK_t (tDQSS=0.75tCK) and the first and second align data ALGN_R and ALGN_F when the clock signal CK_t precedes the data strobe signal DQS (tDQSS=1.25tCK) overlap each other. The clock synchronization signal PDS2CK is set to be activated in a center of the overlapping portion when the data strobe signal DQS and the clock signal CK_t are accurately synchronized with each other. As such, a tDQSS timing margin of ±0.25tCK is obtained in both directions from a rising edge at which the clock synchronization signal PDS2CK is activated.

FIG. 18 is a block diagram illustrating a semiconductor memory system 180 including an MRAM 170, according to another exemplary embodiment.

Referring to FIG. 18, the semiconductor memory system 180 includes a memory controller 160 and an MRAM 170. The MRAM 170 may use an 8n prefetch architecture and DDR interface in order to perform a high speed operation. The MRAM 170 samples a command signal CMD and an address signal ADD by using a differential clock signal CK_t/CK_c. The differential clock signal CK_t/CK_c may be referred to as a command/address clock signal. Also, the MRAM 170 samples a data input/output signal DQ by using a differential data clock signal WCK_t/WCK_c.

The MRAM 170 may operate in an x32 mode or an x16 mode. In MRAM interface, two 32-bit wide data words to/from I/O pins are transmitted in every WCK clock cycle. One single write or read access corresponding to an 8n prefetch architecture may form 256 bit wide data words, the 256 bit wide data words may be transmitted to an internal memory core during 2 CK clock cycles, and eight 32 bit wide data words may be transmitted to I/O pins during a ½ WCK clock cycle.

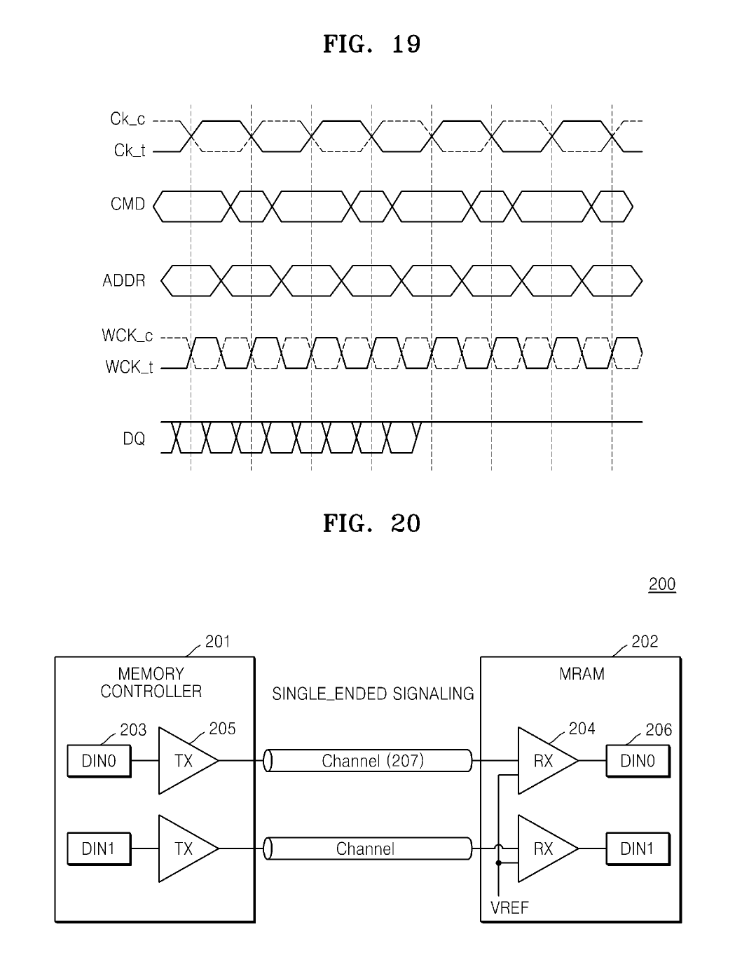

FIG. 19 is a diagram for explaining MRAM interface of FIG. 18, according to one exemplary embodiment.

Referring to FIG. 19, in an MRAM interface, command signals CMD are registered at every rising edge of a command/address clock signal CK_t, and address signals ADDR are stored at every rising edge of the command/address clock signal CK_t and a rising edge of a command/address clock signal CK_c. Data DQ is stored at every rising edge of a data clock signal WCK_c and every rising edge of a data clock signal WCK_t. Each of the data clock signals WCK_t and WCK_c operates at a frequency that is two times a frequency of each of the command/address clock signals CK_t and CK_c.

FIG. 20 is a block diagram illustrating a semiconductor memory system 200 including an MRAM 202, according to another exemplary embodiment.

Referring to FIG. 20, the semiconductor memory system 200 supports a single-ended signaling interface through a channel 207 connected between a memory controller 201 and the MRAM 202. The MRAM 202 operates under the control of the memory controller 201. The memory controller 201 includes a data output buffer 203 that outputs first data DIN0 and a transmitter 205 that transmits the first data DIN0 to the channel 207. The MRAM 202 includes a receiver 204 that compares the first data DIN0 received through the channel 207 with a reference voltage VREF, and a data input buffer 206 that inputs a comparison result of the receiver 204.

In the MRAM 202, the receiver 204 may include a comparator. In one embodiment, the receiver 204 outputs logic high data when a voltage level of the first data DIN0 is higher than that of the reference voltage VREF, and outputs logic low data when a voltage level of the first data DIN0 is lower than that of the reference voltage VREF. In single-ended signaling interface, one data bit is transmitted to one channel 207. Accordingly, since an area of a printed circuit board (PCB) including the semiconductor memory system 200 may be minimized, costs may be reduced.

In single-ended signaling, when a plurality of single-ended ports of the transmitter 205 are simultaneously switched in the same direction, a simultaneously switching output induced noise (SSN) may be generated due to a current flowing through a parasitic inductor. Accordingly, jitter in the transmitter 205 may be increased and an input voltage margin of the receiver 204 may be reduced. In single-ended signaling, crosstalk when a transition position is instantly changed due to data transition of the adjacent channel 207 to reduce a timing margin may occur. Also, in single-ended signaling, a high frequency component of a signal may be attenuated due to low pass filter characteristics of the channel 207, and an inter-symbol interference (ISI) where a state of a previous signal affects a timing of a current signal due to a propagation delay may occur.

In single-ended signaling, when a data bandwidth is increased to exceed Gbps, signal integrity is degraded due to the channel characteristics. Single-ended signaling is therefore not typically suitable for high-bandwidth interface exceeding Gbps. In order to realize a high performance bandwidth, in one embodiment, the semiconductor memory system 200 may use differential-ended signal interface by increasing a clock speed.

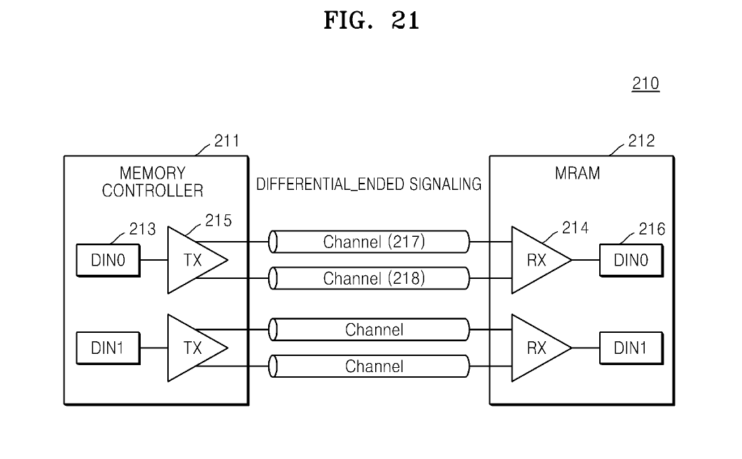

FIG. 21 is a block diagram illustrating a semiconductor memory system 210 including an MRAM 212, according to another exemplary embodiment.

Referring to FIG. 21, the semiconductor memory system 210 supports a differential-ended signaling interface through channels 217 and 218 connected between a memory controller 211 and the MRAM 212. The MRAM 212 operates under the control of the memory controller 211. The memory controller 211 includes a data output buffer 213 that outputs first data DIN0, and a transmitter 215 that transmits the first data DIN0 to the channels 217 and 218. The transmitter 215 transmits the first data DIN0 and inverted first data DIN0B to the channels 217 and 218. The MRAM 202 includes a receiver 214 that receives the first data DIN0 and the inverted first data DIN0 received through the channels 217 and 218, and a data input buffer 216 that inputs an output of the receiver 214.

In the MRAM 212, the receiver 214 may include a differential amplifier that inputs a differential data pair including the first data DIN0 and the inverted first data DIN0B. In differential-ended signaling, since 1-bit data is transmitted by using a differential data pair, noise immunity and signal integrity may be improved. Accordingly, differential-ended signaling is suitable for data transmission exceeding Gbps. In differential-ended signaling, since two channels 217 and 218 are used in order to transmit 1-bit data, an area of a PCB including the semiconductor memory system 210 may be increased, thereby increasing costs.

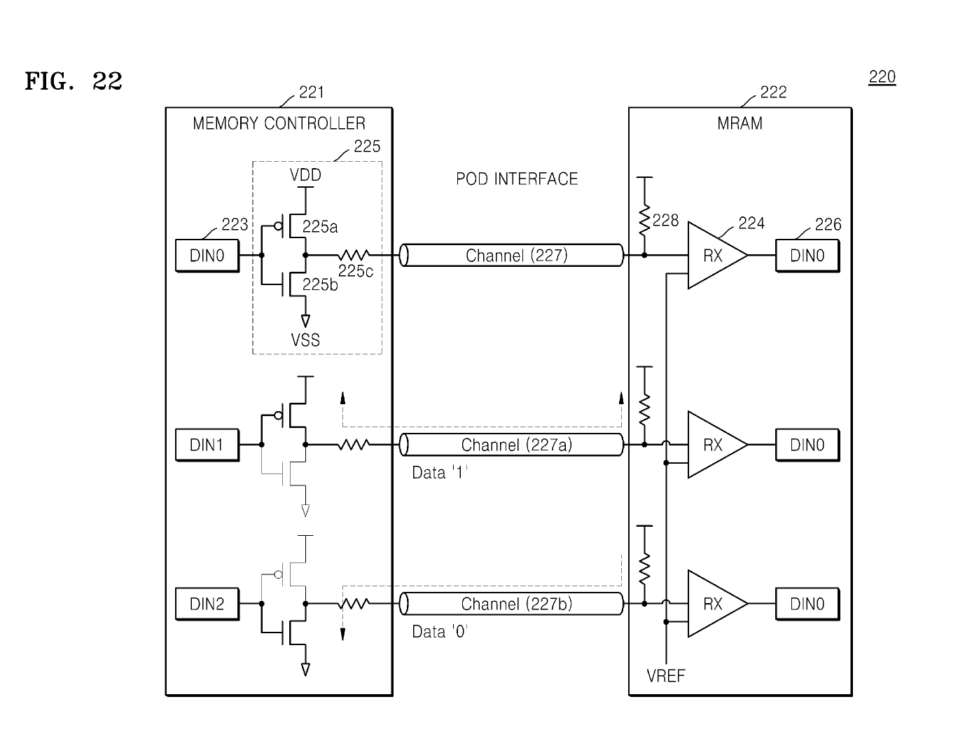

FIG. 22 is a block diagram illustrating a semiconductor memory system 220 including an MRAM 222, according to another exemplary embodiment.

Referring to FIG. 22, the semiconductor memory system 220 supports POD interface through a channel 227 connected between a memory controller 221 and the MRAM 222. The MRAM 222 operates under the control of the memory controller 221. POD interface is based on a voltage. The memory controller 221 includes a data output buffer 223 that outputs first data DIN0, and an output driver 225 that transmits the first data DIN0 to the channel 227.

The output driver 225 includes a PMOS transistor 225a and an NMOS transistor 225b connected in series between a source of a power supply voltage VDD and a source of a ground voltage VSS. An output signal of the data output buffer 223 is applied to gates of the PMOS transistor 225a and the NMOS transistor 225b. Drains of the PMOS transistor 225a and the NMOS transistor 225b are connected to one end of a first resistor 225c. The other end of the first resistor 225c is connected to the channel 227.

The MRAM 222 includes a receiver 224 that compares data transmitted through the channel 227 with a reference voltage VREF, a data input buffer 226 that inputs a comparison result of the receiver 224, and a second resistor 228 that is connected between the source of the power supply voltage VDD and the channel 227. The second resistor 228 may be disposed outside the MRAM 222. The power supply voltage VDD of the MRAM 222 may be referred to as a termination power supply voltage, and the first resistor 225c may be referred to as a termination resistor.

When data transmitted to the channel 227a is, for example, logic “1” data, the channel 227a is maintained in a logic “1” state due to a path formed by the PMOS transistor 225a connected to the source of the power supply voltage VDD, and the source of the power supply voltage VDD connected to the first resistor 225c, and the channel 227a, and the second resistor 228. When data transmitted to the channel 227b is, for example, logic “0” data, the channel 227b is changed to a logic “0” state due to a path formed by the NMOS transistor 225b connected to the source of the ground voltage VSS, and the second resistor 228, the channel 227b, and the first resistor 225c connected to the source of the power supply voltage VDD.

In POD interface, since data transition occurs only when data transmitted to the channel 227 is logic “0” data, POD interface is suitable for high speed data transmission. Also, since current consumption occurs only when data transmitted to the channel 227 is logic “0” data, POD interface may reduce an SSN.

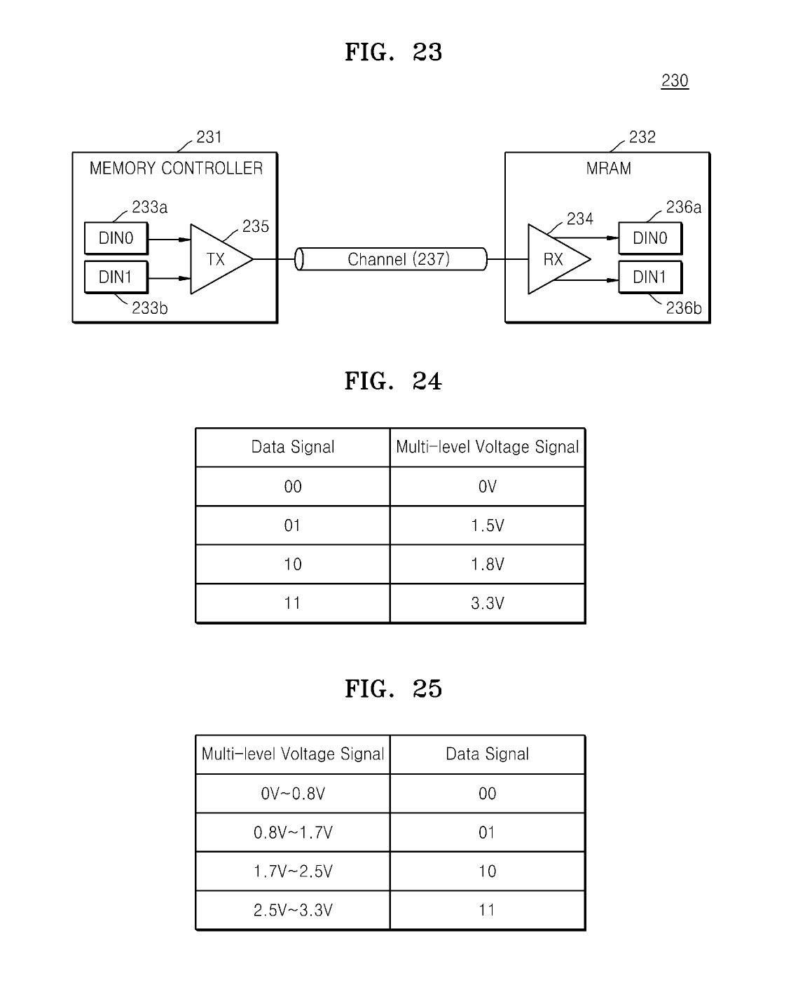

FIG. 23 is a block diagram illustrating a semiconductor memory system 230 including an MRAM 232, according to another exemplary embodiment.

Referring to FIG. 23, the semiconductor memory system 230 supports a multi-level single-ended signaling interface through a channel 237 connected between a memory controller 231 and the MRAM 232. The MRAM 232 operates under the control of the memory controller 231. Multi-level single-ended signaling interface is a method in which a voltage corresponding to a plurality of bits of a data signal is converted to a multi-level voltage signal.

The memory controller 231 includes a first data output buffer 233a that outputs first data DIN0, a second data output buffer 233b that outputs second data DIN1, and a multi-level converter 235 that converts the first and second data DIN0 and DIN1 into a multi-level voltage signal and transmits the multi-level voltage signal to the channel 237. The MRAM 232 includes a multi-level converter 234 that restores the multi-level voltage signal received through the channel 237 into a data signal including a plurality of bits, and first and second data input buffers 236a and 236b that input the restored data signal.

The multi-level converter 234 of the MRAM 232 may convert the first and second data DIN0 and DIN1 into a multi-level voltage signal and transmit the multi-level voltage signal to the channel 237. The multi-level converter 235 of the memory controller 231 may restore the multi-level voltage signal received through the channel 237 to a data signal including a plurality of bits.

FIGS. 24 and 25 are tables for explaining exemplary operations of the multi-level converters 235 and 234 of FIG. 23. FIG. 24 is a table illustrating an example where the multi-level converter 235 converts a data signal into a multi-level voltage signal. FIG. 25 is a table illustrating an example where the multi-level converter 234 converts a multi-level voltage signal into a data signal.

Referring to FIG. 24, the multi-level converter 235 converts a 2-bit data signal to be transmitted to the channel 237 into a multi-level voltage signal. For example, when a data signal is “00”, a voltage level of a multi-level voltage signal is changed to 0 V, when a data signal is “01”, a voltage level of a multi-level voltage signal is changed to 1.5 V, when a data signal is “10”, a voltage level of a multi-level voltage signal is changed to 1.8 V, and when a data signal is “11”, a voltage level of a multi-level voltage signal is changed to 3.3 V. Other exemplary voltage values may be used as well. In addition, additional levels may be used in a multi-level voltage signal (e.g., 8 levels instead of 4).

Referring to FIG. 25, the multi-level converter 234 detects a voltage level of a multi-level voltage signal received from the channel 237, and converts the multi-level voltage signal into a 2-bit data signal according to the detected voltage level. For example, when a multi-level voltage signal is equal to or greater than 0 V and equal to and less than 0.8 V, a data signal is changed to “00”, when a multi-level voltage signal is greater than 0.8 V and equal to or less than 1.7 V, a data signal is changed to “01”, when a multi-level voltage signal is higher than 1.7 V and equal to or less than 2.5 V, a data signal is changed to “10”, and when a multi-level voltage signal is greater than 2.5 V and equal to or less than 3.3 V, a data signal is changed to “11”. Other exemplary voltage ranges may be used as well.

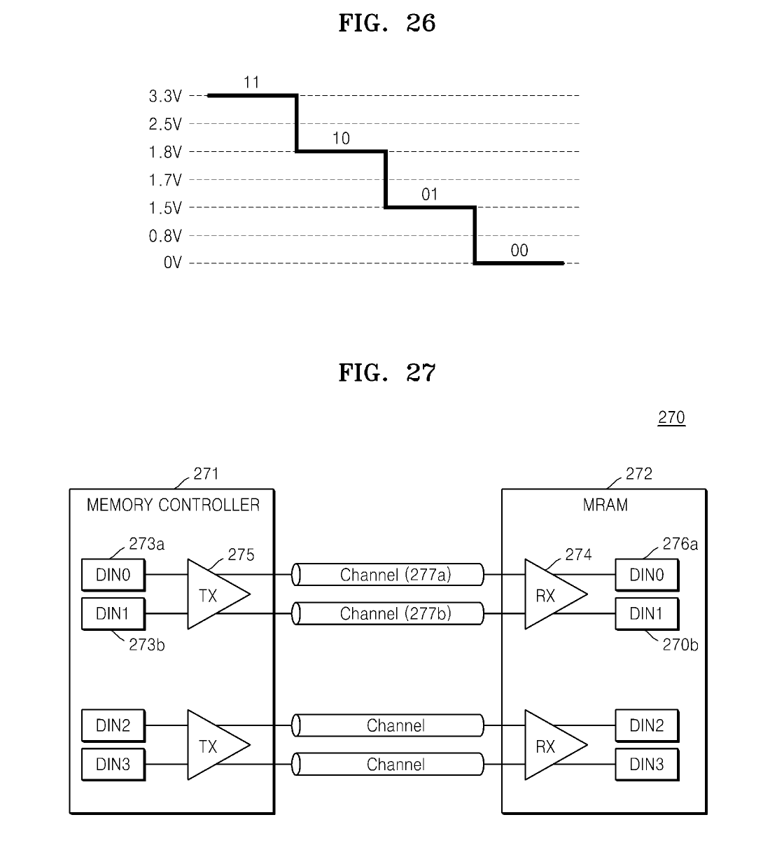

FIG. 26 is a diagram illustrating a voltage level of a multi-level voltage signal according to a data signal in the multi-level single-ended signaling interface of FIG. 23, according to one exemplary embodiment.

Referring to FIG. 26, when a data signal is “11”, a voltage level of a multi-level voltage signal is changed to 3.3 V, when a data signal is “10”, a voltage level of a multi-level voltage signal is changed to 1.8 V, when a data signal is “01”, a voltage level of a multi-level voltage signal is changed to 1.5 V, and when a data signal is “00”, a voltage level of a multi-level voltage signal is changed to 0 V, and the changed multi-level voltage signals are transmitted to the channel 267. When a voltage level of a multi-level voltage signal received from the channel 267 is greater than 2.5 V and equal to or less than 3.3 V, a data signal is changed to “11”, when a voltage level of a multi-level voltage signal is greater than 1.7 V and equal to or less than 2.5 V, a data signal is changed to “10”, when a voltage level of a multi-level voltage signal is greater than 0.8 V and equal to or less than 1.7 V, a data signal is changed to “01”, and when a voltage level of a multi-level voltage signal is greater than 0 V and equal to or less than 0.8 V, a data signal is changed to “00”.

FIG. 27 is a block diagram illustrating a semiconductor memory system 270 including an MRAM 272, according to another exemplary embodiment.

Referring to FIG. 27, the semiconductor memory system 270 supports multi-level differential-ended signaling interface through channels 277a and 277b connected between a memory controller 271 and the MRAM 272. The MRAM 272 operates under the control of the memory controller 271. Multi-level differential-ended signaling interface is a method in which a voltage corresponding to a plurality of bits of a data signal is converted into a multi-level voltage signal pair.

The memory controller 271 includes a first data output buffer 273a that outputs first data DIN0, a second data output buffer 273b that outputs second data DIN1, and a multi-level converter 275 that converts the first and second data DIN0 and DIN1 into a multi-level voltage signal pair and transmits the multi-level voltage signal pair. The MRAM 272 includes a multi-level converter 274 that restores the multi-level voltage signal pair received through the channels 277a and 277b into a data signal including a plurality of bits, and first and second data input buffers 276a and 276b that input the restored data signal.

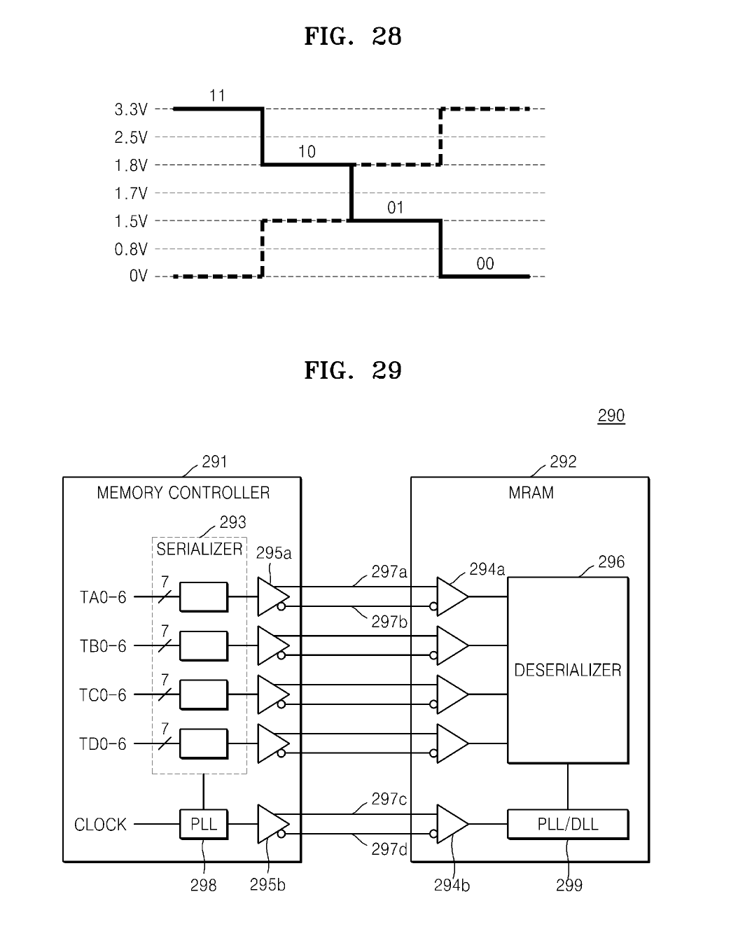

FIG. 28 is a diagram illustrating a voltage level of a multi-level voltage signal according to a data signal in the multi-level differential-ended signaling interface of FIG. 27, according to one exemplary embodiment.

Referring to FIG. 28, the multi-level converter 275 converts a 2-bit data signal to be transmitted to the first and second channels 277a and 277b into a multi-level voltage signal pair. When a data signal is “11”, voltage levels of a multi-level voltage signal pair are changed to 3.3 V and 0 V, when a data signal is “10”, voltage levels of a multi-level voltage signal pair are changed to 1.8 V and 1.5 V, when a data signal is “01”, voltage levels of a multi-level voltage signal pair are changed to 1.5 V and 1.8 V, and when a data signal is “00”, voltage levels of a multi-level voltage signal pair are changed to 0 V and 3.3 V. The changed multi-level voltage signal pair are transmitted to the first channel 277a and the second channel 277b.

The multi-level converter 264 detects voltage levels of a multi-level voltage signal pair received from the channel 237, and converts the multi-level voltage signal pair into a 2-bit data signal according to the detected voltage levels. For example, when a multi-level voltage signal of the first channel 277a is greater than 2.5 V and equal to or less than 3.3 V and a multi-level voltage signal of the second channel 277b is equal to or greater than 0 V and equal to or less than 0.8 V, a data signal is changed to “11”. When a multi-level voltage signal of the first channel 277a is greater than 1.7 V and equal to or less than 2.5 V and a multi-level voltage signal of the second channel 277b is greater than 0.8 V and equal to or less than 1.7 V, a data signal is changed to “10”. When a multi-level voltage signal of the first channel 277a is greater than 0.8 V and equal to or less than 1.7 V and a multi-level voltage signal of the second channel 277b is greater than 1.7 V and equal to or less than 2.5 V, a data signal is changed to “01”. When a multi-level voltage signal of the first channel 277a is equal to or greater than 0 V and equal to or less than 0.8 V and a multi-level voltage signal of the second channel 277b is greater than 2.5 V and equal to or less than 3.3 V, a data signal is changed to “00”. Other voltage values and voltage ranges may be used as well. In addition, additional levels may be used in a multi-level voltage signal (e.g., 8 levels instead of 4).

FIG. 29 is a block diagram illustrating a semiconductor memory system 290 including an MRAM 292, according to another exemplary embodiment.

Referring to FIG. 29, the semiconductor memory system 290 supports an LVDS interface through channels 297a and 297b connected between a memory controller 291 and the MRAM 292. The MRAM 292 operates under the control of the memory controller 291. LVDS interface is a method in which a differential input signal having an extremely small swing, for example, a swing of about 350 mV is received to ensure high immunity to a noise, and a high data transmission speed. In particular, since a differential input signal is received and a high common mode rejection ratio is ensured, anti-noise characteristics are improved.

The memory controller 291 includes a serializer 293 that receives parallel data TA0 through TA6 and converts the parallel data TA0 through TA6 to serial data, and a first output driver 295a that transmits the serial data to the channels 297a and 297b. Also, the memory controller 291 includes a phase-locked loop (PLL) 298 that receives a clock signal CLOCK and supplies an operation clock of the serializer 293 and the first output driver 295a, and a second output driver 295b that transmits the operation clock output from the PLL 298 to the channels 297c and 297d.

The MRAM 292 includes a first input driver 294a that receives serial data transmitted through the channels 297a and 297b, and a parallelizer 296 that converts an output of the first input driver 294a into parallel data. An operation frequency of the first input driver 294a is the same as an operation frequency of the first output driver 295a. The MRAM 292 includes a second input driver 294b that receives an operation clock transmitted through the channels 297c and 297d, and a PLL 299 that supplies an operation clock of the parallelizer 296 and the first input driver 294a. The PLL 298 of the memory controller 291 and the PLL 299 of the MRAM 292 synchronize operation clocks transmitted through the second output driver 295b and the second input driver 294b.

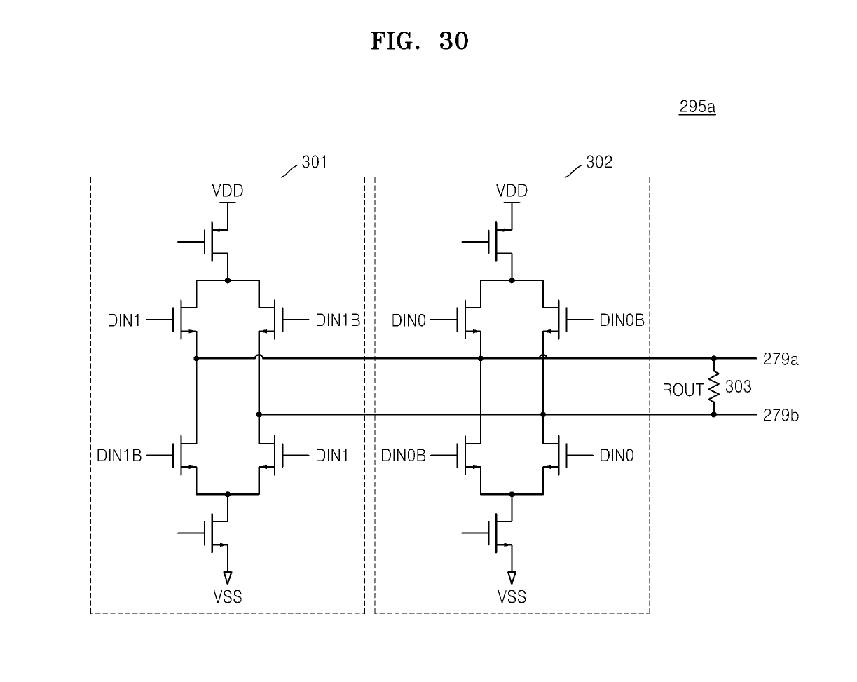

FIG. 30 is a circuit diagram illustrating the first output driver 295a of FIG. 29, according to one exemplary embodiment.

Referring to FIG. 30, the first output driver 295a includes a first differential amplifier 301, a second differential amplifier 302, and a resistor 303. A case where the first output driver 209a receives an even data pair DIN0 and DINB and an add data pair DIN1 and DIN1B from among pieces of serial data output from the serializer 293 will be exemplarily explained. The first differential amplifier 301 detects and amplifies the odd data pair DIN1 and DIN1B, and the second differential amplifier 302 detects and amplifies the even data pair DIN0 and DINB. Outputs of the first and second sense amplifiers 301 and 302 are applied to the resistor 303. Accordingly, a differential output signal having an extremely small swing, for example, a swing of about 350 mV, is generated at both ends of the resistor 303, and is transmitted to the channels 297a and 297b.

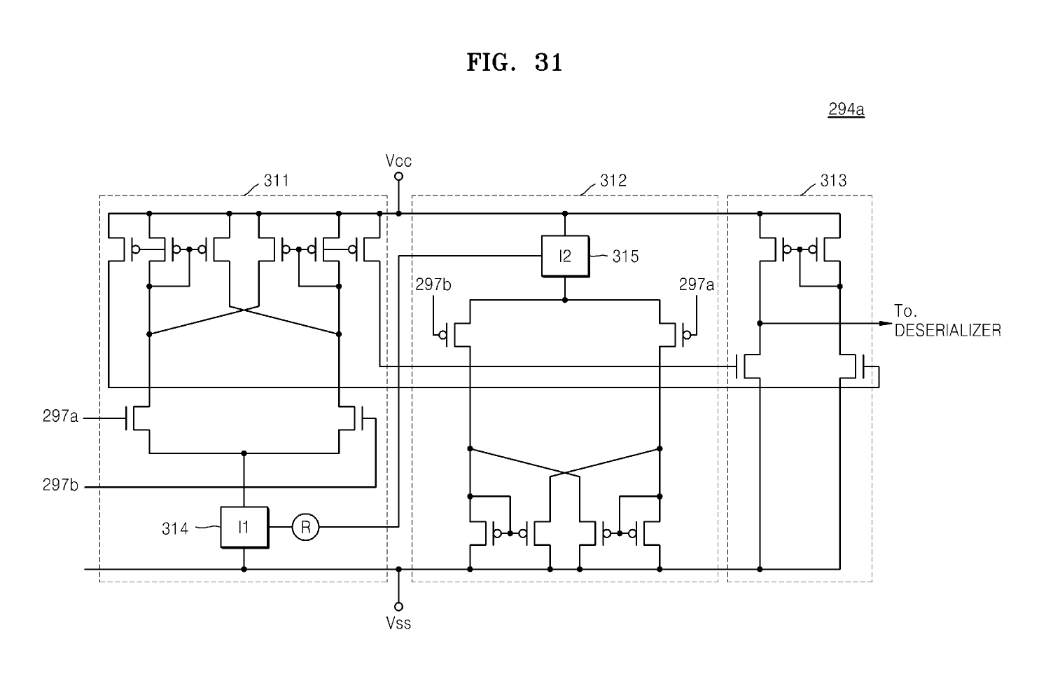

FIG. 31 is a circuit diagram illustrating the first input driver 294a of FIG. 29, according to one exemplary embodiment.

Referring to FIG. 31, the first input driver 294a includes an N-channel differential amplifier 311, a P-channel differential amplifier 312, and a comparator 313. First and second current sources 314 and 315 are connected to the differential amplifiers 311 and 312 to control currents supplied to the differential amplifiers 311 and 312, respectively. The differential amplifiers 311 and 312 detect and amplify a data pair transmitted to the channels 297a and 297b. The comparator 313 compares outputs of the differential amplifiers 311 and 312, and transmits a comparison result to the parallelizer 296.

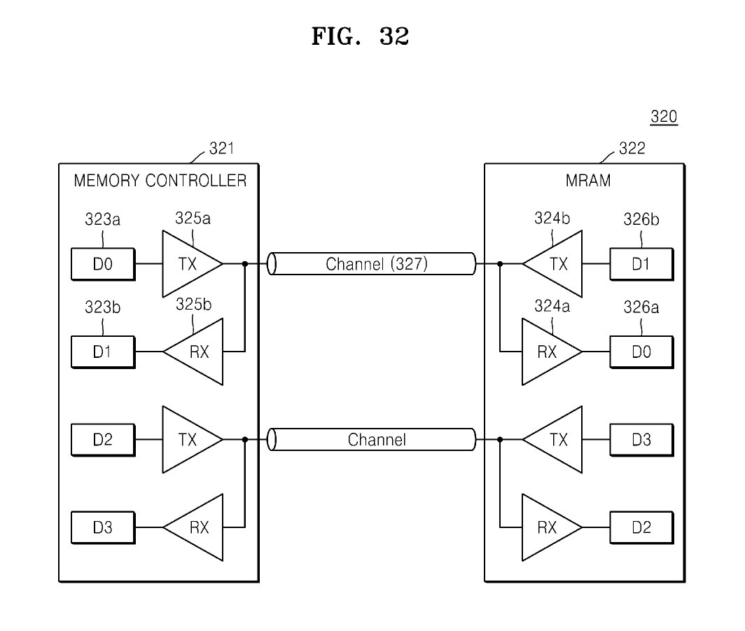

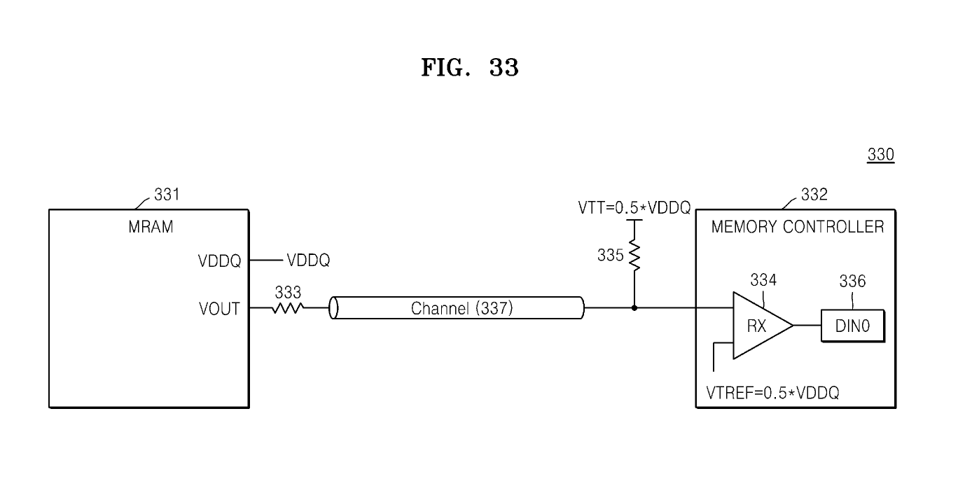

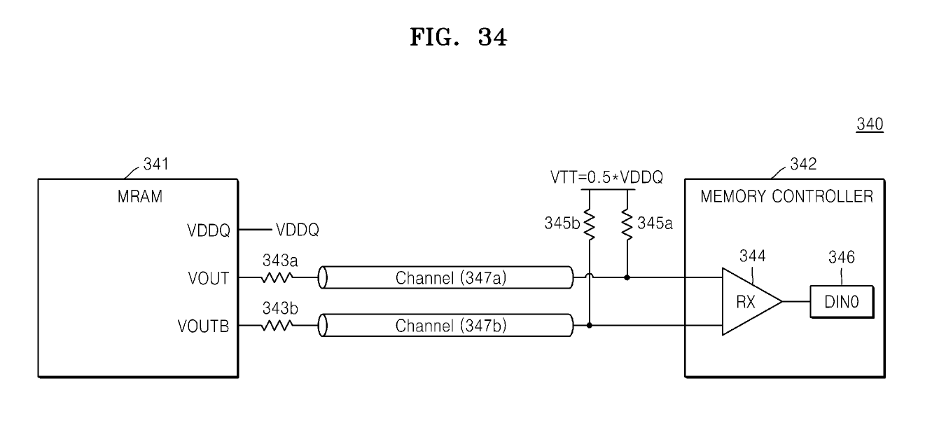

FIG. 32 is a block diagram illustrating a semiconductor memory system 320 including an MRAM 322, according to another exemplary embodiment.

Referring to FIG. 32, the semiconductor memory system 320 supports a bidirectional interface through a channel 327 connected between a memory controller 321 and the MRAM 322. The MRAM 322 operates under the control of the memory controller 321. In a bidirectional interface, communications are performed through one channel 327. Accordingly, since a smaller number of channels are used, a data bandwidth may be improved.

The memory controller 321 includes first and second buffers 323a and 323b, a first output driver 325a, and a first input driver 325b. The first buffer 323a stores first data D0, and the first output driver 325a transmits the first data D0 stored in the first buffer 323a to the channel 327. The first input driver 325b receives second data D1 transmitted through the channel 327 and the second buffer 323b stores the received second data D1.

The MRAM 322 includes a second input driver 324a, a second output driver 324b, and third and fourth buffers 326a and 326b. The second input driver 324a receives the first data D0 transmitted through the channel 327 by the first output driver 325a, and the third buffer 326a stores the received first data D0. The fourth buffer 326b stores the second data D1, and the second output driver 324b transmits the second data D1 stored in the fourth buffer 326b to the channel 327. The second data D1 transmitted to the channel 327 is received by the first input driver 325b.

FIGS. 33 through 35 are block diagrams illustrating semiconductor memory systems 330, 340, and 350 respectively including MRAMs 332, 342, and 352, according to other embodiments.

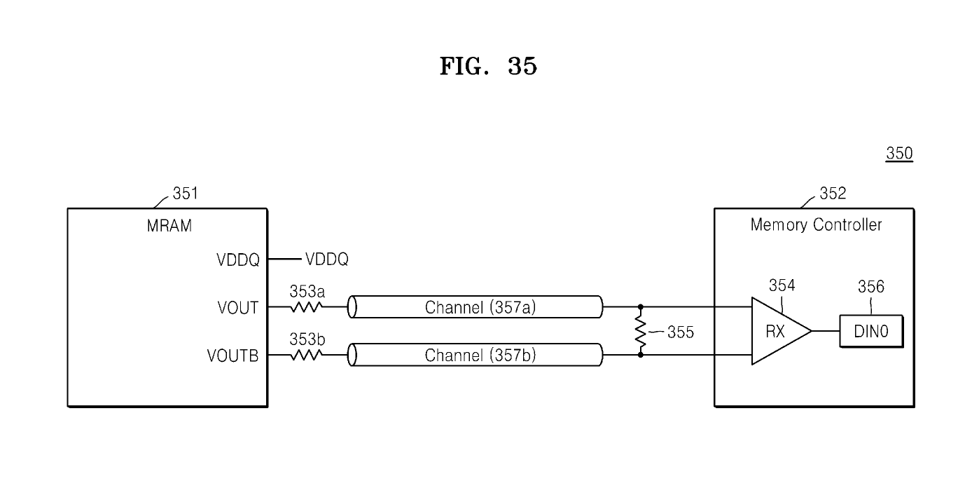

FIGS. 33 through 35 are block diagrams for explaining CTT interface of the semiconductor memory systems 330, 340, and 350. FIG. 33 illustrates CTT interface of single-ended signaling. FIGS. 34 and 35 illustrate CTT interface of differential-ended signaling.

Referring to FIG. 33, the semiconductor memory system 330 supports single-ended signaling CTT interface through a channel 337 connected between the MRAM 331 and a memory controller 332. A line resistor 333 is connected between one end of the channel 337 and the MRAM 331, and a termination resistor 335 is connected between the other end of the channel 337 and a source of a termination voltage VTT. A signal output from the MRAM 331 is transmitted to the memory controller 332 through the line resistor 333 and the channel 337. The termination voltage VTT is set to have a voltage level corresponding to a half of a data input/output power supply voltage VDDQ of the MRAM 331, that is, corresponding to VTT=0.5*VDDQ.

The memory controller 332 includes a receiver 334 that compares a voltage of an output signal of the MRAM 331 transmitted through the channel 337 with a reference voltage VTREF, and a buffer 336 that inputs a comparison result of the receiver 334. The reference voltage VTREF is also set to have a voltage level corresponding to a half of the data input/output power supply voltage VDDQ of the MRAM 331, that is, corresponding to VTREF=0.5*VDDQ, and has the same voltage level as that of the termination voltage VTT.

In single-ended signaling CTT interface, the channel 337 has a swing width such that the channel 337 has a high voltage level by being precharged to the termination voltage VTT in a standby state and is changed from the high voltage level to a low voltage level according to an output signal of the MRAM 331. A low voltage level is in between a ground voltage VSS and the terminal voltage VTT that is a half of the data input/output power supply voltage VDDQ. Accordingly, CTT interface may improve an operation speed by reducing a signal swing width.

Referring to FIG. 34, the semiconductor memory system 340 supports differential-ended signaling CTT interface through channels 347a and 347b connected between the MRAM 341 and a memory controller 342. A first line resistor 343a is connected between one end of the first channel 347a and the MRAM 341, and a first termination resistor 345a is connected between the other end of the first channel 347a and a source of the termination voltage VTT. A second line resistor 343b is connected between one end of the second channel 347b and the MRAM 341, and a second termination resistor 345b is connected between the other end of the second channel 347b and the source of the termination voltage VTT. The termination voltage VTT is set to have a voltage level corresponding to a half of the data input/output power supply voltage VDDQ, that is, corresponding to VTT=0.5*VDDQ. The channel 337 is maintained at the termination voltage VTT.

A differential signal pair output from the MRAM 341 is transmitted to the memory controller 342 through the first line resistor 343a, the first channel 347a, the second line resistor 343b, and the second channel 347b. The memory controller 342 includes a receiver 344 that detects and amplifies an output signal pair of the MRAM 341 transmitted through the first and second channels 347a and 347b, and a buffer 346 that inputs an output of the receiver 344.

Referring to FIG. 35, the semiconductor memory system 350 supports differential-ended signaling CTT interface through channels 357a and 347b connected between the MRAM 352 and a memory controller 352. A differential signal pair output from the MRAM 352 is transmitted to the memory controller 352 through a first line resistor 353a, the first channel 357a, a second line resistor 353b, and the second channel 357b. The first and second channels 357a and 357b are short-circuited from each other by a termination resistor 355 at an input side of the memory controller 352. The memory controller 352 includes a receiver 354 that detects and amplifies an output signal pair of the MRAM 351 transmitted through the first and second channels 357a and 357b, and a buffer 356 that inputs an output of the receiver 354.

In certain embodiments, an MRAM transmits/receives a digital signal through a bus according to a request of a memory controller or a microprocessor. In certain embodiments, an MRAM uses a DLL/PLL that synchronizes a clock signal and/or a data strobe signal DQS with a DQ signal. However, the microprocessor may need many different synchronous interfaces. Therefore, in one embodiment, an MRAM interfaces with a high speed synchronous bus without a specific DLL/PLL.

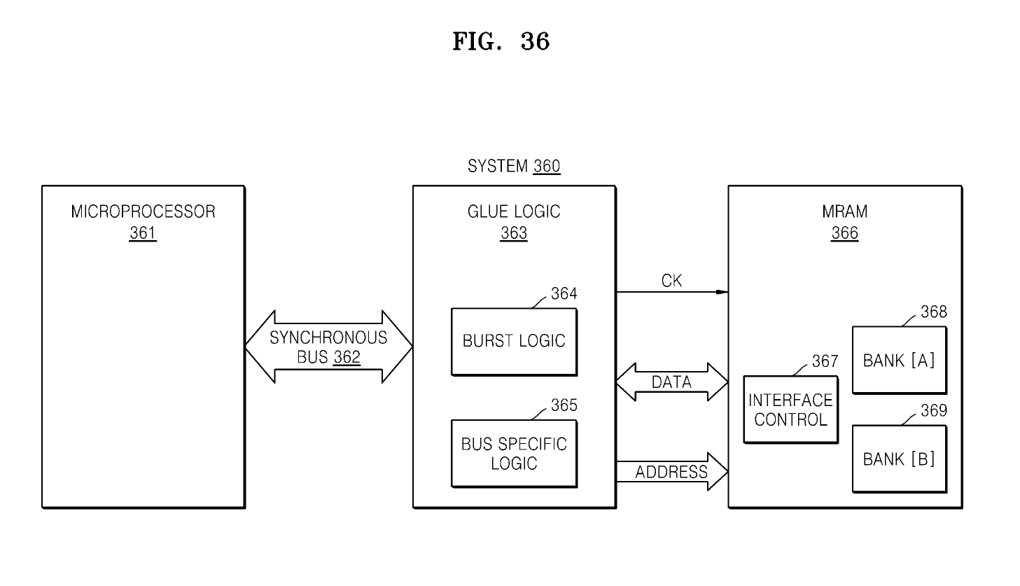

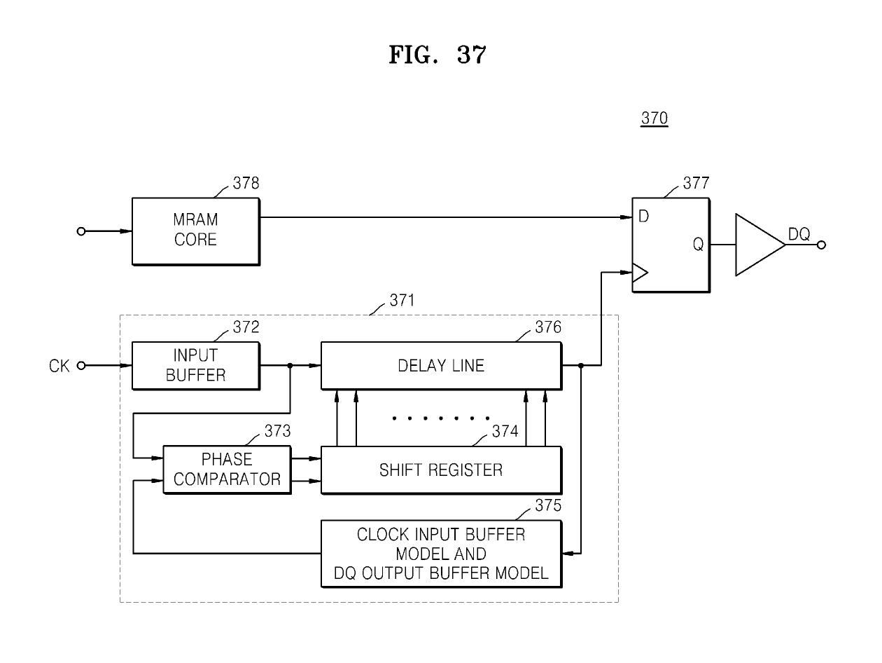

FIG. 36 is a block diagram illustrating a system 360 including an MRAM 366, according to another exemplary embodiment.

Referring to FIG. 36, the system 360 includes the MRAM 366 that uses a synchronous interface and does not use a DLL/PLL. A glue logic unit 363 is disposed between a microprocessor 361 and the MRAM 366, and the MRAM 366 includes circuits required to interface with a high speed synchronous bus 362. The MRAM 366 includes an interface controller 367 that controls an operation of banks 368 and 369 in which STT-MRAM cells are arranged. The interface controller 367 controls a burst write/read operation of the bank A 368 and/or the bank B 369.

The glue logic unit 363 includes a burst logic unit 364, and a bus specific logic unit 365 that supports an interface with many different synchronous buses. Since the memory processor 361 may need different burst sequences, the burst logic unit 364 is used. For example, the burst logic unit 364 may set an order of read data applied by the MRAM 366 on a data terminal according to a nibble sequential burst mode or an interleave burst mode. The MRAM 366 interfaces with the high speed synchronous bus 362 by using the glue logic unit 363, and thus, the MRAM 366 does not need a DLL/PLL therein.

FIG. 37 is a block diagram illustrating a DLL 371 included in an MRAM 370, according to one exemplary embodiment.

Referring to FIG. 37, the MRAM 370 includes the DLL 371 in order to synchronize data transmitted to local circuits with a clock signal CK. The DLL 371 includes an input buffer 372, a phase comparator 373, a shift register 374, a clock input buffer model and DQ output buffer model 375, and a delay line 376. Based on a delayed clock signal output from the delay line 376, a controller 377, such as a gate, controls data transmitted from an MRAM core 378 to a DQ data circuit.

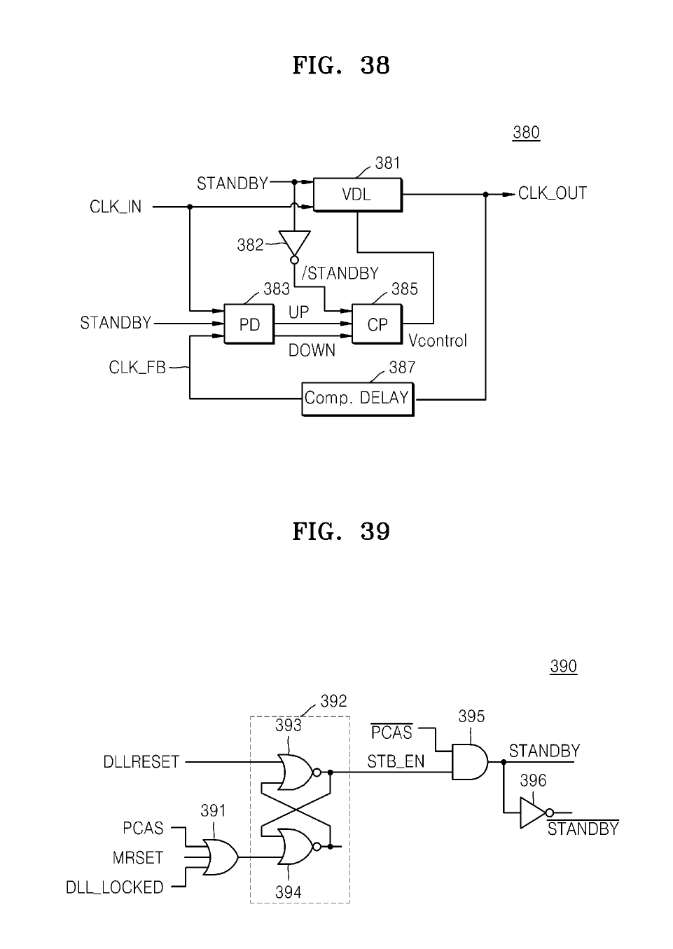

FIG. 38 is a circuit diagram illustrating a DLL 380 included in an MRAM, according to another exemplary embodiment.

Referring to FIG. 38, the DLL 380 is disabled according to a standby operation mode. The DLL 380 includes a voltage controlled delay line (VDL) 381, a phase detector 383, a charge pump 385, and a compensation delay circuit 387.

The phase detector 383 detects a phase difference between an external clock CLK_IN and an internal clock CLK_OUT or a feedback clock CLK_FB in response to the external clock CLK_IN, a standby signal STANDBY, and the internal clock CLK_OUT or the feedback clock CLK_FB whose phase is compensated by the compensation delay circuit 387, and outputs control signals UP and DOWN corresponding to the phase difference to the charge pump 385.

The charge pump 385 outputs a control voltage Vcontrol that controls a delay time of the VDL 381 to the VDL 381 in response to the control signal UP or DOWN and an inverted standby signal /STANDBY. The VDL 381 adjusts a delay time of the external clock CLK_IN in response to the external clock CLK_IN, the standby signal STANDBY, and the control voltage Vcontrol, and synchronizes the internal clock CLK_OUT with the external clock CLK_IN.

The compensation delay circuit 387 outputs the feedback clock signal CLK_FB whose phase leads a phase of the outer clock CLK_IN in response to the internal clock CLK_OUT. The compensation delay circuit 387 monitors a delay of the data input buffer and a data output buffer.

While the DLL 380 is turned on, the DLL 380 changes the control voltage Vcontrol of the charge pump 385 that adjusts a delay time of the VDL 381 in order to compensate for a change in a delay due, for example, to a change in a temperature or an external power supply voltage while continuously performing a locking operation. As such, locking information during an operation of the DLL 380 is updated. However, when the DLL 380 is turned off, a value of the control voltage Vcotnrol which was continuously being updated is no longer updated, and is increased/or reduced to a power supply voltage Vcc or a ground voltage Vss. When the DLL 380 is turned on again, the DLL 380 performs a locking operation by continuously changing the control voltage Vcontrol in order to set a predetermined delay time of the VDL 381. A time taken to reach a locking state after the DLL 380 is turned on is referred to as a locking time.

FIG. 39 is a circuit diagram illustrating a control signal generator 390 that generates the standby signal STANDBY of FIG. 38, according to one exemplary embodiment.

Referring to FIG. 39, the control signal generator 390 includes a logic circuit 391, a standby enable signal generator 392, and an AND circuit 395.

The logic circuit 391 performs an AND operation on a signal PCAS (which is generated by a CAS command such as a read command and a write command), a signal MRSET, and a signal DLL_LOCKED. The signal PCAS is a signal generated in response to an active command. The signal MRSET which is a command for setting a DLL operation mode is applied a particular number of cycles (e.g., 200 cycles) after a DLL is reset, for example, according to a DDR specification. The signal DLL_LOCKED is a signal indicating that a locking time taken to reach a locking state after the DLL is turned on has elapsed (for example, the DLL has been completely locked) by a counter embedded in the MRAM.

The standby enable signal generator 392 may include a latch that has a signal DLLRESET as a RESET input and an output signal of the logic circuit 391 as a SET input. The signal DLLRESET is a signal that is generated in an MRS in order to reset the DLL 380 (see FIG. 38) and is activated for a predetermined period of time. Since the DLL 380 (see FIG. 38) performs a locking operation after the signal DLLRESET is generated, the signal DLLRESET operates the DLL for a predetermined period of time irrespective of an operation mode (e.g., an active mode or a precharge mode) of the MRAM. The standby enable signal generator 392 includes a cross coupled NOR and generates a standby enable signal STB_EN. The AND circuit 395 generates the standby signal STANDBY by performing AND on the standby enable signal STB_EN and a command signal /PCAS that indicates an operation state of the MRAM, for example, a precharge state of the MRAM.

When the signal DLLRESET is activated, the standby enable signal STB_EN that activates the standby signal STANDBY is inactivated, and when at least one of the signal PCAS, the signal MRSET, and the signal DLL_LOCKED is activated, the standby enable signal STB_EN is activated.

Accordingly, only when the MRAM is in a precharge state, for example, the signal /PCAS is activated to a logic ‘high’, and the standby enable signal STB_EN is activated, is the standby signal STANDBY activated. A case where the standby signal STANDBY is activated is referred to as a standby mode. The standby mode does not refer to an ON state where locking information is continuously updated, nor does it refer to an OFF state where all previous locking information is lost and the DLL does not operate, but refers to an operation state where locking information before a precharge state of the MRAM is maintained and predetermined circuits included in the DLL 380 (see FIG. 38) do not operate.

Accordingly, when any one of the signal PCAS, the signal MRSET, and the signal DLL_LOCKED which indicate an end to the locking state of the DLL 380 is activated, since the standby enable signal STB_EN is activated, and the standby signal STANDBY is activated when the MRAM is in a precharge state, the DLL 380 may operate in a standby mode.

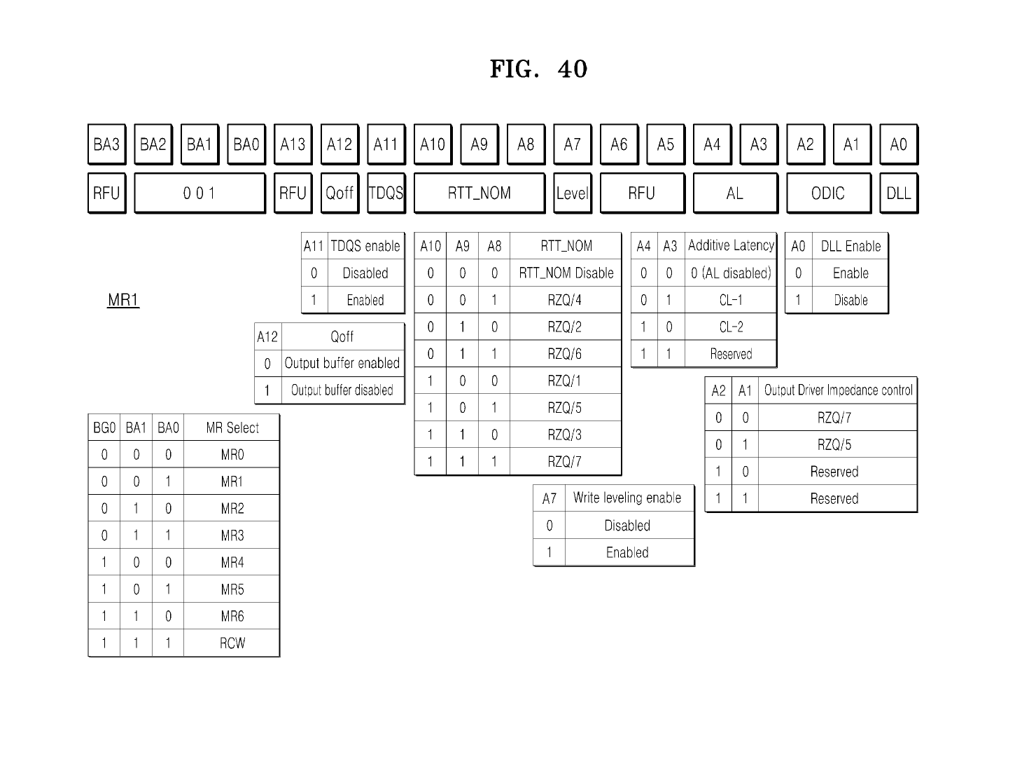

FIG. 40 is a diagram illustrating a mode register MR1 that applies the signal MRSET of FIG. 39, according to one exemplary embodiment. The mode register MR1 of FIG. 40 is one of a plurality of mode registers that program various functions, features, and modes of the MRAM 12.

Referring to FIG. 40, different modes of operations settable to the mode register MR1 and bit assignment of each mode will be explained. The mode register MR1 is selected by a “001” bit value for BG0, and BA1:BA0. The mode register MR1 stores data for controlling DLL enable/disable of the MRAM 12, output drive strength, AL, write leveling enable/disable, TDQS enable/disable, and output buffer enable/disable.

1-bit A0 is used to select DLL enable or disable of the MRAM 12. In one embodiment, the DLL 29 (see FIG. 2) needs to be enabled for normal operation. In one embodiment, the DLL 29 is enabled for the MRAM 12 to return to the normal operation during power-up initialization and after DLL disable. During the normal operation, “1” is programmed to the A0 bit. DLL enable is applied as the signal MRSET of FIG. 39.

2-bit A2:A1 is used for output driver impedance control (ODIC) of the MRAM 12. When “00” is programmed to the A2:A1 bits, output driver impedance is controlled to RZQ/7. RZQ may be set to, for example, 240Ω. When “01” is programmed, the output driver impedance is controlled to RZQ/5. “10” and “11” are reserved.

2-bit A4:A3 is used to select AL of the MRAM 12. An AL operation is supported to increase the efficiency of a command and data bus for a sustainable bandwidth. During the AL operation, a read or write command (with or without auto-precharge) may be immediately issued after an active command. Read latency (RL) is controlled based on a sum of AL and CL register settings. Write latency (WL) is controlled based on a sum of AL and CWL register settings.

When “00” is programmed to the A4:A3 bit, AL0, that is, AL disable, is set. When “01” is programmed, CL-1 is set, and when “10” is programmed, CL-2 is programmed. “11” is reserved.

1-bit A7 is used to provide a write leveling feature of the MRAM 12. For better signal integrity, an MRAM memory module employs a fly-by topology for commands, addresses, control signals, and clocks. The fly-by topology may reduce the number and length of stubs.

3-bit A10:A8 is used to provide an ODT feature of the MRAM 12. The ODT feature allows the memory controller to independently change terminal resistances of DQ, DQS_t, DQS_c, and DM_n of the MRAM 12 in order to improve signal integrity of a memory channel.

The MRAM 12 may provide various ODT features (RTT_NOM, RTT_WR, and RTT_PAR). In one embodiment, a value of nominal termination (RTT_NOM) or park termination (RTT_PARK) is selected during an operation without a command, and a value of dynamic termination (RTT_WR) is selected when a write command is registered.

When A10:A8 is programmed to “000”, RTT_NOM is disabled. When “001” is programmed, RTT_NOM is preselected as RZQ/4. RZQ may be set to, for example, 240Ω When “010” is programmed, RTT_NOM is preselected as RZQ/2, when “011” is programmed, RTT_NOM is preselected as RZQ/6, when “100” is programmed, RTT_NOM is preselected as RZQ/1, when “101” is programmed, RTT_NOM is preselected as RZQ/5, when “110” is programmed, RTT_NOM is preselected as RZQ/3, and when “111” is programmed, RTT_NOM is preselected as RZQ/7.

1-bit A11 is used to provide a TDQS function. TDQS provides additional terminal resistance outputs usable in a specific system configuration. For example, in one embodiment, TDQS corresponds only to X8 MRAM. When the A11 bit is programmed to “0”, TDQ is disabled, DM/DBI/TDQS provides a DM function, and TDQS_c is not used. X4/X16 MRAM has to disable the TDQS function by setting the A11 bit of the mode register MR1 to “0”. When the A11 bit is programmed to “1”, TDQ is enabled, and MRAM 12 enables the same termination resistance function applied to DQS_t/DQS_c in a terminal TDQS_t/TDQS_c.

1-bit A12 is used to provide an output buffer enable or disable (Qoff) function of the MRAM 12. When the A12 bit is programmed to “0”, output buffers are enabled. When the A12 bit is programmed to “1”, the output buffers are disabled. Accordingly, outputs DQs, DQS_ts, and DQS_c are also disabled.

BG1, A13, A6, and A5 bits of the mode register MR1 are reserved future usage (RFU) and are programmed to “0” during mode register setting.

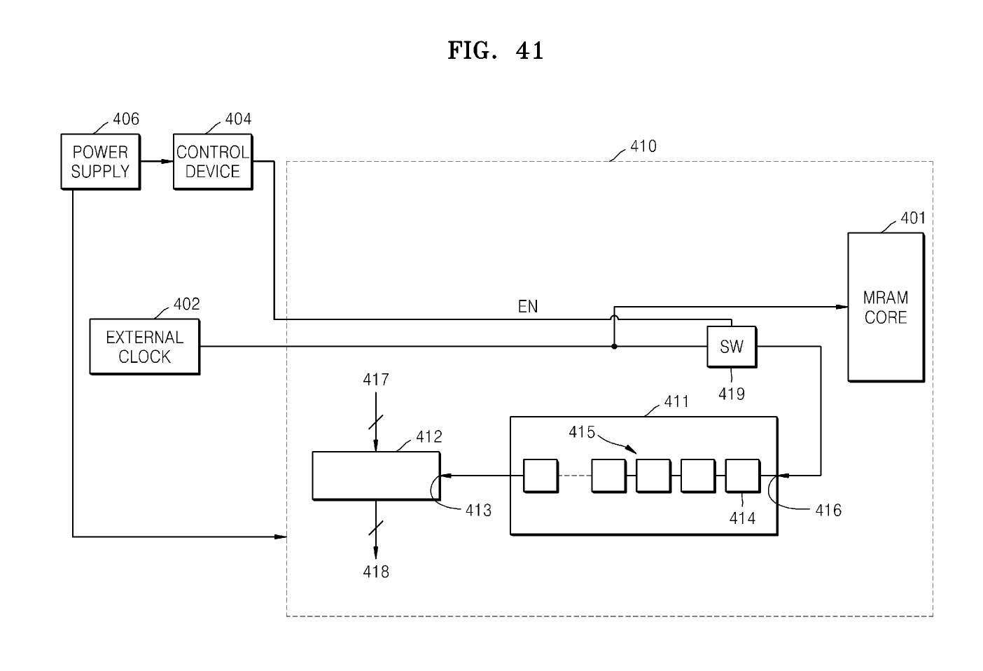

FIG. 41 is a block diagram illustrating a DLL 411 included in an MRAM 410, according to another exemplary embodiment.

Referring to FIG. 41, the MRAM 410 includes the DLL 411 and a DQ buffer 412. The DLL 411 receives a signal from an actually periodic external clock 402, and applies the signal to a DLL clock input 413 of the DQ buffer 412. In one embodiment, the external clock 402 is a free running clock received from a memory controller or another external circuit. The external clock 402 synchronizes an operation of an MRAM core array 401, and is delayed by the DLL 411.

The DLL 411 includes a delay line 415 to which a plurality of delay elements 414 are serially connected. The external clock 402 is applied to an input 416 of the serially connected delay elements 414, and is applied to the DLL clock input 413 after a predetermined period of time is delayed by the delay elements 414. As such, a delayed external clock signal is input to the DQ buffer 412 as the DLL clock input 413.

The DQ buffer 412 latches n data inputs connected to a multi-bit internal data path 417 of the MRAM 410, and outputs the n data inputs to an external data path 418. The external data path 418 may be connected to an external bus of the MRAM 410. The DQ buffer 412 latches data on the internal data path 417 in response to the DLL clock input 413 and transmits the data to the external data path 418.

States of the delay elements 414 of the delay line 415 are changed in response to a clock transition at the input 416 of the DLL 411. During the state transition, power consumed by the delay elements 414 is increased. According to a request of a system and a frequency of an external clock 402, the number of the delay elements 414 in the delay line 415 may be increased. Due to a high frequency operation of the external clock 402 and the great number of delay elements 414, a considerable amount of power may be consumed during the state transition of the delay elements 414.

When the MRAM 410 is in a power down mode, the DQ buffer 412 does not need to latch data on the internal data path 417 and transmit the data to the external data path 418. As a result, when the MRAM 410 is in a power down mode, the DLL 411 does not need to operate. When the DLL 411 does not operate, since it means that states of the delay elements 414 of the delay line 415 do not need to be changed, power consumption related to the state transition of the delay elements 414 during a power down mode may be reduced.

Therefore, in one embodiment, during a power down mode, the DLL 411 may be disabled. The MRAM 410 may include a switch circuit 419, which responds to a control signal EN disposed between the external clock 402 and the input 416 of the DLL 411. The control signal EN is applied, for example, from an external control device 404 that may include a memory controller or another external circuit. The external control device 404 applies the control signal EN that is activated when the MRAM 410 is in a normal mode, and is inactivated when the MRAM 410 is in a power down mode. A power supply unit 406 applies a power supply voltage to operate the external control device 404 and the MRAM 410.

When the control signal EN is activated, the switch circuit 419 is closed or turned on, the external clock 402 is connected to the input 416 of the DLL 411. When the control signal EN is inactivated, the switch circuit 419 is opened or turned off, connection between the external clock 402 and the input 416 of the DLL 411 is cut off. As a result, when the switch circuit 419 is opened, the external clock 402 is not applied to the input 416 of the DLL 411, and thus the state transition of the delay elements 414 of the delay line 415 in the DLL 411 does not occur.

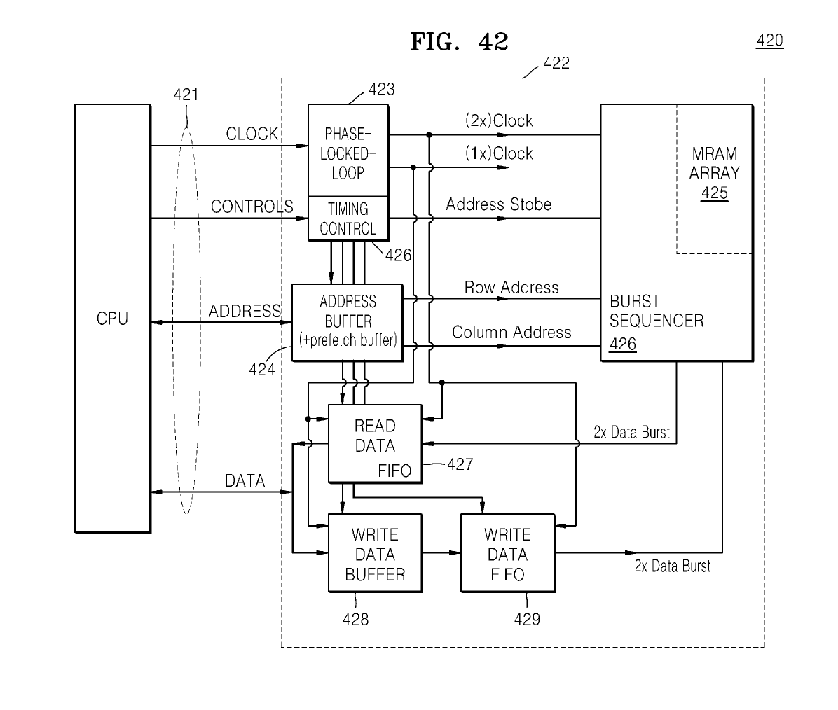

FIG. 42 is a block diagram illustrating a PLL 423 included in an MRAM 422, according to one exemplary embodiment.

Referring to FIG. 42, the MRAM 422 is connected to control, address, and data lines of a central processing unit (CPU) bus 421. The MRAM 422 includes the PLL 423, an address buffer 424, an MRAM cell array 425, a burst sequencer 425a, a timing control circuit 426, a read data FIFO 427, a write data buffer 428, and a write data FIFO 429.

The PLL 423 receives a CPU bus clock signal, generates a clock signal (1× clock signal) having the same frequency as the CPU bus clock signal, and generates a clock signal (2× clock signal) having a frequency corresponding to two times a frequency of the CPU bus clock signal. 1× and 2× clock signals have limited phases with respect to the CPU bus clock signal. The phases are selected in order to provide setup and hold times suitable for correct data transmission.

The address buffer 424 latches a CPU bus address and decodes the CPU bus address with row, column, and bank addresses of the MRAM cell array 425. The timing control circuit 426 drives an internal address strobe signal from the CPU bus address received from the address buffer 424 and a control signal received from the CPU bus 204. The address strobe, row address, column address, bank address, and 2× clock signals are applied to the burst sequencer 425a and the MRAM cell array 425. The burst sequencer 425a is used to access the MRAM cell array 425.

The address buffer 424 may further include prefetch buffers that store an address of a next access operation even while a current access operation is performed. The prefetch buffers enable a pipeline operation that may reduce latency between operations.

The MRAM cell array 425 is required to perform a normal read or write access operation after a precharge operation. A precharge time taken to perform a precharge operation is long enough to completely equalize capacitances of a sense amplifier and a bit line. That is to ensure a very small signal applied from a cell capacitor to a sense amplifier connected to a next RAS operation may be correctly and reliably read out.

For example, when the MRAM 422 is used as a cache memory along with an SRAM cache in a computer system, a precharge time of the MRAM 422 should be hidden from an access operation of the CPU bus 421. This is because an access cycle time of an SRAM is almost the same as access latency of the SRAM whereas an access cycle time of the MRAM 422 is a sum of access latency of the MRAM 422 and a precharge time. In order to match an SRAM performance in this embodiment, a precharge time of the MRAM 422 should to be hidden.

In order to hide a precharge time from an MRAM access time, the MRAM 422 includes the read data FIFO 427, the write data buffer 428, and the write data FIFO 429. A 2× clock signal is used to clock the MRAM cell array 425, a data input terminal of the read data FIFO 427, and a data output terminal of the write data FIFO 429. A 1× clock signal is used to clock a data output terminal of the read data FIFO 427 and a data input terminal of the write data buffer 428.

Data read from the MRAM cell array 425 is transmitted to the CPU bus 421 through the read data FIFO 427. Data read to the read data FIFO 427 is read at a 2× clock signal frequency, and data read to the CPU bus 421 is read at a 1× clock signal frequency. The read data FIFO 427 performs clock resynchronization.

On the contrary, data written to the MRAM cell array 425 is transmitted from the CPU bus 421 through the write data buffer 428 and the write data FIFO 429. Data transmitted to the write data buffer 428 may be transmitted at a 1× clock signal frequency and data transmitted to the write data FIFO 429 may be transmitted at a 2× clock signal frequency.

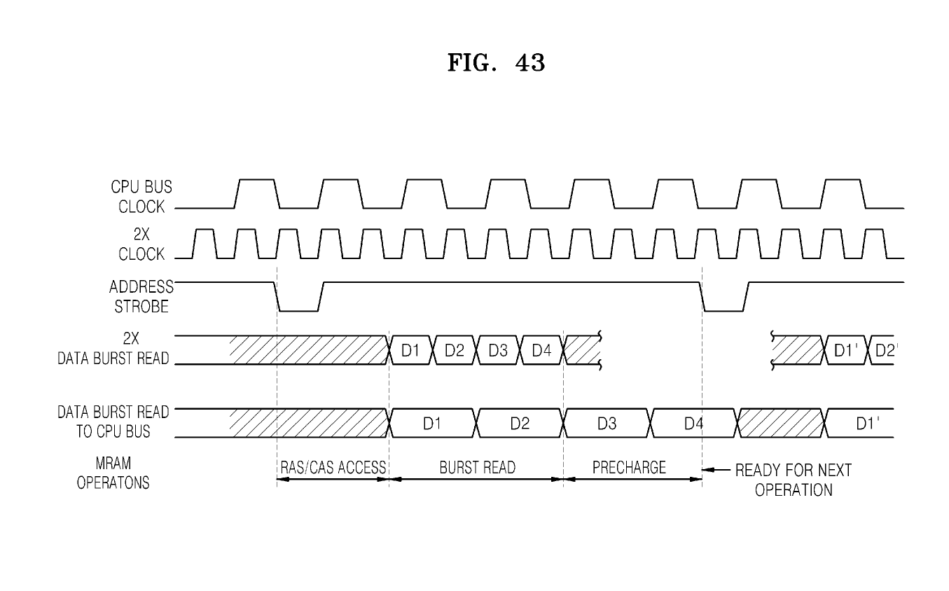

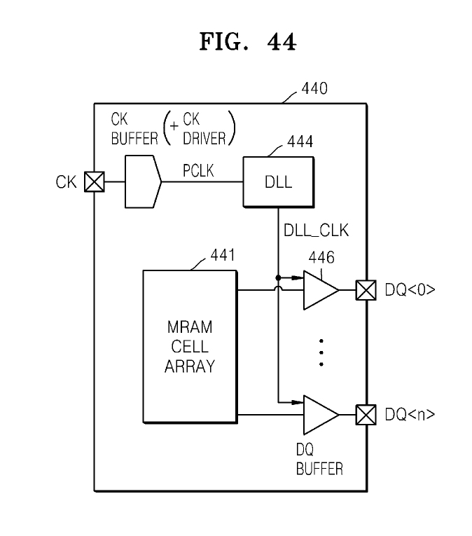

FIG. 43 is a timing diagram for explaining an operation of the MRAM 422 of FIG. 42, according to one embodiment.

Referring to FIG. 43, after an address strobe signal is generated as a low signal, RAS and CAS operations are initialized. At 2 rising clock edges after the address strobe signal is generated, the RAS and CAS operations are completed, and a burst read operation that is synchronized with a 2× clock signal is performed in the MRAM cell array 425. Burst data read from the MRAM cell array 425 is clocked to the read data FIFO 427 due to a 2× clock signal. Read burst data output from the read data FIFO 427 is transmitted to the CPU bus 204 due to a 1× clock signal. After the burst data is read, the MRAM 422 may perform a precharge operation that prepares for a next operation.

Since read burst data is written to the read data FIFO 427 due to a 2× clock signal, there is a time to perform a precharge operation before data of the read data FIFO 427 is completely transmitted to the CPU bus 204 due to a 1× clock signal. Accordingly, a precharge time of the MRAM 422 may be hidden from the CPU bus 204.

FIG. 44 is a circuit diagram illustrating a DLL 444 included in an MRAM 440, according to another exemplary embodiment.

Referring to FIG. 44, the MRAM 440 includes an MRAM cell array 441, a clock buffer 442, the DLL 444, and a plurality of DQ buffers 446. The clock buffer 442 receives an external clock signal CK, and transmits a buffered internal clock signal PCLK to the DLL 444. The clock buffer 442 may further include a clock driver that appropriately drives the internal clock signal PCLK in consideration of loads of circuit blocks to which the internal clock signal PCLK is applied.

Since the internal clock signal PCLK is generated by being delayed from the external clock signal CK by the clock buffer 442, a phase difference inevitably exists between the external clock signal CK and the internal clock signal PCLK. Due to the phase difference, when the external clock signal CK is applied, an internal operation of the MRAM 440 is delayed by the phase difference.

The DLL 444 generates a DLL clock signal DLL_CLK that minimizes a skew between the external clock signal CK and the internal clock signal PCLK so that the external clock signal CK and the internal clock signal PCLK have the same phase As such, the external clock signal CK and the internal clock signal PCLK are completely synchronized with each other. The DLL clock signal DLL_CLK is applied to the DQ buffers 446 that latch data read from the MRAM cell array 441. Each of the DQ buffers 446 latches corresponding read data in response to the DLL clock signal DLL_CLK and outputs the read data to a DQ pad (DQ<n:0>).

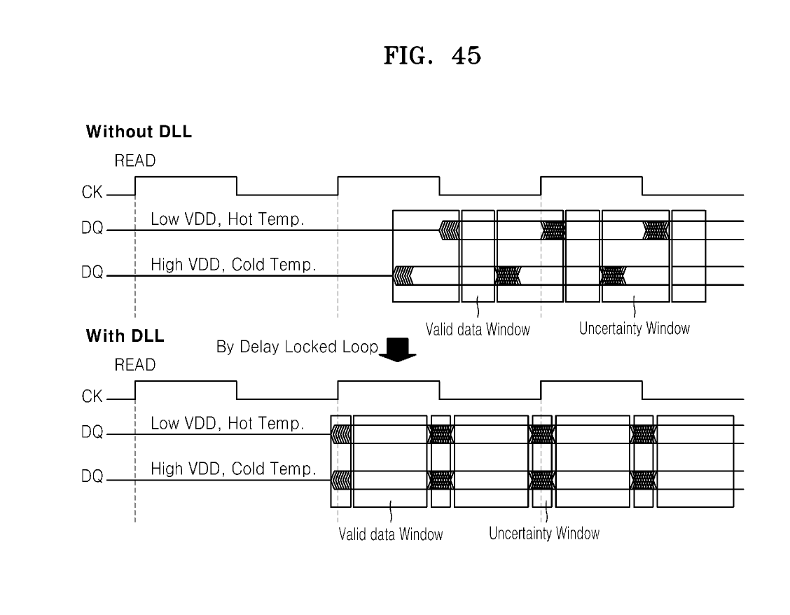

FIG. 45 is a diagram for explaining an operation of the DLL 444 of FIG. 44, according to one exemplary embodiment.

Referring to FIG. 45, a case where the DLL 444 does not operate and a case where the DLL 444 operates will be explained. When the DLL 444 does not operate, data is output to the DQ pad after an irregular delay time from a rising edge of the external clock signal CK synchronized with a read command READ. This is because pieces of read data are irregularly delayed and output according to a signal line load, a power supply voltage, a temperature change, and so on, thereby reducing an effective data window.

When the DLL 444 operates, pieces of data are output to the DQ pad after a predetermined delay time from a rising edge of the external clock signal CK synchronized with the read command READ. This is because the DLL clock signal DLL_CLK synchronized with the external clock signal CK is generated after a signal line load, a power supply voltage and temperature change, and so on are compensated for by the DLL 444, thereby increasing an effective data window of read data latched in response to the DLL clock signal DLL_CLK.

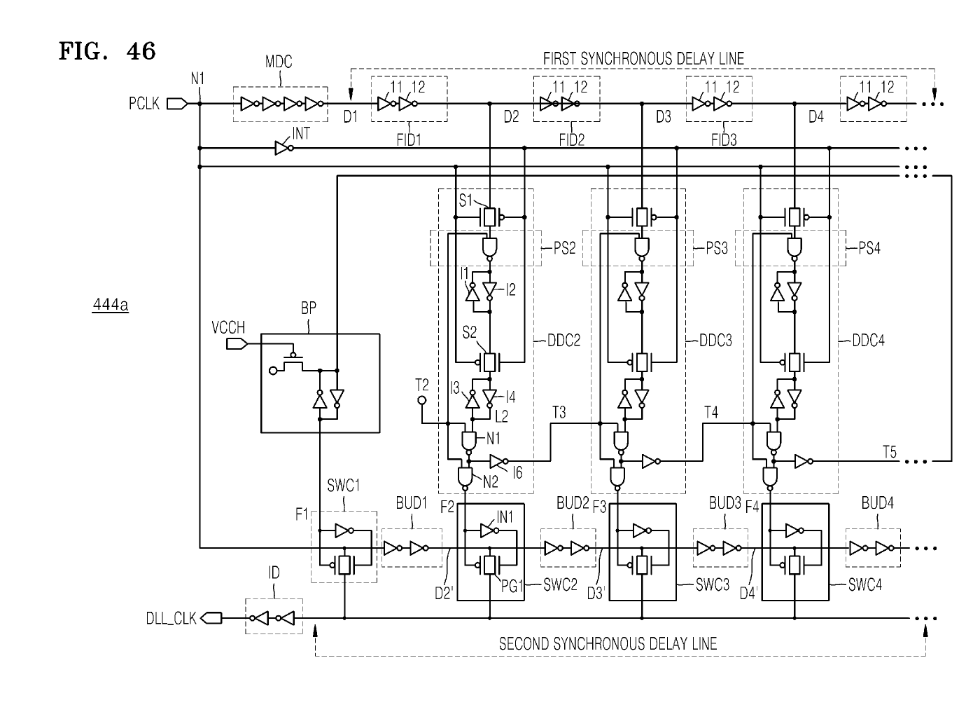

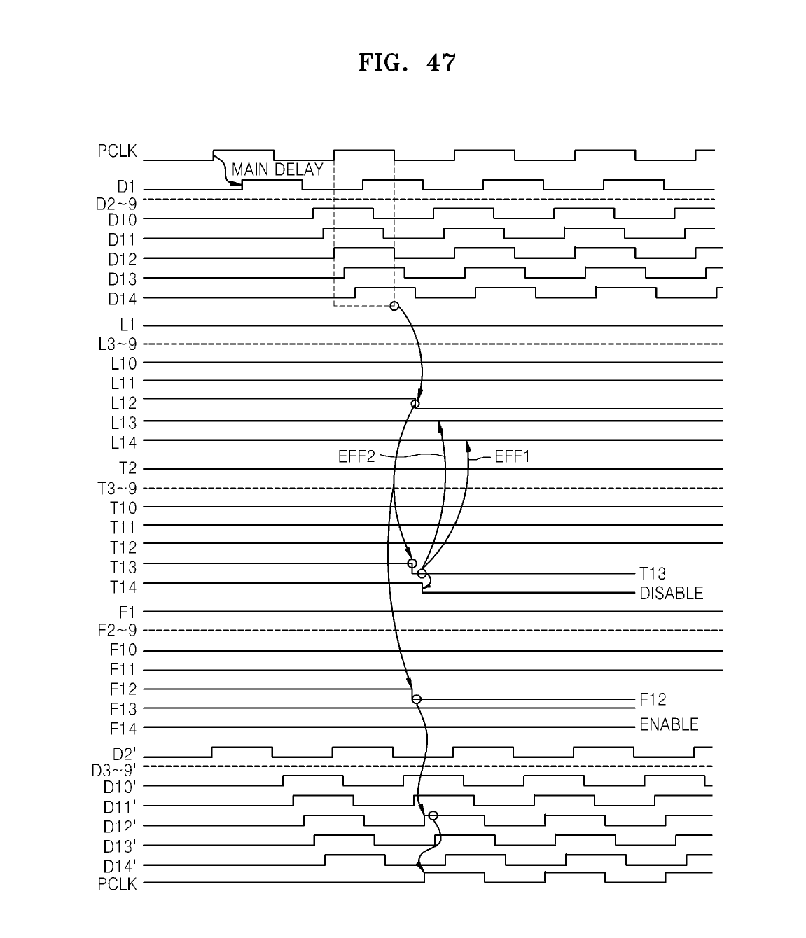

FIG. 46 is a circuit diagram illustrating a DLL 444a included in the MRAM 440, according to another exemplary embodiment.

Referring to FIG. 46, the DLL 444a is a digital DLL in the MRAM 440 of FIG. 44. The digital DLL 444a includes a main delay unit MDC, first unit delay units FID1 through FIDn, phase delay detectors DDC2 through DDCn, switches SWC1 through SWCn, second unit delay units BUD1 through BUDn, an internal delay unit ID, and a bypass unit BP.

An internal clock signal PCLK is applied to the main delay unit MDC, the plurality of phase delay detectors DDC2 through DDCn, and a second synchronization delay line. A clock D1 output from the main delay unit MDC is applied to a first synchronization delay line to which the first unit delay units FID1 through FIDn are serially connected. The first unit delay units FID1 through FIDn outputs clocks D2 through Dn obtained by delaying the clock D1. The second synchronization delay line is configured such that the plurality of second unit delay units BUD1 through BUDn having the same delay time as the first unit delay units FID1 through FIDn are serially connected. The switches SWC1 through SWCn that select one of clocks D2′ through Dn′ obtained by delaying a predetermined unit time or the internal clock signal PCLK in response to enable signals F1 through Fn and applies the selected signal as the internal clock signal PCLK are connected between the second unit delay units BUD1 through BUDn.

The internal clock signal PCLK generates a clock D1 by being delayed by a predetermined period of time by the main delay unit MDC. The internal clock signal PCLK is sequentially delayed by the second unit delay units BUD1 through BUDn which are serially connected in the second synchronization delay line and delayed clocks D2′ through Dn′ are output from output nodes. The clocks D2′ through Dn′ are outputs preceding the clock D1 that is an output of the main delay unit MDC. Unless the switches SWC1 through SWCn connected between the internal clock signal PCLK and output nodes of the clocks D2′ through Dn′ are turned on by the enable signals F1 through Fn, the internal clock signal PCLK is not generated.

The clock D1 output from the main delay unit MDC is output as clocks D2 through D14 by being sequentially delayed by the first unit delay units FID1 through find, which are serially connected in the first synchronization delay line. The clocks D2 through Dn output from the first unit delay units FID1 through FIDn are applied to transmission switches S1 of the phase delay detectors DDC2 through DDCn. Each of the transmission switches S1 includes a transmission gate that is switched in response to the internal clock signal PCLK and an output node of an inverter INT that inverts the internal clock signal PCLK.

The phase delay detectors DDC2 through DDCn input and compare phases of the clocks D2 through Dn with phases of carry output terminals Ti+1 of the phase delay detectors DDC2 through DDCn at front ends, and output a comparison result to the carry output terminals Ti+1 of the corresponding phase delay detectors DDC2 through DDCn. Each of the phase delay detectors DDC2 through DDCn includes transmission switches S1 and S2, operation blocking unit PS2 through PSn, latch units I1, I2, I3, and I4, NAND gates N1 and N2, and an inverter I6.

Output nodes of the transmission nodes S1 in the phase delay detectors DDC2 through DDCn are connected to one input of each of the operation blocking units PS2, PS3, and PS4, and outputs of the operation blocking units PS2, PS3, and PS4 are connected to input nodes of the first latches I1 and I2. When the internal clock signal PCLK is a logic high signal, the transmission switch S1 is turned on and clocks D2 through D14 which are outputs of the first unit delay units FID1 through FIDn are applied to the one input of each of the operation blocking units PS2, PS3, and PS4. When phases are not synchronized, a logic high signal is input to other inputs of the operation blocking units PS2, PS3, and PS4. The operation blocking units PS2, PS3, and PS4 invert phases of the clocks D2 through D14 applied to the one input of each thereof and output the inverted clocks D2 through D14. In this case, the operation blocking units PS2, PS3, and PS4 operate as phase inverting transmission switches.

The operation blocking units PS2 through PSn include NAND gates that block internal operations of the phase delay detectors DDC2 through DDCn to save power. One input of each of the operation blocking units PS2 through PSn is connected to the transmission switches S1, and the other input of each of the operation blocking units PS2 through PSn is connected to the carry output terminals T1 of the phase delay detectors DDC2 through DDCn at the front ends.

For example, in the operation blocking unit PS3, an output of the carry output terminal T3 of the phase delay detector DDC2 is input to the other side of the NAND gate. An output of the operation blocking unit PS2 is applied to inputs of the first latches I1 and I2. When phases of two signals in the phase delay detector DDC2 are synchronized, the carry output terminal T3 of the phase delay detector DDC2 is output as a logic low. The operation blocking unit PS3 is fixed to a logic high irrespective of a logic state of one input of the NAND gate, and inputs of the first latches I1 and I2 are fixed to a logic high. The first latches I1 and I2 whose inputs are fixed to a logic high do not perform their latch operations and are finally disabled, to block an operation of the phase delay detector DDC3. Accordingly, all of the internal operations of the phase delay detection units DDC3 through DDCn provided at a rear end of the phase delay detector DDC2 whose phase is synchronized are blocked so as not to consume a current, thereby saving power.

The first latches I1 and I2 latch inverted clocks D2 through D14 output from the operation blocking units PS2, PS3, and PS4 until the transmission switch S2 is turned on. An input of the transmission switch S2 is connected to an output node of the first latches I1 and I2, and the transmission switch S2 is turn on when the internal clock signal PCLK is a logic low signal. An output of the transmission switch S2 is latched by the second latches I3 and I5. An output node Li of the second latches I3 and I4 is applied to carry generators N1, N2, and I6.

The carry generators N1, N2, and I6 activate an enable signal output to the output node Fi only when the output node Li of the second latches I3 and I4 is a logic low and disable a carry output signal Ti+1. For example, when the carry input terminal T3 is a logic high and a node L3 is a logic low, an output F3 of a NAND gate N2 becomes a logic low. When a node F3 is enabled to a logic low, the switch SWC3 is turned on, and the carry output terminal T4 becomes a logic low and is disabled. This is a case where an enable signal output to the node F3 is activated and the delayed clock D3 and the internal clock signal PCLK are synchronized without a phase delay difference therebetween.

When the first and second synchronization delay lines are not synchronized to the end, the bypass unit BP receives a carry output of the phase delay detector DDCn and bypasses the internal clock signal PCLK to the DLL clock signal DLL_CLK. When the internal clock signal PCLK having a frequency greater than a delay time of delay lines is applied by the bypass unit BP, the internal clock signal PCLK is bypassed to the DLL clock signal DLL_CLK due to an operation of the switch SWC1. The internal delay unit ID is provided at a final end in order to make an output time and a level of the DLL clock signal DLL_CLK more accurate.

FIG. 47 is a timing diagram for explaining an operation of the DLL 444a of FIG. 46, according to one embodiment.

Referring to FIG. 47, when a phase of a delayed clock D12 of the first synchronization delay line is matched to a phase of the internal clock signal PCLK, an output end L12 of a second latch is output as a logic low, a carry output terminal T13 is disabled to a logic low, and F12 is enabled to a logic low. Accordingly, a delayed clock D12′ of the second synchronization delay line passes through a corresponding switch and is output as the DLL clock signal DLL_CLK.

When the carry output terminal T13 is disabled to a logic low, output ends L14, . . . , and Ln after an output end L13 of the second latch are not changed to a logic low due to operations of the operation blocking units PS13 through PSn. Since a logic low signal is output according to phase matching to the carry output terminal T13 of the phase delay detector to which the second latch having the output end L12 belongs, the carry output terminal T13 at logic low is applied to an input of the operation blocking unit of the phase delay detector having the output end L13, and an input of a first latch is fixed to a logic high.

An output of the first latch whose input is fixed to a logic high becomes a logic low, and thus the output L13 of the second latch is a logic high. Since the first and second latches do not latch a clock signal and are disabled, an operation of the phase delay detector to which the first and second latches belong is blocked. As indicated by arrows EFF1 and EFF2, power is saved.

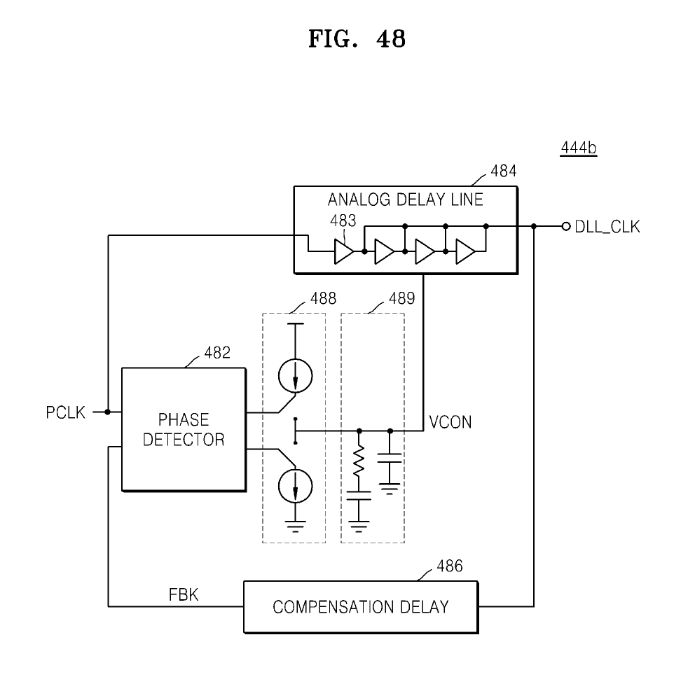

FIG. 48 is a circuit diagram illustrating a DLL 444b included in the MRAM 440, according to another exemplary embodiment.

Referring to FIG. 48, the DLL 444b is an analog DLL in the MRAM 440 of FIG. 44. The analog 444b includes a phase detector 482, an analog delay line 484, a compensation delay circuit 486, a charge pump 488, and an analog loop filter 489.

The phase detector 482 compares a phase of the internal clock signal PCLK with a phase of a feedback clock signal FBK. The charge pump 488 generates a voltage control signal VCON in response to a comparison result of the phase detector 482. The analog delay line 484 includes a plurality of delay elements that input the internal clock signal PCLK, and output the DLL clock signal DLL_CLK in response to the voltage control signal VCON. The compensation delay circuit 486 inputs the DLL clock signal DLL_CLK, and outputs the feedback clock signal FBK by compensating for a load on a line path through which read data of the MRAM cell array 444 (see FIG. 44) is transmitted.

The phase detector 482 has no dead zone. The analog delay line 484 includes a plurality of delay elements 483 that provide minimum jitter. The DLL 444b integrates a phase difference, that is, a phase error, on a capacitor in the loop filter 489. Since the phase error is integrated on the capacitor and the phase detector 482 has no dead zone, the DLL 444b provides low clock jitter and precise resolution.

In order to reduce jitter of the DLL clock signal DLL_CLK, a bandwidth of the DLL 444b may be reduced. A bandwidth may be reduced by increasing a capacitance of the loop filter 489 and reducing a current of the charge pump 489. In the reduced bandwidth (fine adjustment), when the internal clock signal PCLK and the feedback clock signal FBK have a zero phase error, all up/down cycles of the phase detector 482 adjust the DLL clock signal DLL_CLK by a small amount or none. In a coarse adjustment, a bandwidth of the DLL 444b may be increased by reducing a size of the capacitor and increasing a current of the charge pump 489. In the increased bandwidth, all up/down cycles of the phase detector 482 may adjust a phase of the DLL clock signal DLL_CLK with a larger amount than that in the fine adjustment.

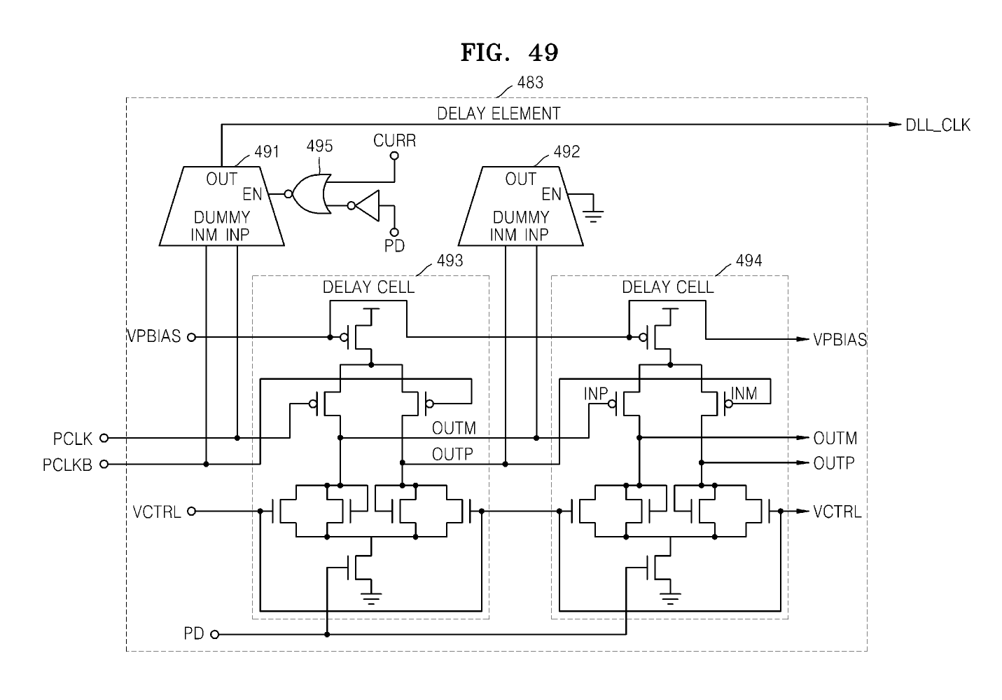

FIG. 49 is a circuit diagram illustrating the delay elements 483 in the analog delay line 484 of FIG. 48, according to one exemplary embodiment.

Referring to FIG. 49, each of the delay elements 483 includes first and second amplifiers 491 and 492, and first and second delay cells 493 and 494. The first and second amplifiers 491 and 492 may be CMOS differential amplifiers. An output of the first amplifier 491 may be an output of the delay element 492, and may be applied as the DLL clock signal DLL_CLK. The second amplifier 492 is used as a dummy amplifier. The second amplifier 492 is disabled when an enable input signal is applied to a source of a ground voltage VSS. The second amplifier 492 is used to match coupling to a load of the first amplifier 491.

An enable signal of the first amplifier 491 is applied to a control logic circuit 495. The control logic circuit 495 generates an enable signal in response to a power down signal PD and a signal CURR indicating whether a delay element before a corresponding delay element is enabled.

The first and second delay cells 493 and 494 may be realized as PFET differential amplifiers having a parallel diode load along with a voltage control load. The first delay cell 493 detects and amplifies voltage levels of an internal clock signal pair PCLK and PCLKB and generates output signals OUTM and OUTP. Output signals of the first delay cell 493 are applied to an input signal pair INP and INM of the second delay cell 494. Output signals OUTM and OUTP of the second delay cell 494 are applied to an input signal pair of a delay element next to the corresponding delay element. The first and second delay cells 493 and 494 are disabled by the power down signal PD, thereby reducing current consumption.

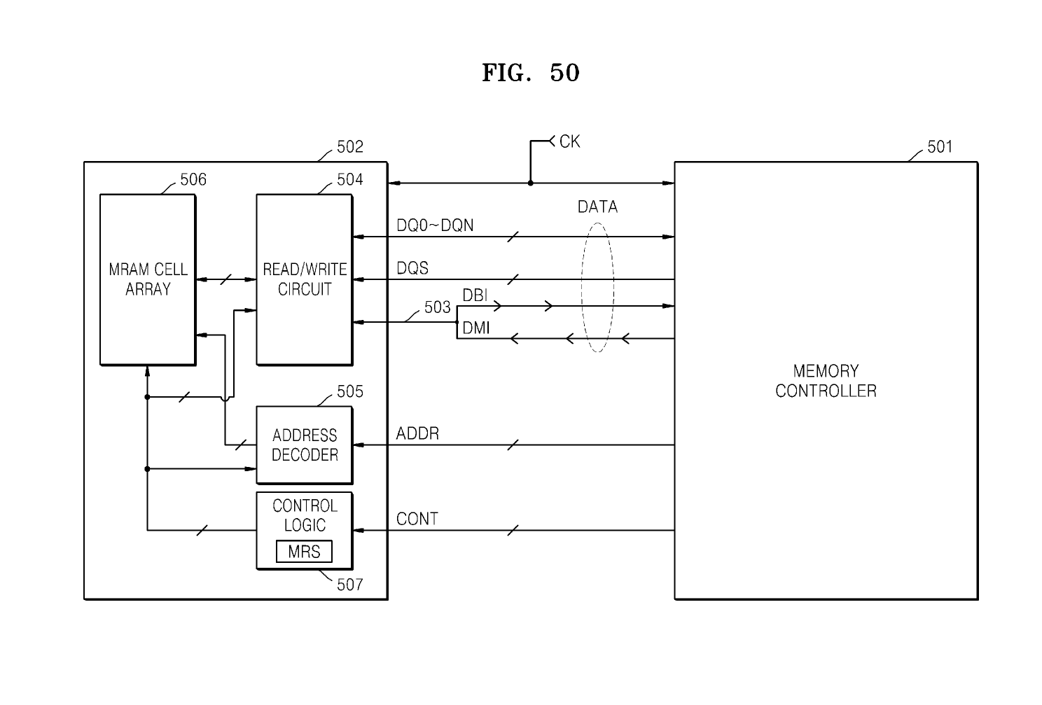

FIG. 50 is a block diagram illustrating an MRAM 502 according to another exemplary embodiment.

Referring to FIG. 50, the MRAM 502 is connected to a memory controller 501 through an address bus ADDR, a data bus DATA, and a control bus CONT. An external clock signal CK is applied to the MRAM 502 and the memory controller 501. Data transmission on the buses ADDR, DATA, and CONT occurs at a relatively appropriate time with respect to edges of the clock signal CK in order for a receiving device to successfully capture transmission data.

The data bus DATA includes a data strobe signal DQS. The data strobe signal DQS is applied by the MRAM 502 to the data bus DATA along with read data words DQ0 through DQN, and the memory controller 501 uses the data strobe signal DQS in order to successfully capture read data words. In a write operation, the memory controller 501 applies the data strobe signal DQS to the data bus DATA along with write data words DQ0 through DQN, and the MRAM 502 uses the data strobe signal DQS in order to successfully capture write data.

The MRAM 502 includes an address decoder 505 that receives and decodes address bits through the address bus ADDR from the memory controller 501, and applies the decoded address signals to an MRAM cell array 506. In the MRAM cell array 502, STT-MRAM cells for storing data bits are arranged in rows and columns. Data stored in each of the STT-MRAM cells is accessed in response to a decoded address signal and is transmitted to a read/write circuit 504.

The MRAM 502 includes a control logic unit 507 that receives a plurality of control signals applied to the external control bus CONT. In response to the control signals, the control logic unit 507 generates a plurality of control and timing signals for controlling operations and timings of the address decoder 505, the MRAM cell array 506, and the read/write circuit 504 during an operation of the MRAM 502. The control logic unit 507 may include a mode register MRS that provides a plurality of operation options of the MRAM 502. The mode register MRS may program various functions, features, and modes of the MRAM 502.

The MRAM 502 transmits data inversion information to the memory controller 501 through a data masking pin 503 during a read data transmission operation. In order to minimize bit switching between continuous read data words, the MRAM 502 selectively outputs true or inverted read data words DQ0 through DQN to the data bus DATA, and activates a data bus inversion signal DBI on the data masking pin 503 when inverted data is output.

The MRAM 502 includes the read/write circuit 504 that transmits data words DQ0 through DQN to the external data bus DATA and receives the data words DQ0 through DQN from the memory controller 501. In a write operation, the memory controller 501 applies write data words DQ0 through DQN and a data strobe signal DQS to the data bus DATA, and the read/write circuit 504 stores the write data words DQ0 through DQN in response to rising/falling edges of the data strobe signal DQS. In a read operation, the read/write circuit 504 applies read data words DQ0 through DQN and a data strobe signal DQS to the data bus DATA, and the memory controller 501 stores the read data words DQ0 through DQN in response to rising/falling edges of the data strobe signal DQS. The read/write circuit 504 receives a data masking signal DM applied to the data masking pin 503, and masks the write data words DQ0 through DQN in response to the data masking signal DM during a write operation.

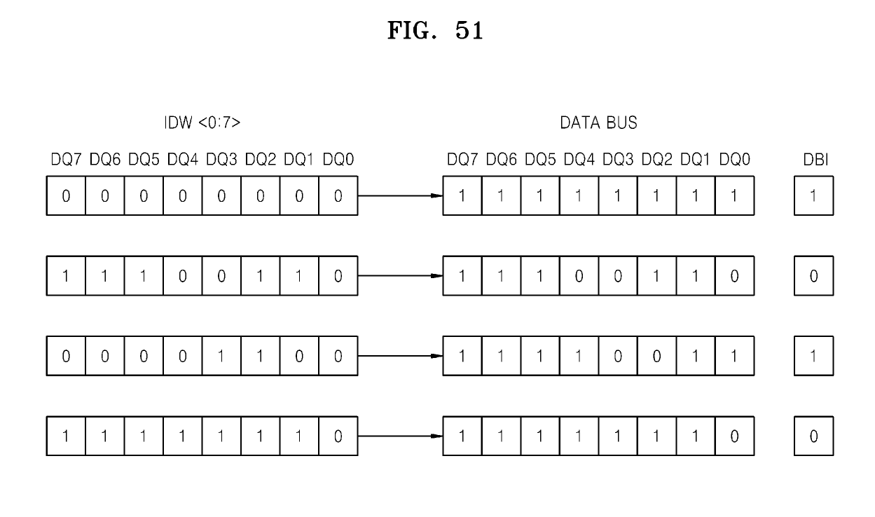

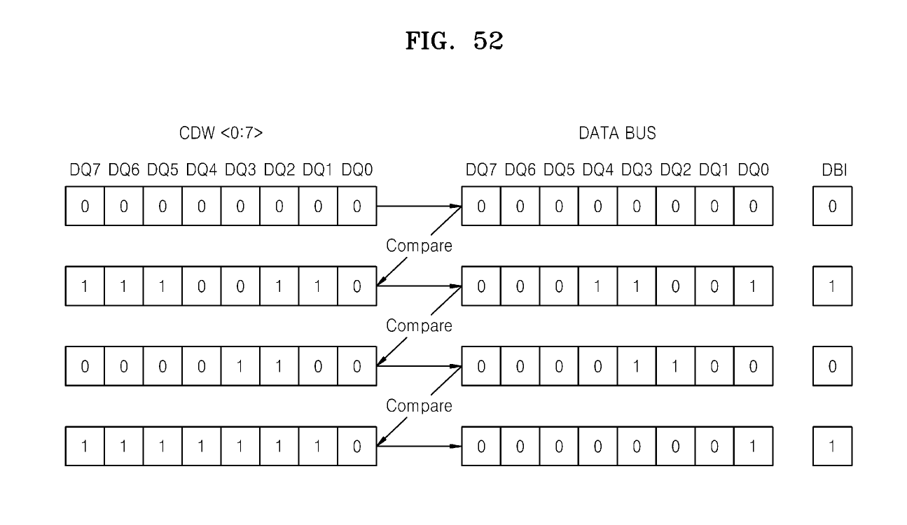

FIGS. 51 and 52 are diagrams for explaining an operation of the read/write circuit 504 of FIG. 50, according to one exemplary embodiment.

FIG. 51 is a diagram for explaining a DC type data bus inversion method that minimizes a data pattern of a logic low. FIG. 52 is a diagram for explaining an AC type data inversion method that minimizes a change from a previous data pattern.

Referring to FIG. 51, when internal read data words DQ0 through DQ7 IDW<0:7> read from the MRAM cell array 506 are “00000000”, the read/write circuit 504 counts the number of logic low data bits of the internal read data words IDW<0:7> and when the number is equal to or greater than half, outputs inverted internal read data words IDW<0:7> “11111111” to the data bus DATA. As such, the read/write circuit 504 serves as a data bus inverter by inverting the data to be output to the data bus DATA. The inversion is performed by bit switching (e.g., switching “0” bits for “1” bits, and switching “1” bits for “0” bits. In this case, the data bus inversion signal DBI is activated to a logic “1”.

When the internal read data words DQ0 through DQ7 IDW<0:7> are “11100110”, since a counted number of logic low data bits is equal to or less than half, the read/write circuit 504 outputs true internal read data words IDW<0:7> “11100110” to the data bus DATA. In this case, the data bus inversion signal DBI is inactivated to a logic “0”. When the internal read data words DQ0 through DQ7 IDW<0:7> are “00001100”, the read/write circuit 504 outputs inverted internal read data words IDW<0:7> “11110011” to the data bus DATA, and the data bus inversion signal DBI is activated to a logic “1”. When the internal read data words DQ0 through DQ7 IDW<0:7> are “11111110”, the read/write circuit 504 outputs true internal read data words IDW<0:7> “11111110” to the data bus DATA, and the data bus inversion signal DBI is activated to a logic “0”. As a result of this method, a number of logic low bits in a data pattern of data words can be minimized.

Referring to FIG. 52, it is assumed that current read data words DQ0 through DQ7 CDW<0:7> “00000000” read from the MRAM cell array 506 are output to the data bus DATA, and the data bus inversion signal DBI is inactivated to a logic “0”. Next, when current read data words DQ0 through DQ7 CDW<0:7> are read as “11100110”, the read/write circuit 504 compares “11100110” with the data pattern “00000000” of the previous read data words DQ0 through DQ7 on the data bus DATA, and in order to minimize a pattern change, inverts the current read data words DQ0 through DQ7 CDW<0:7> and outputs “00011001” to the data bus DATA. In this case, the data bus inversion signal DBI is activated to a logic “1”.

Next, when current read data words DQ0 through DQ7 CDW<0:7> are read as “00001100”, the read/write circuit 504 compares “00001100” with the data pattern “00011001” of the previous read data words DQ0 through DQ7 on the data bus DATA, outputs the current read data words DQ0 through DQ7 CDW<0:7> “00001100” which causes a minimum pattern change, and inactivates the data inversion signal DBI to a logic “0”. Next, when current read data words DQ0 through DQ7 CDW<0:7> are read as “11111110”, the read/write circuit 504 compares “11111110” with the data pattern “00001100” of the previous read data words DQ0 through DQ7 on the data bus DATA, outputs inverted current read data words DQ0 through DQ7 CDW<0:7> “00000001” which causes a minimum pattern change to the data bus DATA, and inactivates the data bus inversion signal DBI to a logic “1”.

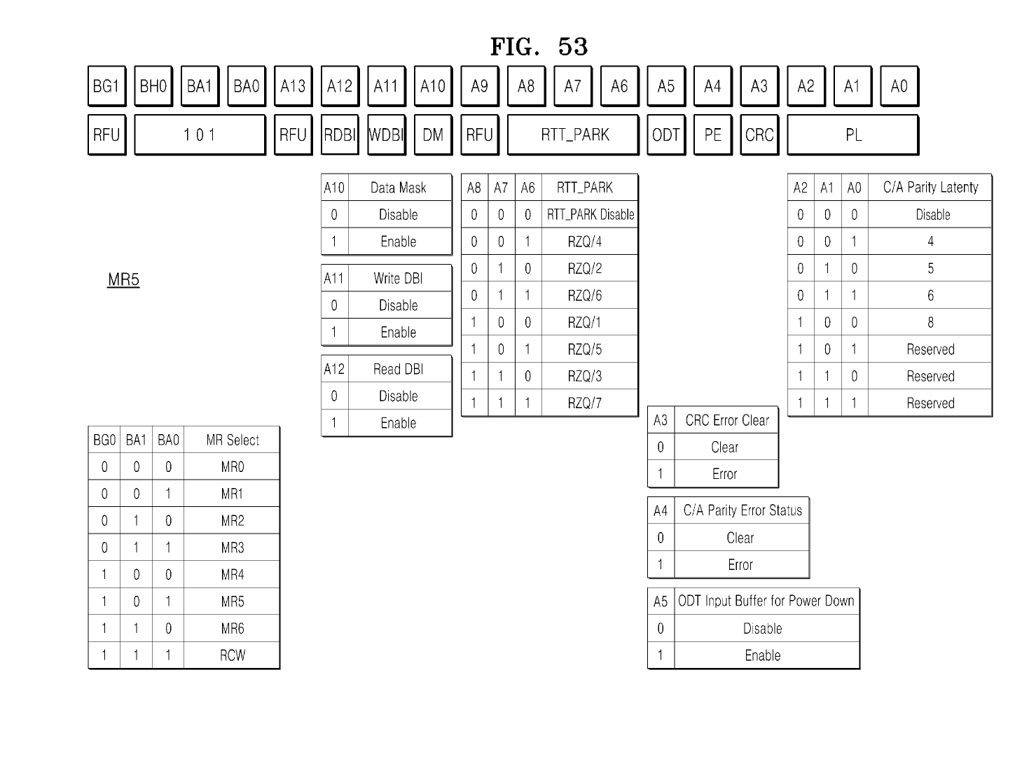

FIG. 53 is a diagram illustrating the mode register MRS included in the control logic unit 507 of FIG. 50, according to one exemplary embodiment.

A mode register MR5 of FIG. 53 is one of a plurality of mode registers that program various functions, features, and modes of the MRAM 502.

Referring to FIG. 53, different modes of operation settable to the mode register MR5 and bit assignment of each mode will be explained. The mode register RM5 is selected by a “101” bit value for BG0, and BA1:BA0. The mode register RM5 stores data for controlling a C/A parity function, a CRC error state, a C/A parity error state, an ODT input buffer power down function, a data mask function, a write DBI function, and a read DBI function.

3-bit A2A0 is used to provide a C/A parity (PL) function. A C/A parity supports a parity calculation of a command signal and an address signal. A default state of CA/A parity bits is disabled. A C/A parity is enabled by programming a non-zero value other than “0” during C/A parity latency, and in this case, the MRAM 502 confirms that there is no parity error before a command is performed. When the C/A parity latency is enabled and is applied to all commands, an additional delay for performing the command is programmed.

When “000” is programmed to the A2:A0 bit, a C/A parity is in a disable state. When “001” is programmed to the A2:A0 bit, C/A parity latency is set to 4 clock cycles. When “010” is programmed, 5 clock cycles are set, when “011” is programmed, 6 clock cycles are set, and when “100” is programmed, 8 clock cycles are set. “101”, “110”, and “111” are undetermined.

1-bit A3 is used to notify a CRC error (CRC) state of the MRAM 502. A CRC error state supports the memory controller 501 to determine whether an error generated in the MRAM 502 is a CRC error or an address/parity error. When a CRC error is detected, “1” is programmed to the A3 bit and, otherwise, “0” is programmed.

1-bit A4 is used to notify a C/A parity error (PE) state of the MRAM 502. A parity error state supports the memory controller 501 to determine whether an error generated in the MRAM 502 is a CRC error or an address/parity error. When a parity error is detected, “1” is programmed to a A4 bit, and otherwise, “0” is programmed.

1-bit A5 bit is used to control an ODT input buffer power down (ODT) function of the MRAM 502. When “0” is programmed to the A5 bit, a power down of an ODT input buffer is set to disable, and when “1” is programmed, the power down is set to enable.

3-bit A8:A6 is used to control an ODT park termination (RTT_PARK) feature of the MRAM 502. A park termination may be previously determined in a high-Z state without a command. A park termination is turned on when an ODT pin is “low”.

When “000” is programmed to the A8:A6 bit, a park termination is disabled. When “001” is programmed to the A8:A6 bit, a park termination value is set to RZQ/4. When “010” is programmed, the park termination value is set to RZQ/2, when “011” is programmed, the park termination value is set to RZQ/6, when “100” is programmed, the park termination value is set to RQZ/1, when “101” is programmed, the park termination value is set to RZQ/5, when “110” is programmed, the park termination value is set to RZQ/3, and when “111” is programmed, the park termination value is set to RZQ/7. RZQ may be set to, for example, 240 Q.

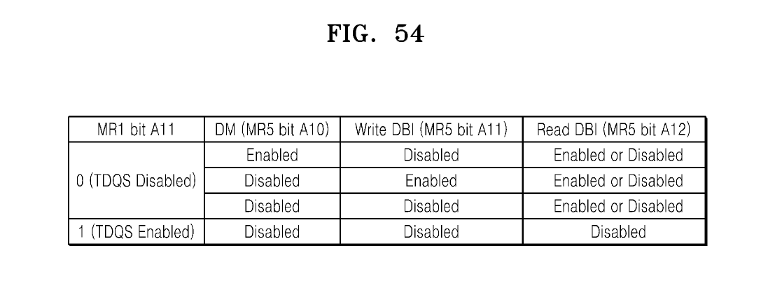

1-bit A10 is used to provide a DM function of the MRAM 502. The MRAM 502 supports a DM function and a DBI function. In a write operation of the MRAM 502, any one of the DM function or the DBI function may be enabled, but both the DM and DBI functions may not be simultaneously enabled. If both the DM and DBI functions are disabled, the MRAM 502 turns off an input receiver. Only the DBI function is provided during a read operation of the MRAM 502. When a TDQS function is enabled, the DM and DBI functions are not supported. The DM, DBI, and TDQS functions provided by the mode register are summarized as shown in FIG. 54.

When “0” is programmed to the A10 bit, the DM function is disabled. When “1” is programmed to the A10 bit, the DM function is enabled. In a write operation of the MRAM 502, when the DM function is enabled, the MRAM 502 masks write data received to DQ inputs.

1-bit A11 is used to provide a write DBI function of the MRAM 502. The DBI function is supported to reduce power consumption of the MRAM 502. When a transmission line of the MRAM 502 is terminated to a power supply voltage Vdd, more current is consumed to transmit a signal of a low level than a signal of a high level. When the number of bits of a high level is greater than the number of bits of a low level from among transmission data, the transmission data may be inverted such that the number of bits of a low level is equal to or less than half the number of all bits of the transmission data, and then may be transmitted. In this case, a signal indicating that the transmission data has been inverted may be additionally transmitted.

When a write DBI function is enabled, the MRAM 502 inverts write data received to the DQ inputs. When “0” is programmed to the A11 bit, the write DBI function is disabled. When “1” is programmed to the A11 bit, the write DBI function is enabled.

1-bit A12 is used to provide a read DBI function of the MRAM 502. When the read DBI function is enabled, the MRAM 502 inverts read data transmitted to DQ outputs. When “0” is programmed to the A12 bit, the read DBI function is disabled. When “1” is programmed to the A12 bit, the read DBI function is enabled.

BG1, A13, and A9 bits of the mode register RM5 are RFU, and are programmed to “0” during mode register setting.

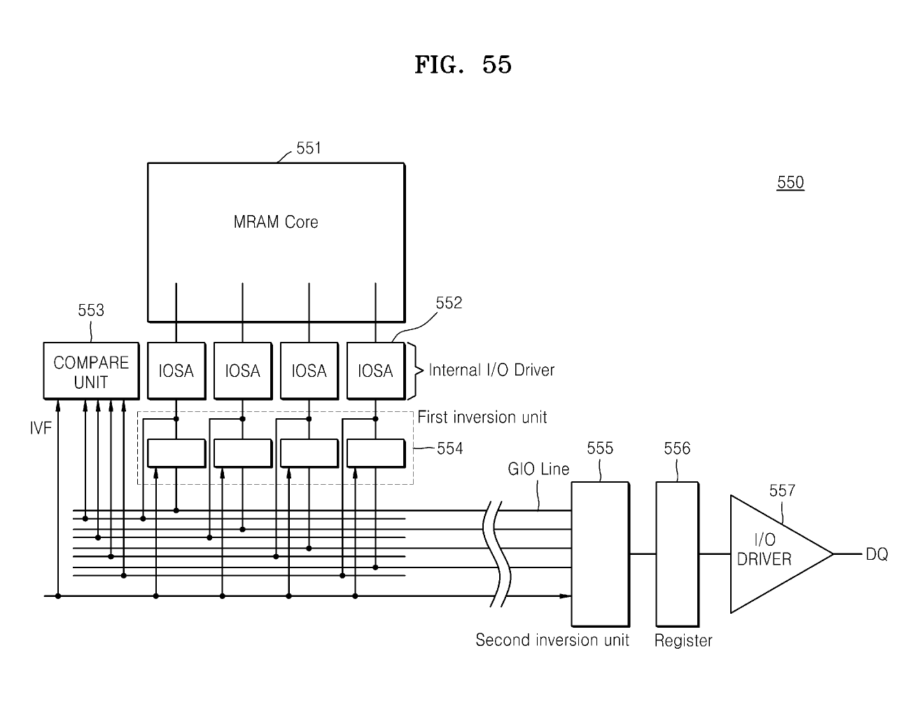

FIG. 55 is a block diagram illustrating an MRAM 550 according to another exemplary embodiment.

Referring to FIG. 55, the MRAM 550 realizes a 4-bit prefetch scheme by using one data I/O pin DQ. The MRAM 550 may further include a necessary number of data I/O pins DQs for communication with the outside. An MRAM core block 551 including an STT_MRAM cell array has an operation frequency slower than an operation frequency of an external clock. In order to output data synchronized with the external clock, 4 pieces of internal I/O data are simultaneously output to 4 internal I/O drivers (IOSAs) 552 from the MRAM core block 551 by one access.

The MRAM 550 includes a data comparator 553 and first and second sets of data inverters 554 and 555 (first and second inversion units) in order to control internal I/O data transmission. The data comparator 553 compares a state of current data provided to the IOSA 552 with a state of previous data, and when a data ratio with phase transition is greater than a preset ratio, generates an inversion flag signal IVF. The data comparator 553 temporarily stores (n−1)th data which is previously output, and compares the (n−1)th data with nth data which is currently output. When the (n−1)th data and the (n−1)th data are different, that is, when the number of bits having different phases is greater than a preset number, the data comparator 553 outputs the inversion flag signal IVF.

The first set of data inverters 554 includes circuitry that inverts a phase of nth data from the IOSA 552 when the inversion flag signal IVF is activated, and outputs the inverted nth data to a global data input/output line GIO.

The second set of data inverters 555 includes circuitry that inverts a phase of the inverted nth data transmitted through the global data input/output line GIO when the inversion flag signal IVF is activated, and applies the inverted inverted data to a pipeline register 556 with the same phase as that of the nth data output from the MRAM core block 551.

The pipeline register 556 converts the nth data 4-bit prefetched by the MRAM core block 551 into serial data, and outputs the serial data to a data I/O pin DQ through an I/O driver 557.

The MRAM 550 may selectively operate the first inversion unit 554 or the second inversion unit 555 in order to provide a write DBI function or a read DBI function of the MRAM. In order to provide a write DBI function, the MRAM 550 disposes a write driver along with the first set of data inverters 554, when the number of bits of a low level is greater than the number of bits of a high level from among a plurality of pieces of write data DQ0 through DQN, inverts write data such that the number of bits of a low level is equal to or less than half the number of all bits of the write data, and writes the inverted data to the MRAM core block 551. In this case, a flag signal indicating that the write data has been inverted is additionally generated.

In order to provide a read DBI function, the MRAM 550, when the number of bits of a low level is greater than the number of bits of a high level from among read data applied by the MRAM core block 551, inverts the read data by using the first set of data inverters 554 or the second set of data inverters 555 such that the number of bits of a low level is equal to or less than half of all bits of the read data, and outputs the inverted data to pins DQ0 through DQN. In this case, a flag signal indicating that the read data has been inverted is additionally generated.

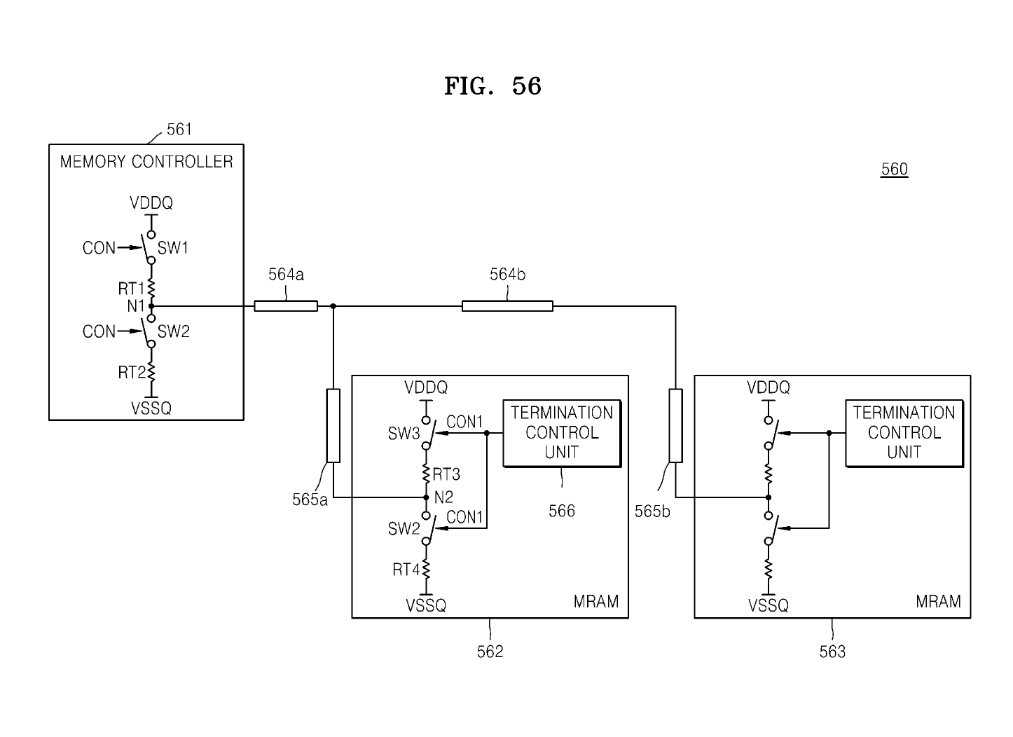

FIG. 56 is a circuit diagram illustrating an exemplary memory system 560 including MRAMs, 562 and 563 according to one embodiment.

Referring to FIG. 56, in the memory system 560, a memory controller 561 and MRAMs 562 and 563 are connected via a DQ bus, and active termination control of the DQ bus is performed. In the memory controller 561, termination resistors RT1 and RT2 and switches SW1 and SW2 are serially connected between a source of a power supply voltage VDDQ and a source of a ground voltage VSSQ. A connection node N1 between the termination resistor RT1 and the switch SW2 is connected to a data bus 410a. Resistance values of the termination resistors RT1 and RT2 may be the same or different.

A control signal CON for turning on/off on-chip active termination of the memory controller 561 may be generated in the memory controller 561. During a data read operation of the MRAM 562 and 563, the switches SW1 and SW2 may be turned on by the control signal CON and the termination resistors RT1 and RT2 are connected to the source of the power supply voltage VDDQ or the ground voltage VSSQ. Also, during a write operation of the memory controller 561, the switches SW1 and SW2 are turned off by the control signal CON and the termination resistors RT1 and RT2 are not connected to the source of the power supply voltage VDDQ or the ground voltage VSSQ.

In the MRAM 562, termination resistors RT3 and RT4 and switches SW3 and SW4 are serially connected between the source of the power supply voltage VDDQ and the source of the ground voltage VSSQ. A connection node N2 between the termination resistor RT3 and the switch SW4 is connected to a DQ bus 565a. The MRAM 562 includes a termination control unit 566 that generates a control signal CON1 for controlling active termination in response to a corresponding chip select signal. A configuration of the MRAM 563 is the same as that of the MRAM 562, and the MRAM 563 is connected to the memory controller 561 via a DQ bus 565b and data buses 564a and 564b.

When a corresponding chip select signal is enabled and a read or write operation is performed, the MRAMs 562 and 563 generate the control signal CON1 to turn off the termination resistors RT3 and RT4 of the MRAMs 562 and 563. Meanwhile, the MRAMs 562 and 563 generate the control signal CON1 to turn on the termination resistors RT3 and RT4 of the MRAMs 562 and 563.

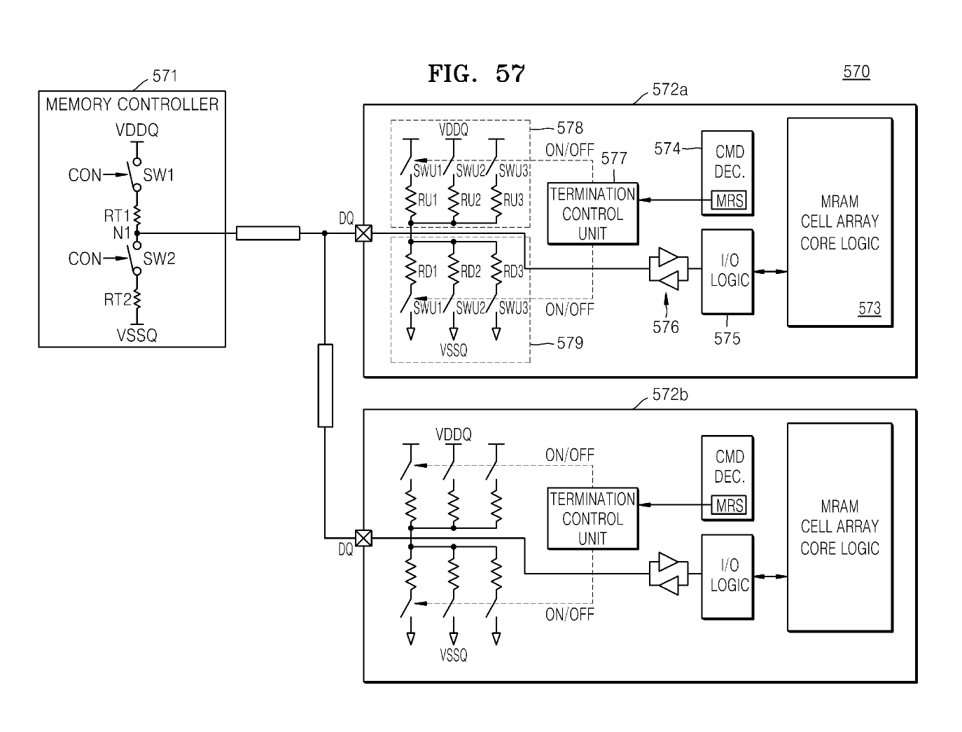

FIG. 57 is a circuit diagram illustrating a memory system 570 including MRAMs 572a and 572b, according to another exemplary embodiment.

Referring to FIG. 57, the memory system 570 includes a memory controller 571 and the MRAMs 572a and 572b performing a dynamic ODT function. The memory controller 571 is configured in the same manner as that of the memory controller 561 of FIG. 56. During a read operation of the MRAMs 572a and 572b, the termination resistors RT1 and RT2 are turned on, and during a write operation, the termination resistors RT1 and RT2 are turned off.

Each of the MRAMs 572a and 572b includes a cell array and core logic 573 in which STT-MRAM cells are arranged in rows and columns, and a command decoder 574 that receives a plurality of commands and clock signals from the memory controller 571. The command decoder 574 includes a mode register MRS that provides dynamic termination features from among a plurality of operation options of the MRAMs 572a and 572b.

Read data applied from the MRAM cell array and core logic 573 is latched in an I/O logic 575, and is output to a DQ terminal through a data driver 576. Write data transmitted to the DQ terminal from the memory controller 571 is latched in the I/O logic 575 through the data driver 576, and is written to the memory cell array 573.

The DQ terminal of the MRAM 572a is connected to a pull-up resistor 578 and a pull-down resistor 579. The pull-up resistor 578 includes switches SWU1 through SWU3 and resistors RU1 through RU3 serially connected between the source of the power supply voltage VDDQ and the DQ terminal. The pull-down resistor 579 includes switches SWD1 through SWD3 and resistors RD1 through RD3 serially connected between the DQ terminal and the source of the ground voltage VSSQ. The resistors RU1 and RD1 have RQZ resistance values, the resistors RU2 and RD2 have RZQ/2 resistance values, and the resistors RU3 and RD3 have RZQ/4 resistance values. RZQ may be set to, for example, 240 Q or a similar value.

The switches SWU1 through SW3 and SWD1 through SWD3 are selectively turned on or off in response to a control signal applied by the termination control unit 577. The termination control unit 577 may enable a termination resistance value of the DQ terminal to be set to RZQ, RZQ/2, or RZQ/4, or to be set to be dynamic ODT off in response to dynamic termination information applied by the mode register MRS.

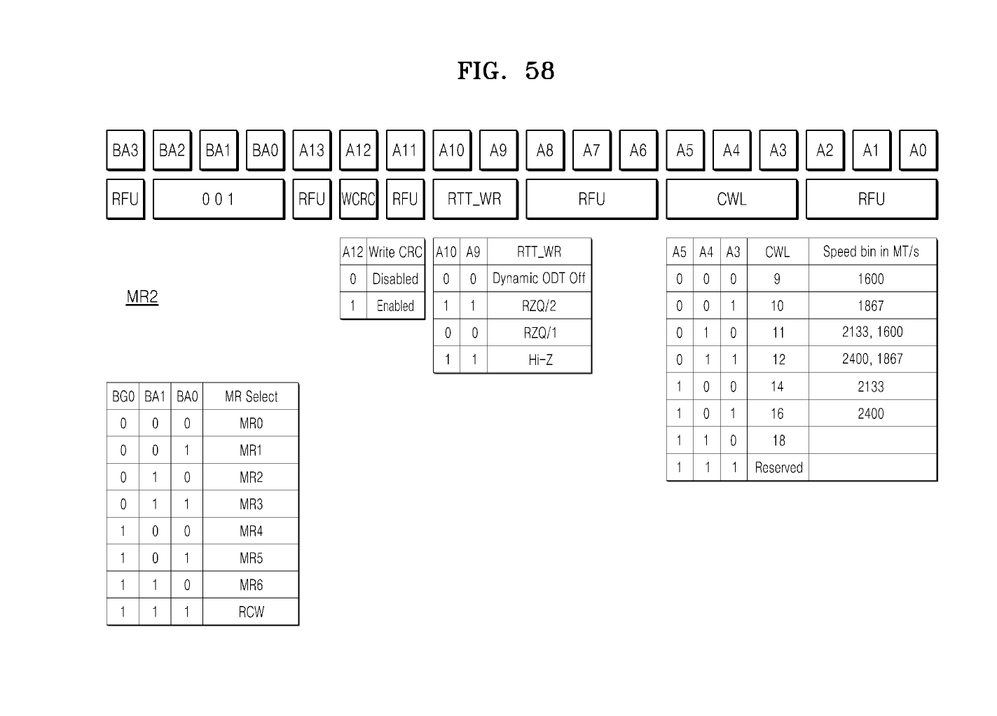

FIG. 58 is a diagram illustrating an exemplary mode register included in a control logic unit of FIG. 57.

A mode register MR2 of FIG. 58 is one of a plurality of mode registers that program various functions, features, and modes of the MRAM 572a.

Referring to FIG. 58, different modes of an operation settable to the mode register MR2 and bit allocation of each of the modes will be explained. The mode register MR2 stores data for CWL, dynamic termination, and write CRC.

3-bit A5:A3 is used to provide a CWL function. CWL is defined as a clock cycle delay between a first bit of effective input data and an internal write command. Whole latency (WL) is a sum of AL and CWL. That is, WL=AL+CWL.

When “000” is programmed to the A5:A3 bits, CWL 9 is set during an operation of a data rate of 1600 MT/s. When “001” is programmed, CWL 10 is set during an operation of a data rate of 1867 MT/s. When “010” is programmed, CWL 11 is set during an operation of a data rate of 1600 or 2133 MT/s. When “011” is programmed, CWL 12 is set during an operation of a data rate of 1867 or 2400 MT/s. When “100” is programmed, CWL 14 is set during an operation of a data rate of 2133 MT/s. When “101” is programmed, CWL 16 is set during an operation of a data rate of 2400 MT/s. When “110” is programmed, CWL 18 is set. “111” is undetermined.

2-bit A10:A9 is used to provide a dynamic termination (RTT_WR) feature of the MRAM 12. A dynamic ODT may be provided in order to enhance signal integrity on a data bus, in a specific application of the MRAM 12. When “00” is programmed to the A10:A9 bit, dynamic ODT off is set. When “01” is programmed, dynamic ODT is set to RZQ/2, when “10” is programmed, dynamic ODT is set to RZQ/1, and when “11” is programmed, dynamic ODT is set to high impedance (Hi-Z).

1-bit A12 is used to provide a write CRC function of the MRAM 12. A CRC function is used to detect an error by transmitting CRC data obtained through a CRC calculation in order to prevent loss of data transmitted between the MRAM 12 and the memory controller 11. The CRC calculation of the MRAM 12 may use a polynomial expression x8+x2+x+19. When the A12 bit is programmed to “0”, the write CRC calculation is disabled. When the A12 bit is programmed to “1”, the write CRC calculation is enabled.

BG1, A13, A11, A8:A6, and A2:A0 bits of the mode register MR2 are RFU and are programmed to “0” during mode register setting.

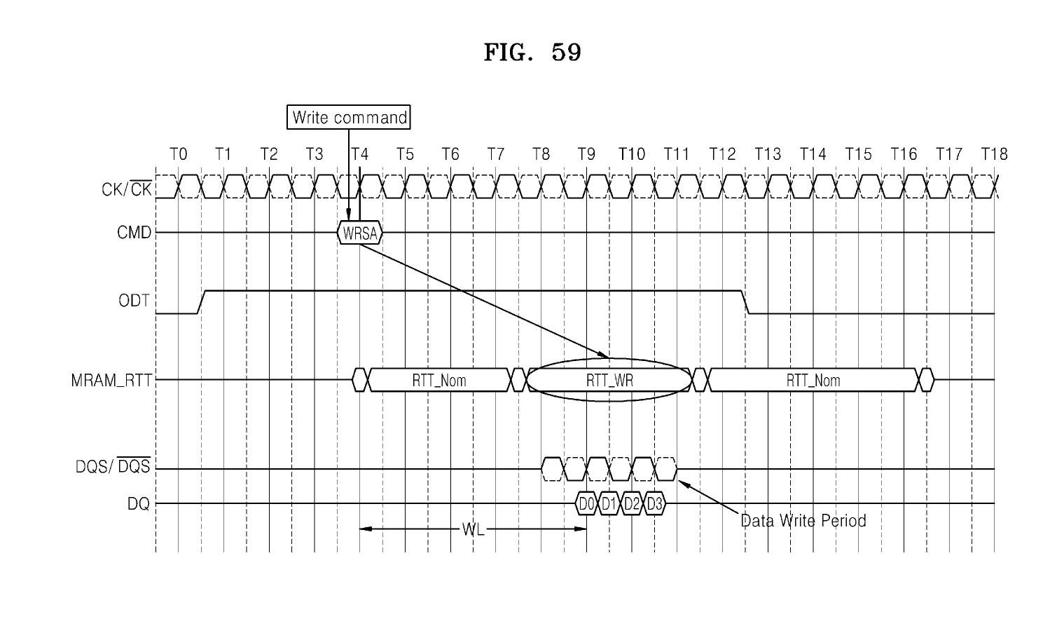

In the MRAM 572a, the dynamic termination RTT_WR may receive a write command and change an ODT value preset to a nominal termination RTT_NOM into a dynamic ODT value during a write operation as shown in FIG. 59. When the write operation ends, the dynamic ODT value is returned to the nominal termination value.

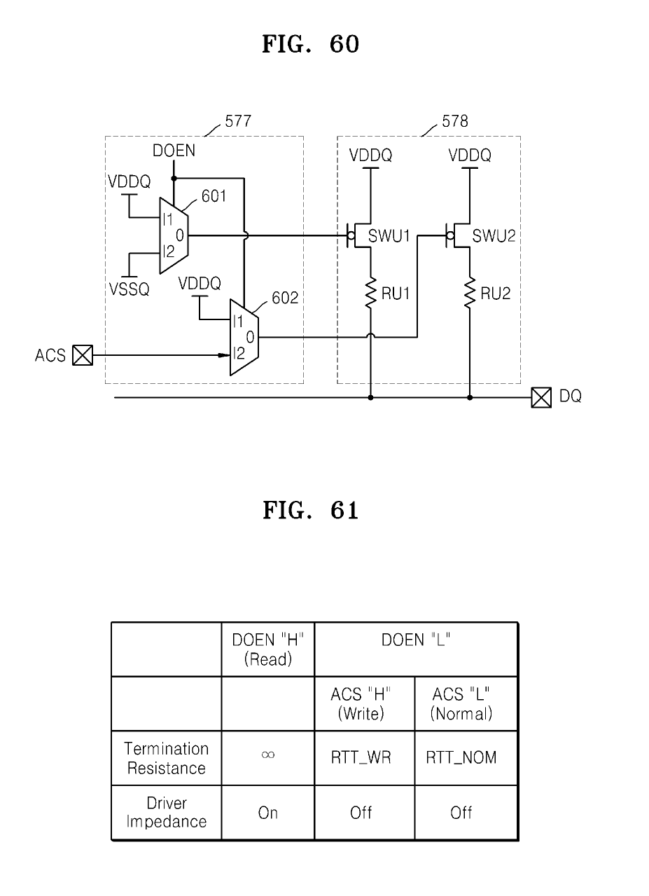

FIGS. 60 and 61 are diagrams illustrating the termination control unit 577 of FIG. 57, according to exemplary embodiments.

Referring to FIG. 60, the termination control unit 577 may control an ODT of an MRAM in response to an external control pin ACS instead of the mode register MRS of FIG. 57. The termination control unit 577 includes a first MUX unit 601 and a second MUX unit 602. The first and second MUX units 601 and 602 selectively output an output signal received from first and second input terminals I1 and I2 to an output terminal O in response to a read enable signal DOEN. The first and second MUX units 601 and 602 output a signal received from the first input terminal I1 to the output terminal O in response to a logic “high” of the read enable signal DOEN, and output a signal received from the second input terminal I2 to the output terminal O in response to a logic “low” of the read enable signal DOEN.

Each of the switches SWU1 and SWU2 in the pull-up resistor 578 includes a PMOS transistor. The output terminal O of the first MUX unit 601 is connected to a gate of the PMOS transistor which is the switch SWU1, and the output terminal O of the second MUX unit 602 is connected to a gate of the PMOS transistor which is the switch SWU2. An ODT operation at the DQ terminal of the MRAM due to the read enable signal DOEN and the external control pin ACS is as shown in FIG. 61.

Referring to FIG. 61, during an MRAM read operation, a power supply voltage VDDQ is output to the output terminals O of the first and second MUX units 601 and 602 in response to the read enable signal DOEN which is activated to a logic “high”. Accordingly, the switches SWU1 and SW2 are turned off, a termination resistance becomes infinity (∞) and an impedance of a data driver is shown to the DQ terminal.

During an MRAM write operation, the ground voltage VSSQ is output to the output terminal O of the first MUX unit 601 in response to the read enable signal DOEN which is inactivated to a logic “low”, and a logic level of the external control pin ACS is output to the output terminal O of the second MUX unit 602. When the external control pin ACS is a logic “high”, the switch SWU1 is turned on, the switch SWU2 is turned off, and a dynamic termination resistor RTT_WR is set as the resistor RU1 of the DQ terminal. When the external control pin ACS is a logic “low”, the switches SWU1 and SWU2 are turned on and a nominal termination resistor RTT_NOM is set as the resistors RU1 and RU2 which are connected in parallel of the DQ terminal.

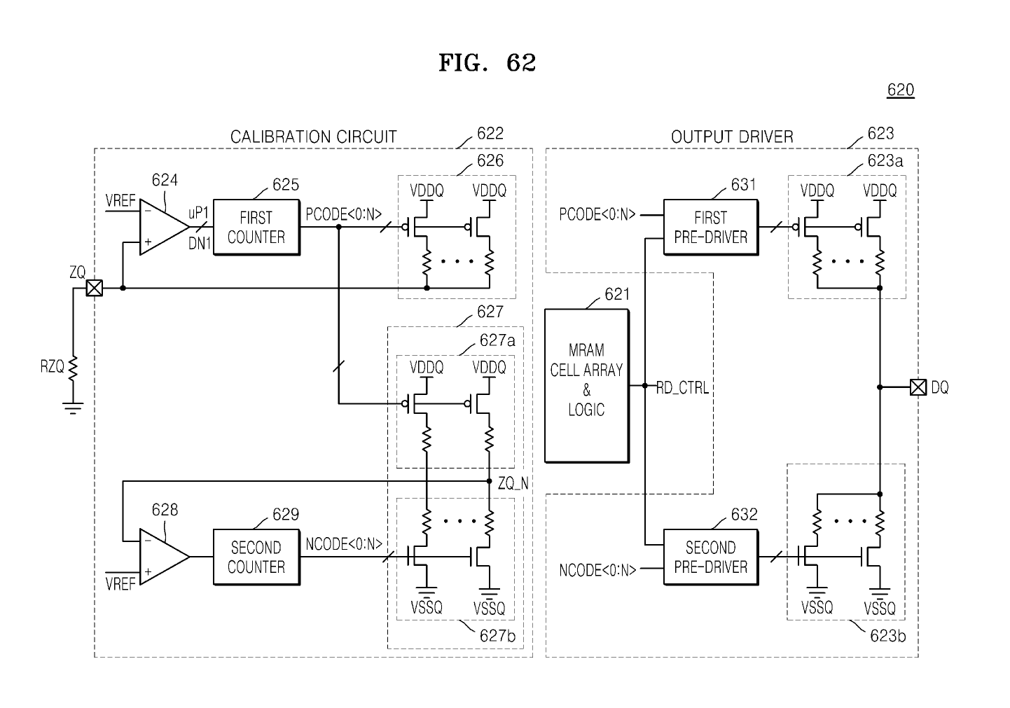

FIG. 62 is a circuit diagram illustrating an MRAM 620 according to another exemplary embodiment.

Referring to FIG. 62, the MRAM 620 reduces a swing width of a DQ signal interfacing with external devices in order to increase an operation speed. This is to minimize a time taken to transmit a signal. As a swing width of the DQ signal is reduced, an effect of external noise on a noise is increased and reflection of a signal due to impedance mismatching at an interface end is increased. Impedance mismatching is caused by a change in external noise or a power supply voltage, a change in an operation temperature, or a change in a manufacturing process.

When impedance mismatching occurs, it may be difficult to transmit DQ data at high speed and the DQ data output from a data output end of the MRAM 620 may be distorted. When a semiconductor device at a receiver side receives the distorted DQ data at an input end, problems such as setup/hold failure or input level misjudgment may occur.

In order to achieve impedance matching between a transmitter side and a receiver side in a system, source termination is performed by an output circuit at the transmitter side and parallel termination is performed by a termination circuit connected in parallel to an input circuit connected to an input pad at the receiver side. A process of providing pull-up and pull-down codes to terminations based on a change in a process voltage temperature (PVT) is related to ZQ calibration. Since calibration is performed by using a ZQ node, it is called ZQ calibration. In the MRAM 620, a termination resistance of the DQ pad is controlled by using codes generated as a result of ZQ calibration.

The MRAM 620 includes an MRAM cell array and logic 621, an external resistor RZQ connected to a ZQ pin, a calibration circuit 622, and an output driver 623 connected to the DQ pad. The MRAM cell array and logic 621 includes a plurality of STT-MRAM cells that are arranged in rows and columns and input/output write/read data to/from the STT-MRAM cells. During a read operation, a read control signal RD_CTRL output from the MRAM cell array and logic 621 is output to the DQ pad through the output driver 623. The read control signal RD_CTRL is a representative signal obtained by combining various control signals and read data of the MRAM cell array 621 applied to the output driver 623.

The calibration circuit 622 includes a first comparator 624, a first counter 625, a first calibration resistor 626, a second calibration resistor 627, a second comparator 628, and a second counter 629.

The first comparator 624 compares a voltage of the ZQ pin with a reference voltage VREF, and transmits a first up/down signal UP1/DN1, which is a comparison result to the first counter 625. The first counter 625 performs a count operation in response to the first up/down signal UP1/DN1 and outputs a first calibration code PCODE<0:N>. The reference voltage VREF may be set to have a voltage level corresponding to a half of the power supply voltage VDDQ. The first calibration code PCODE<0:N> calibrates the first calibration resistor 626 to have the same value as that of an external resistor RZQ.

The first calibration resistor 626 includes PMOS transistors that input the first calibration code PCODE<0:N> to gates thereof, and resistors that are serially connected to the PMOS transistors, between the source of the power supply voltage VDDQ and the ZQ pin. The first calibration resistor 626 adjusts a resistance value in response to the first calibration code PCODE<0:N>. The first comparator 624, the first counter 625, and the first calibration resistor 626 perform comparison until all resistance values of the external resistor RZQ connected to the ZQ pin and the first calibration resistor 626 are the same, that is, until a voltage of the ZQ pin is the same as the reference voltage VREF, and generate the first calibration code PCODE<0:N>. A pull-up calibration, which is a repeated operation for generating the first calibration code PCODE<0:N> is performed.

The external resistor RZQ of, for example, 240Ω, is connected to the ZQ pin. Since the reference voltage VREF has a voltage level corresponding to half the power supply voltage VDDQ, the first comparator 624 generates the first calibration code PCODE<0:N> such that an overall resistance value of the first calibration resistor 626 is the same as the resistance value 240Ω of the external resistor RZQ.

The second calibration resistor 627 is calibrated to have the same resistance value as that of the first calibration resistor 626, and generates a second calibration code NCODE<0:N>. The second calibration resistor 627 includes a pull-up calibration resistor 627a and a pull-down calibration resistor 627b.

The pull-up calibration resistor 627a is configured in the same manner as that of the first calibration resistor 626. The pull-up calibration resistor 627a receives a pull-up calibration code PCODE<0:N> and has the same resistance value as an overall resistance value of the first calibration resistor 626. A connection node ZQ_N between the pull-up calibration resistor 627a and the pull-down calibration resistor 627b is applied to an input of the second comparator 628.

The pull-down calibration resistor 627b includes NMOS transistors that input the second calibration code NCODE<0:N> to gates thereof, and resistors that are serially connected to the NMOS transistors, between the source of the ground voltage VSSQ and the ZQ_N node. The pull-down calibration resistor 627b adjusts a resistance value in response to the second calibration code NCODE<0:N>.

The pull-down calibration resistor 627b performs pull-down calibration such that a voltage of the ZQ_N node is the same as the reference voltage VREF. As such, an overall resistance value of the pull-down calibration resistor 627b is the same as an overall resistance value of the pull-up calibration resistor 627a, by using the second comparator 628 and the second counter 629. The second calibration code NCODE<0:N> is generated by performing a repeated pull-down calibration operation.

The first and second calibration codes PCODE<0:N> and NCODE<0:N> determine a termination resistance value of the output driver 623. The output driver 623 includes a pull-up termination resistor 623a and a pull-down termination resistor 623b that are connected to the DQ pad, and first and second pre-drivers 631 and 632. The pull-up termination resistor 623a is configured in the same manner as that of the first calibration resistor 623 and the pull-up calibration resistor 627a, and the pull-down termination resistor 623b is configured in the same manner as that of the pull-down calibration resistor 627b.

The first pre_driver 631 receives the first calibration code PCODE<0:N> and a read control signal RD_CTRL output from the MRAM cell array and logic 621, and controls the first pull-up termination resistor 623a. The second pre_driver 632 receives the second calibration code NCODE<0:N> and the read control signal RD_CTRL output from the MRAM cell array and logic 621, and controls the second pull-up termination resistor 623a.

A logic state of the read control signal RD_CTRL determines whether to turn on the pull-up termination resistor 623a or the pull-down termination resistor 623b. When the read control signal RD_CTRL is a logic “high” signal, the pull-up termination resistor 623a is turned on and the DQ pad is output as a logic “high”. Whether to turn on or off each resistor in the pull-up termination resistor 623a which is turned on is determined by the first calibration code PCODE<0:N>.

When the read control signal RD_CTRL is a logic “low signal, the pull-down termination resistor 623b is turned on and the DQ pad is output as a logic “low”. Whether to turn on or off each resistor in the pull-down termination resistor 623b which is turned on is determined by the second calibration code NCODE<0:N>.

ODT of the MRAM 620 may increase or reduce a resistance value at a predetermined rate without mismatch between the calibration resistors 626, 627a, and 627b and the termination resistors 623a and 623b due to a ZQ calibration operation.

Although ODT is used to determine resistance values of the pull-up termination resistor 623a and the pull-down termination resistor 623b in the present embodiment, an ODT device of the MRAM 620 does not always include both the pull-up termination resistor 623a and the pull-down termination resistor 623b. For example, at an output driver side of the MRAM 620, both the pull-up termination resistor 623a and the pull-down termination resistor 623b may be used, and at an input buffer side, only the pull-up termination resistor 623a may be used.

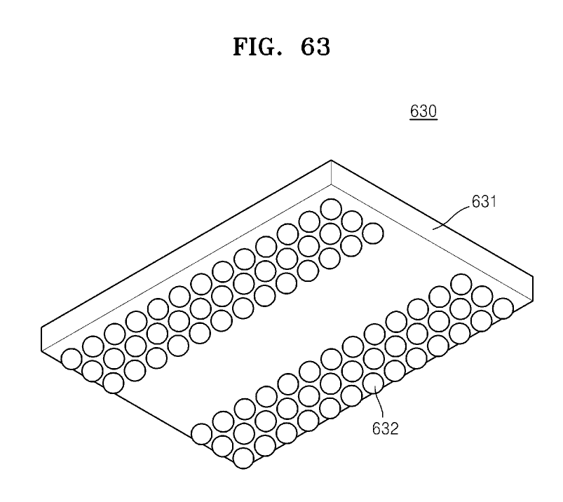

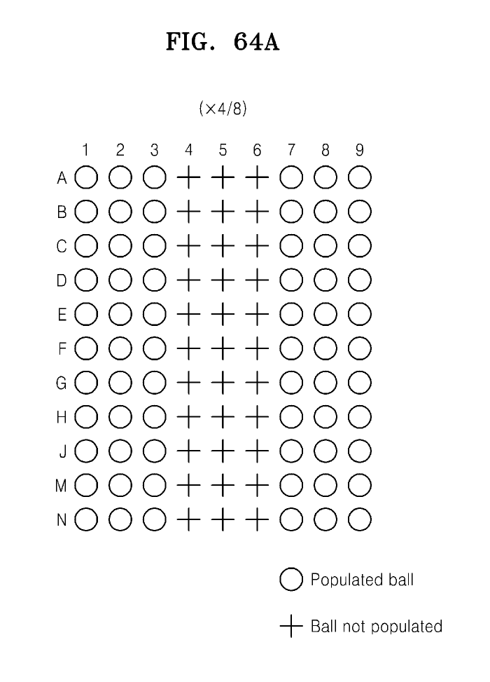

FIGS. 63 through 69 are views and diagrams for explaining an MRAM package 630, MRAM pin structures, and MRAM modules 670, 680, and 690, according to various exemplary embodiments. An MRAM may constitute a pin structure and a package which is compatible with an SDRAM. Also, a module including MRAM chips may be compatible with an SDRAM module. For example, a pin arrangement of the MRAM chip may be compatible with that of any one of a DDR2 SDRAM, DDR3 SDRAM, and DDR4 SDRAM.

Referring to FIG. 63, the MRAM package 630 includes a semiconductor device body 631, and a ball grid array (BGA) 632. The BGA 632 includes a plurality of solder balls. The plurality of solder balls may connect the semiconductor memory device body 631 and a PCB (not shown). The solder balls may be formed of conductive materials.

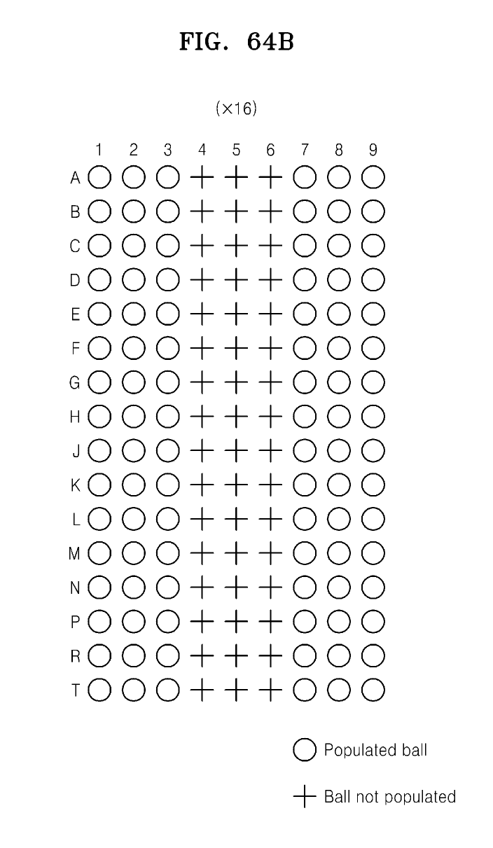

Referring to FIG. 64A, when the MRAM package 630 is used according to an X4 or X8 data input/output specification, the BGA 632 may be arranged in 13 rows and 9 columns. The 13 rows may be defined as A through N rows, and the 9 columns may be defined as 1 through 9 columns. The 1 through 3 columns and 7 through 9 columns of the BGA 632 may be solder ball regions. Solder balls (O) may be provided in the solder ball regions. The 4 through 6 columns of the BGA 632 may be a dummy ball region (+). A solder ball is not provided in the dummy ball region. As a result, in the BGA 632, 78 solder balls may be provided.

Referring to FIG. 64B, when the MRAM package 630 is used according to an X16 data input/output specification, the BGA 632 may be arranged in 16 rows and 9 columns. The 16 rows may be defined as A through T rows, and the 9 columns may be defined as 1 through 9 columns. The 1 through 3 columns and 7 through 9 columns of the BGA may be solder ball regions, and the 4 through 6 columns may be a dummy ball region (+). In the BGA, 96 solder balls may be provided.

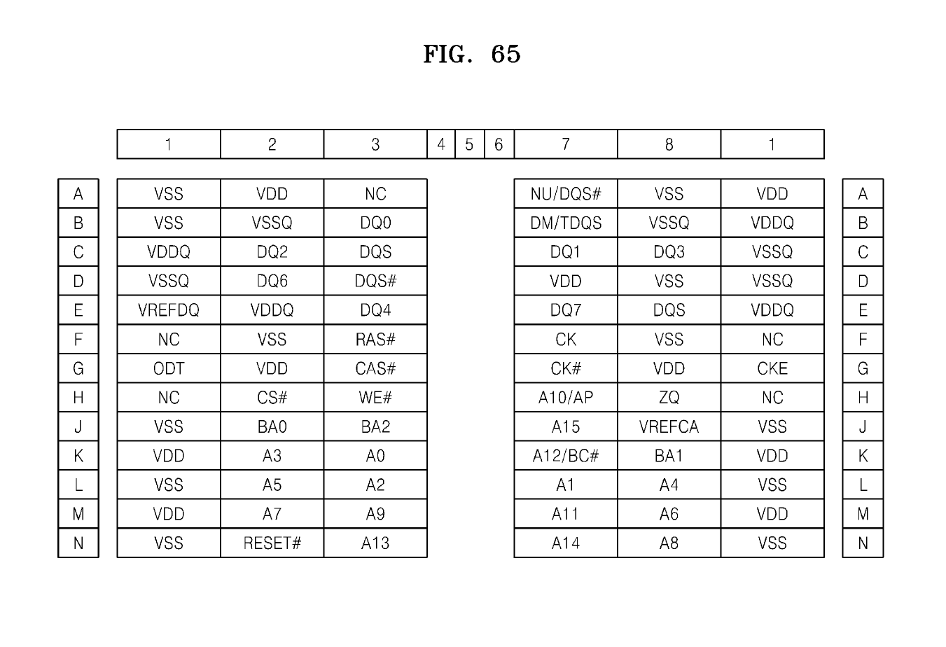

Referring to FIG. 65, an MRAM pin structure of an MRAM package according to an X4 or X8 data I/O specification is arranged to be compatible with a DDR3 SDRAM. A pin arrangement includes power supply voltages VDD and VDDQ, ground voltages VSS and VSSQ, data input/output signals DQ0 through DQ7, address signals A0 through 14, clock signals CK and CK#, a clock enable signal CKE, and command signals CAS#, RAS#, and WE#.

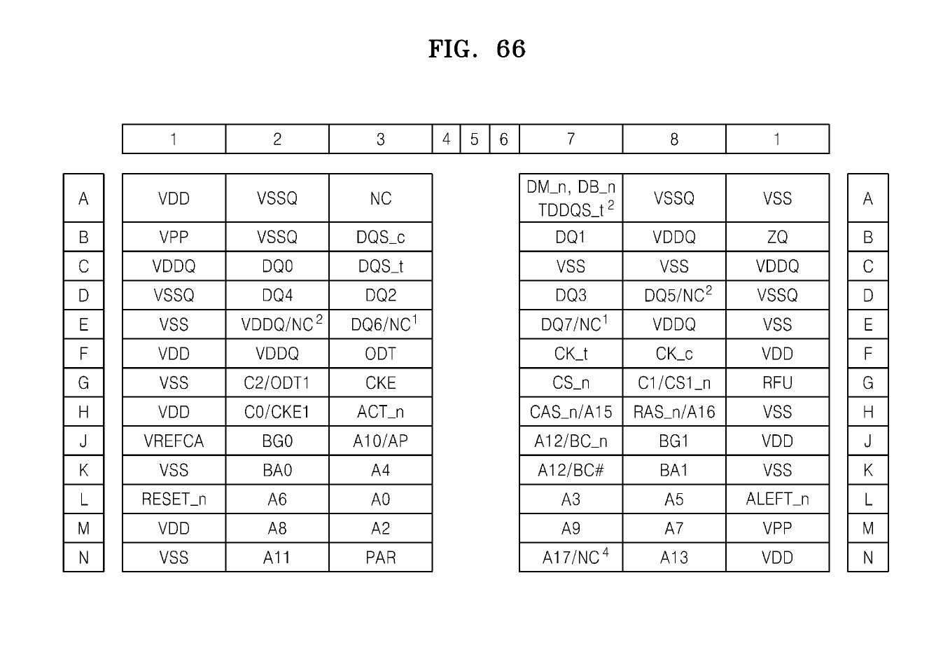

Referring to FIG. 66, an MRAM pin structure of an MRAM package according to an X4 or X8 data I/O specification is arranged to be compatible with a DDR SDRAM. A pin arrangement includes power supply voltages VDD, VPP, and VDDQ, ground voltages VSS and VSSQ, data input/output signals DQ0-7, address signals A0-17, clock signals CK_t and CK_c, a clock enable signal CKE, and command signals CAS_n, RAS_n, and WE_n.

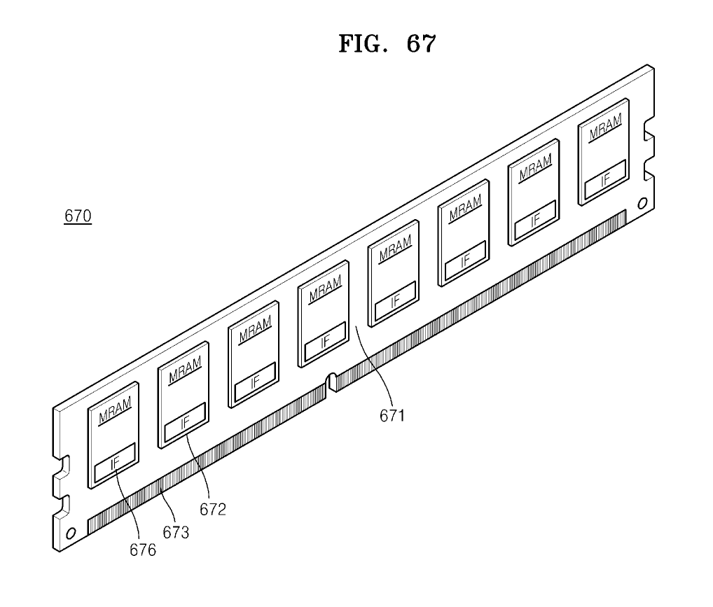

Referring to FIG. 67, the MRAM module 670 includes a PCB 671, a plurality of MRAM chips 672, and a connector 673. The plurality of MRAM chips 672 may be coupled to a top surface and a bottom surface of the PCB 671. The connector 673 is electrically connected to the plurality of MRAM chips 672 through conductive lines (not shown). Also, the connector 673 may be inserted into a slot of an external host.

Each of the MRAM chips 672 includes an interface unit 676 that includes circuitry that provides various interface functions. The interface unit 676 may support, for example, an SDR, DDR, QDR, or ODR interface, a packet protocol interface, a source synchronous interface, single-ended signaling interface, differential-ended signaling interface, POD interface, multi-level single-ended signaling interface, multi-level differential-ended signaling interface, LVDS interface, bidirectional interface, and CTT interface. In one embodiment, the interface unit 676 may sample a DQ signal by using a differential data clock signal whose frequency is two times a frequency of a command/address clock signal.

In order to synchronize data transmitted in various interfaces with a clock signal, the interface unit 676 may include a digital DLL/PLL or an analog DLL/PLL, and may interface with a high speed synchronous bus without a DLL/PLL. In order to minimize bit switching between data words, the interface unit 676 may provide a write DBI function and a read DBI function. The interface unit 676 may provide an ODT function for impedance matching, and may control termination resistance by using a ZQ calibration operation.

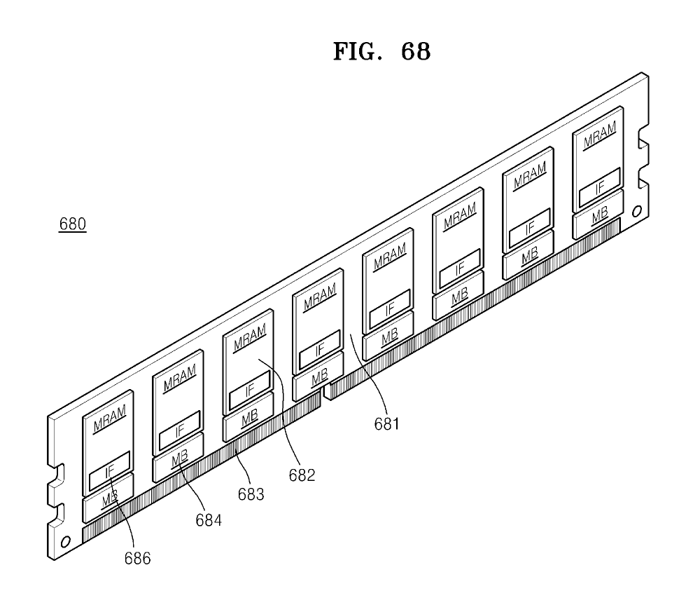

Referring to FIG. 68, in one embodiment, the MRAM module 680 includes a PCB 681, a plurality of MRAM chips 682, a connector 683, and a plurality of buffer chips 684. The plurality of buffer chips 684 may be disposed between the connector 683 and the MRAM chips 682. The MRAM chips 682 and the buffer chips 684 may be provided on a top surface and a bottom surface of the PCB 681. The MRAM chips 682 and the buffer chips 684 formed on the top surface and the bottom surface of the PCB 681 may be connected to each other via a plurality of via holes.

Each of the MRAM chips 682 includes an interface unit 686 that provides various interface functions. The interface unit 686 may have the same function as that of the interface unit 676 of FIG. 67.

The buffer chip 684 may store a result obtained by testing a feature of the MRAM chip 682 connected to the buffer chip 684. Since the buffer chip 684 manages an operation of the MRAM chip 682 by using stored feature information, an effect of a weak cell or a weak page on the MRAM chip 682 is reduced. For example, the buffer chip 684 includes a storage unit therein and may aid a weak cell or a weak page of the MRAM chip 682.

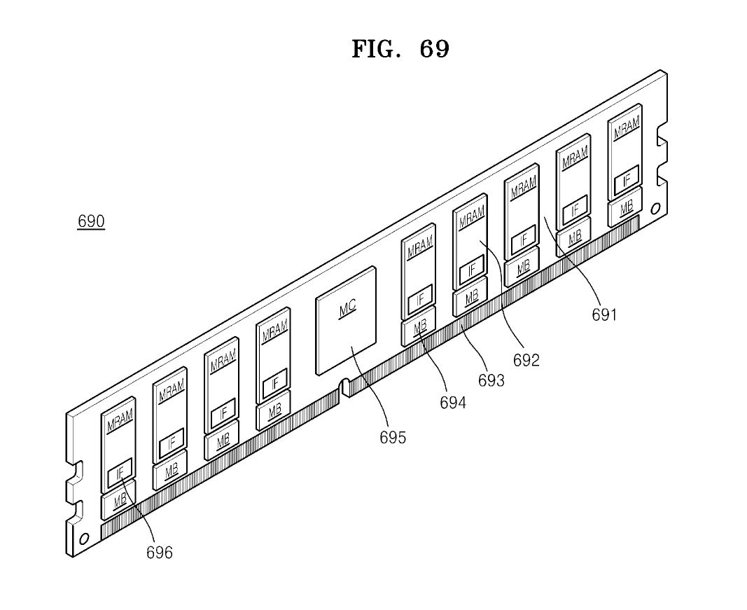

Referring to FIG. 69, in one embodiment, the MRAM module 690 includes a PCB 691, a plurality of MRAM chips 692, a connector 693, a plurality of buffer chips 694, and a controller 695. The controller 695 communicates with the MRAM chips 692 and the buffer chips 694, and controls an operation mode of the MRAM chips 692. The controller 695 may control various functions, features, and modes by using a mode register of the MRAM chip 695.

The controller 695 controls read leveling, write leveling, and read preamble training to compensate for a skew of, for example, the MRAM chips 692, and controls a write recovery (WR) time and a read-to-precharge (RTP) time such that immediately after one operation is completed, a precharge operation is automatically started. Also, the controller 695 controls Vref monitoring and data masking operations of the MRAM chips 692.

In one embodiment, each of the MRAM chips 692 includes an interface unit 696 that provides various interface functions of a corresponding MRAM chip 692. The interface unit 696 may have the same function as that of the interface unit 676 of FIG. 67.

The MRAM modules 670, 680, and 690 may be applied to memory modules such as a single in-line memory module (SIMM), a dual in-line memory module (DIMM), a small-outline DIMM (SO-DIMM), a unbuffered DIMM (UDIMM), fully-buffered DIMM (FBDIMM), a rank-buffered DIMM (RBDIMM), a load-reduced DIMM (LRDIMM), mini-DIMM, and micro-DIMM.

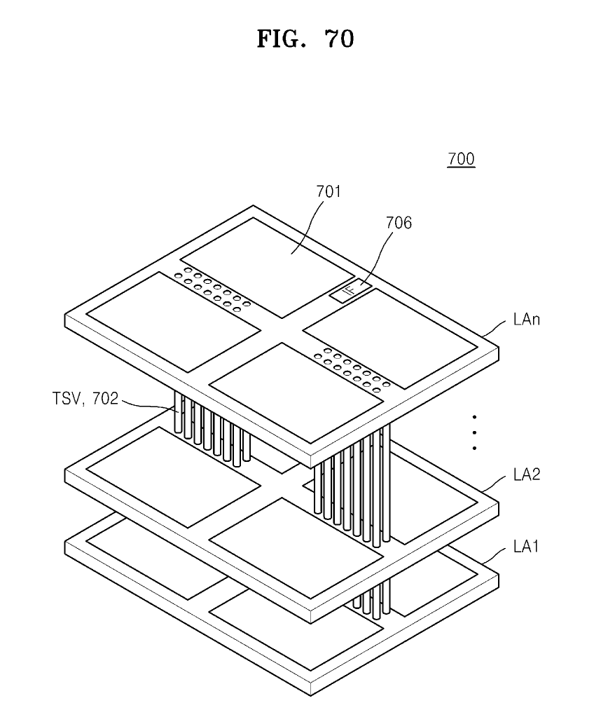

FIG. 70 is a perspective view illustrating a semiconductor device 700 having a stacked structure including MRAM semiconductor layers LA1 through LAn, according to one exemplary embodiment.

Referring to FIG. 70, the semiconductor device 700 may include the plurality of MRAM semiconductor layers LA1 through LAn. Each of the semiconductor layers LA1 through LAn may be a memory chip including memory cell arrays 701 each including MRAM cells, and some of the semiconductor layers LA1 through LAn may be master chips that interface with an external controller and the rest of the semiconductor layers LA1 through LAn may be slave chips that store data. In FIG. 70, the semiconductor layer LA1 that is located at a lowermost position may be a master chip and the other semiconductor layers LA2 through LAn may be slave chips.

The plurality of semiconductor layers LA1 through LAn may transmit/receive signals through substrate vias, such as through silicon vias (TSVs) 702, and the semiconductor layer LA1 acting as a master chip may communicate with an external memory controller (not shown) through a conductive unit (not shown) formed on an outer surface of the semiconductor layer LA1.

Also, a signal may be transmitted between the semiconductor layers LA1 through LAn according to an optical I/O connection. For example, a signal may be transmitted between the semiconductor layers LA1 through LAn by using a radiative method using radio frequency (RF) waves or ultrasound waves, an inductive coupling method using magnetic induction, or a nonradiative method using magnetic field resonance.

The radiative method is a method of wirelessly transmitting a signal by using an antenna such as a monopole or a planar inverted-F antenna (PIFA). Radiation occurs as an electric field and a magnetic field, which vary according to time affect each other, and a signal may be received according to polarization features of incident waves when there is an antenna operating at the same frequency.

The inductive coupling method is a method of generating a strong magnetic field in one direction by winding a coil several times, and generating coupling by approaching coils which resonate at similar frequencies.

The nonradiative method is a method using evanescent wave coupling that moves electromagnetic waves between two media resonating at the same frequency through a short distance electromagnetic field.

Each of the semiconductor layers LA1 through LAn includes an interface unit 706 that provides various interface functions of each of the semiconductor layers LA1 through LAn. The interface unit 706 may have the same function as that of the interface unit 676 of FIG. 67.

In the modules 670, 680, and 690 of FIGS. 67 through 69, each MRAM chip may include the plurality of semiconductor layers LA1 through LAn.

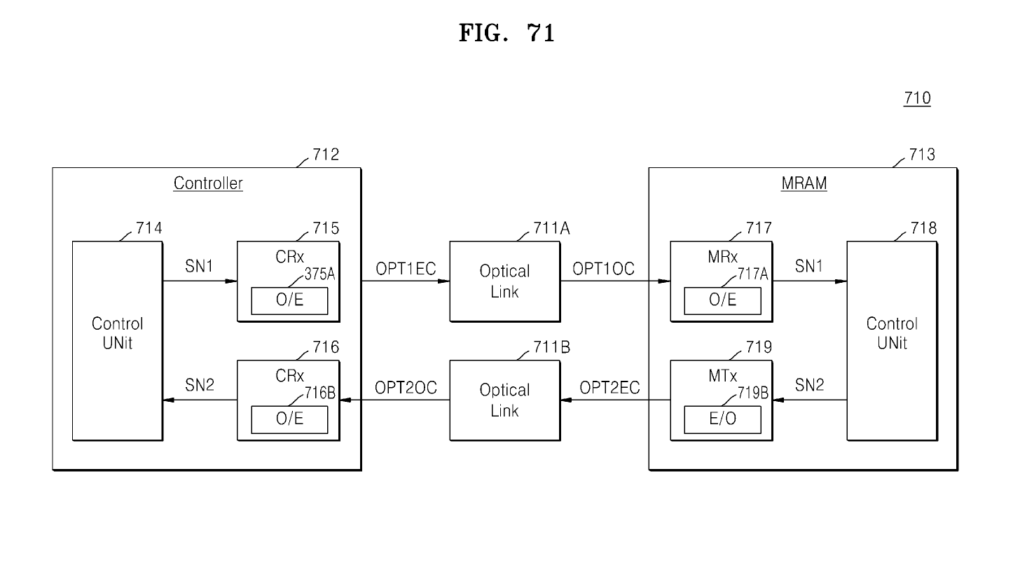

FIG. 71 is a block diagram illustrating an exemplary memory system 710 including an MRAM 713, according to another embodiment.

Referring to FIG. 71, the memory system 710 includes optical links 711A and 711B, a controller 712, and the MRAM 713. The optical links 711A and 711B interconnect the controller 712 and the MRAM 713. The controller 712 includes a control unit 714, a first transmitter 715, and a first receiver 716. The control unit 714 transmits a first electrical signal SN1 to the first transmitter 715. The first electrical signal SN1 may include command signals, clock signals, address signals, or write data transmitted to the MRAM 713.

The first transmitter 715 includes a first optical modulator 715A, and the first optical modulator 715A converts the first electrical signal SN1 into a first optical transmission signal OTP1EC and transmits the first optical transmission signal OTP1EC to the optical link 711A. The first optical transmission signal OTP1EC is transmitted by serial communication through the optical link 711A. The first receiver 716 includes a first optical demodulator 716B, and the first optical demodulator 716B converts a second optical reception signal OPT2OC received from the optical link 711B into a second electrical signal SN2 and transmits the second electrical signal SN2 to the control unit 714.

The MRAM 713 includes a second receiver 717, a memory region 718 including an STT_MRAM cell, and a second transmitter 719. Also, the MRAM 718 may include an interface unit that provides various interface functions. The second receiver 717 includes a second optical demodulator 717A, and the second optical demodulator 717A converts the first optical reception signal OPT1OC received from the optical link 711A into the first electrical signal SN1 and transmits the first optical reception signal OPT1OC to a memory region 718.

In the memory region 718, write data is written to the STT_MRAM cell in response to the first electrical signal SN1, or data read from the memory region 718 is transmitted as a second electrical signal SN2 to the second transmitter 719. The second electrical signal SN2 may include clock signals and read data transmitted to the memory controller 712. The second transmitter 719 includes a second optical modulator 719B, and the second optical modulator 719B converts the second electrical signal SN2 into the second optical data signal OPT2EC and transmits the second optical data signal OPT2EC to the optical link 711B. The second optical transmission signal OTP2EC is transmitted by serial communication through the optical link 711B.

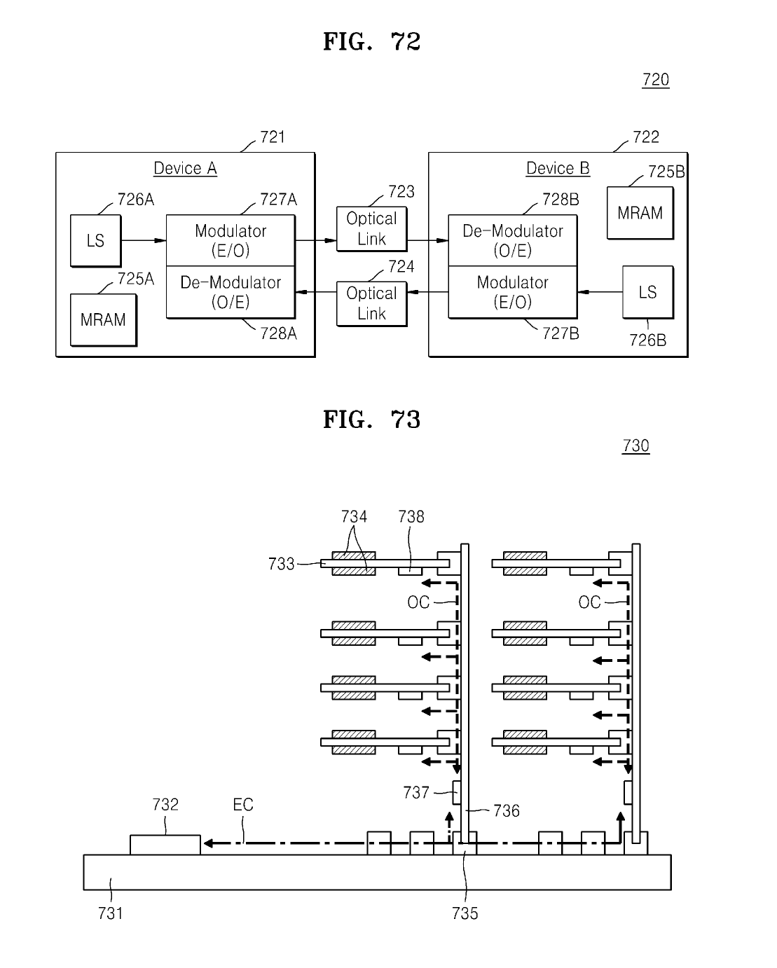

FIG. 72 is a block diagram illustrating a data processing system 720 including MRAMs 725A and 725B, according to one exemplary embodiment.

Referring to FIG. 72, the data processing system 720 includes a first device 721, a second device 722, and a plurality of optical links 723 and 724. The first device 721 and the second device 722 may communicate an optical signal by serial communication.

The first device 721 may include the MRAM 725A, a first light source 726A, a first optical modulator 727A that may perform an electric-to-optical conversion operation, and a first optical demodulator 728A that may perform an optical-to-electric conversion operation. The second device 722 includes the MRAM 725B, a second light source 726B, a second optical modulator 727B, and a first optical demodulator 728B. Each of the MRAMs 725A and 725B may include an interface unit that provides various interface functions.

The first and second light sources 726A and 726B output an optical signal having continuous waves. The first and second light sources 726A and 726B may use as a light source a distributed feedback laser diode (DFB-LD) or a Fabry Perot laser diode (FP_LD) which is a multi-wavelength light source.

The first optical modulator 727A converts transmission data into an optical transmission signal and transmits the optical transmission signal to the optical link 723. The first optical modulator 727A may modulate a wavelength of the optical signal received by the first light source 726A according to the transmission data. The first optical demodulator 728A receives and demodulates an optical signal output from the second optical modulator 727B of the second device 722 and outputs a demodulated electrical signal.

The second optical modulator 727B converts transmission data of the second device 722 into an optical transmission signal and transmits the optical transmission signal to the optical link 724. The second optical modulator 727B may modulate a wavelength of an optical signal received from the second light source 726B according to the transmission data. The second optical demodulator 728B receives and demodulates an optical signal output from the first optical modulator 272A of the first device 721 through the optical link 723, and outputs a demodulated electrical signal.

FIG. 73 is a view illustrating a server system 730 including an MRAM, according to another exemplary embodiment.

Referring to FIG. 73, the server system 730 includes a memory controller 732 and a plurality of memory modules 733. Each of the memory modules 733 may include a plurality of MRAM chips 734. The MRAM chip 734 may include a memory region including an STT_MRAM cell, and an interface unit that provides various interface functions.

In the server system 730, a second circuit board 736 is coupled to each of sockets 735 of a first circuit board 731. The server system 730 may be designed to have a channel structure in which one second circuit board 736 is connected to the first circuit board 731 according to signal channels. However, the present embodiment is not limited thereto, and the server system 730 may have any of various structures.

Meanwhile, a signal of the memory modules 733 may be transmitted via an optical IO connection. For the optical IO connection, the server system 730 may further include an electric-to-optical conversion unit 737, and each of memory modules 733 may further include an optical-to-electrical conversion unit 738.

The memory controller 732 is connected to the electric-to-optical conversion unit 737 through an electrical channel EC. The electric-to-optical conversion unit 737 converts an electrical signal received from the memory controller 732 through the electrical channel EC into an optical signal and transmits the optical signal to an optical channel OC. Also, the electric-to-optical conversion unit 737 converts an optical signal received through the optical channel OC into an electrical signal and transmits the electrical signal to the electrical channel EC.

The memory module 733 is connected to the electric-to-optical conversion unit 737 through the optical channel OC. An optical signal applied to the memory module 733 may be converted into an electrical signal through the optical-to-electric conversion unit 738 and may be transmitted to the MRAM chips 734. The server system 730 including the optical connection memory modules may support high storage capacity and a high processing speed.

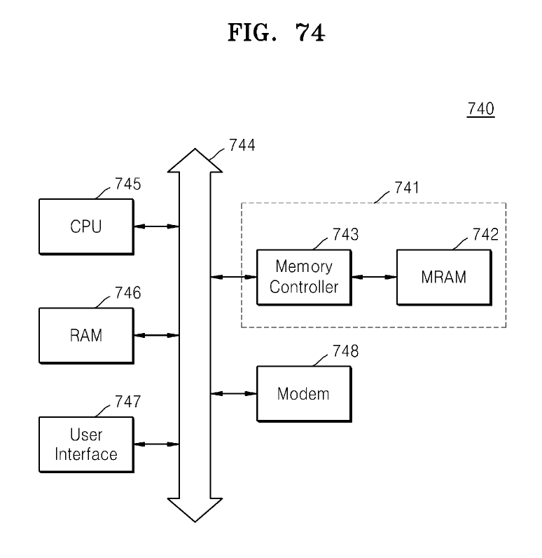

FIG. 74 is a block diagram illustrating a computer system 740 on which an MRAM is mounted, according to an exemplary embodiment.

Referring to FIG. 74, the computer system 740 may be mounted on a mobile device or a desktop computer. The computer system 740 may include an MRAM memory system 741, a CPU 745, a RAM 746, a user interface 747, and a modem 748 such as a baseband chipset, which are electrically connected to a system bus 744. The computer system 740 may further include an application chipset, a camera image processor (CIS), and an input/output device.

The user interface 747 may be an interface for transmitting data to a communication network or receiving data from the communication network. The user interface 747 may have a wired or wireless form, and may include an antenna or a wired/wireless transceiver. Data applied through the user interface 747 or the modem 748 or processed by the CPU 745 may be stored in the MRAM memory system 741.

The MRAM memory system 741 may include an MRAM 742 and a memory controller 743. Data processed by the CPU 745 or external data is stored in the MRAM 742. The MRAM 742 may include a memory region including an STT_MRAM cell, and an interface unit that provides various interface functions.

When the computer system 740 is a device that performs wireless communications, the computer system 740 may be used in a communication system such as code division multiple access (CDMA), global system for mobile communication (GSM), North American multiple access (NADC), or CDMA2000. The computer system 740 may be mounted on an information processing device such as a personal digital assistant (PDA), a portable computer, a web tablet, a digital camera, a portable media player (PMP), a mobile phone, a wireless phone, or a laptop computer.

Although a system includes a separate storage unit for storing a large amount of data such as a cache memory or a RAM having a high processing speed, these memories may be replaced by one MRAM system of the inventive concept. Accordingly, since a large amount of data may be rapidly stored in a memory device including an MRAM, a computer system may have a simple structure.

While the inventive concept has been particularly shown and described with reference to exemplary embodiments thereof, they are provided for the purposes of illustration and it will be understood by those of ordinary skill in the art that various modifications and equivalent other embodiments can be made from the inventive concept. Accordingly, the true technical scope of the inventive concept is defined by the technical spirit of the appended claims.

What is claimed is:

1. A magnetic random access memory (MRAM) comprising:
magnetic memory cells each of which varies between at least two states according to a magnetization direction; and
an interface circuit configured to input/output as a data input/output signal (referred to as a DQ signal) data read from or written to the magnetic memory cell in accordance with a rising edge and a falling edge of a clock signal,
wherein the interface circuit is configured to latch the DQ signal in response to a data strobe signal that is generated along with the DQ signal, wherein an edge of the clock signal occurs in a window center of the latched DQ signal.

2. The MRAM of claim 1, wherein the interface is configured to sample the DQ signal by using a differential data clock signal whose frequency is two times a frequency of the clock signal that samples a command and an address signal.

3. The MRAM of claim 1, wherein the interface circuit is configured to input/output a command packet, a write data packet, or a read data packet which is synchronized with the rising and falling edges of the clock signal as the DQ signal.

4. The MRAM of claim 1, wherein the interface circuit supports single-ended signaling that compares a voltage level of the DQ signal received through one channel with that of a reference voltage.

5. The MRAM of claim 4, wherein the channel supports a pseudo open drain (POD) interface that is pull-up terminated.

6. The MRAM of claim 1, wherein the interface circuit supports differential-ended signaling that inputs the DQ signal and an inverted DQ signal received through two channels.

7. The MRAM of claim 6, wherein each of the two channels supports POD interface that is pull-up terminated.

8. The MRAM of claim 7, wherein the two channels are connected to each other through a resistor and support low voltage differential signaling (LVDS), wherein the DQ signal and the inverted DQ signal have small swings.

9. The MRAM of claim 1, wherein the interface circuit receives the DQ signal through one channel, and the channel supports a multi-level signaling interface that converts a voltage corresponding to a plurality of bits of the DQ signal into a multi-level voltage signal.

10. The MRAM of claim 1, wherein the interface circuit is configured to receive a voltage corresponding to a plurality of bits of the DQ signal as a multi-level voltage signal pair through two channels that support multi-level signaling interface.

11. A magnetic random access memory (MRAM) comprising:
magnetic memory cells each of which varies between at least two states according to a magnetization direction;
a clock generator that generates a first internal clock signal having the same phase as that of a clock signal, a second internal clock signal whose phase is delayed by 90 degrees from that of the clock signal, a third internal clock signal that is obtained by inverting the first internal clock signal, and a fourth internal clock signal that is obtained by inverting the second internal clock signal; and
an interface circuit configured to input/output as a data input/output signal (referred to as a DQ signal) data read from or written to the magnetic memory cell in accordance with rising edges of the first through fourth internal clock signals,
wherein the interface circuit is configured to latch the DQ signal in response to a data strobe signal that is generated along with the DQ signal, and an edge of each of the first through fourth internal clock signals occurs in a window center of the latched DQ signal.

12. A magnetic random access memory (MRAM) comprising:
magnetic memory cells each of which varies between at least two states according to a magnetization direction;
a clock generator that generates a first internal clock signal whose frequency is two times that of a clock signal, a second internal clock signal whose phase is delayed by 90 degrees from that of the first internal clock signal, a third internal clock signal that is obtained by inverting the first internal clock signal, and a fourth internal clock signal that is obtained by inverting the second internal clock signal; and
an interface circuit configured to input/output as a data input/output signal (referred to as a DQ signal) data read from or written to the magnetic memory cell in accordance with rising edges of the first through fourth internal clock signals,
wherein the interface circuit is configured to latch the DQ signal in response to a data strobe signal that is generated along with the DQ signal, and an edge of each of the first through fourth clock signals occurs in a window center of the latched DQ signal.

13. A magnetic random access memory (MRAM) comprising:
magnetic memory cells each of which varies between at least two states according to a magnetization direction;
a delay-locked loop (DLL) configured to receive an external clock signal that synchronizes an operation of the MRAM, delay by a predetermined period of time the external clock signal by using delay elements, and generate an internal clock signal that is synchronized with the external clock signal; and
a data input/output buffer (referred to as a DQ buffer) configured to latch data read from or written to the magnetic memory cell in response to the internal clock signal.

14. The MRAM of claim 13, wherein the DLL is configured to operate such that the external clock signal is prevented from being received when the MRAM is in a power down mode.

15. The MRAM of claim 13, wherein the DLL is configured to generate a first internal clock signal whose frequency is the same as that of the external clock signal and generate a second internal clock signal whose frequency is two times that of the external clock signal,
wherein the first internal clock signal is for clocking the DQ buffer and the second internal clock signal is for clocking the data read from or written to the magnetic memory cell.

16. The MRAM of claim 13, wherein the DLL further comprises phase delay detectors that respectively receive a plurality of delayed clock signals output from the delay elements in response to the external clock signal,
wherein each of the phase delay detectors compares a phase of each of the delayed clock signals with a phase of a carry output terminal of the phase delay detector at a front end and outputs a comparison result to the carry output terminal of the corresponding phase delay detector,
wherein the phase delay detector is configured to output the delayed clock signal as the internal clock signal and disables the carry output terminal, when a phase of the external clock signal and the phase of the delayed clock signal are matched to each other.

17. The MRAM of claim 13, wherein the DLL comprises:
a phase detector configured to compare a phase of the external clock signal with a phase of a feedback clock signal;
a charge pump configured to generate a voltage control signal in response to a comparison result of the phase detector;
a loop filter configured to generate the voltage control signal by integrating a phase difference,
wherein each delay element receives as input the external clock signal, and outputs the internal clock signal in response to the voltage control signal; and
a compensation delay circuit that receives as input the internal clock signal, and outputs the feedback clock signal by compensating for a load on a line path through which the read data is transmitted.

18. A magnetic random access memory (MRAM) comprising:
magnetic memory cells each of which varies between at least two states according to a magnetization direction;
a data bus inverter configured to minimize bit switching between data words read from or written to the magnetic memory cell; and
a data input/output pad (referred to as a DQ pad) that transmits the data words to a data bus.

19. The MRAM of claim 18, wherein the data bus inverter is configured to perform the bit switching in order to minimize a number of logic low bits in a data pattern of the data words.

20. The MRAM of claim 18, wherein the data bus inverter is configured to perform the bit switching in order to minimize a change from a previous data pattern of the data words.

21. The MRAM of claim 18, wherein the MRAM indicates inversion information of the data words by using a data masking pin.

22. A magnetic random access memory (MRAM) comprising:
magnetic memory cells each of which varies between at least two states according to a magnetization direction;
a data driver configured to transmit/receive data read from or written to the magnetic memory cell to a data input/output terminal (referred to as a DQ terminal) through an external data bus; and
an on-die termination circuit configured to control a termination resistance of the DQ terminal in order to achieve impedance matching with the external data bus.

23. The MRAM of claim 22, further comprising:
a calibration terminal (referred to as a ZQ terminal) to which an external resistor is connected; and
calibration resistors that are connected to the ZQ terminal,
wherein the on-die termination circuit is configured to control the terminal resistance of the DQ terminal in response to calibration codes when a resistance value of each of the calibration resistors is the same as a resistance value of the external resistor.

24. The MRAM of claim 22, wherein the on-die termination circuit is configured to control the terminal resistance of the DQ terminal in response to a control pin provided from the outside of the MRAM.

25. The MRAM of claim 22, wherein the on-die termination circuit is configured to control the termination resistance of the DQ terminal in response to dynamic termination information applied from a mode register in the MRAM.

26. A method of operating a magnetic random access memory (MRAM) including magnetic memory cells each of which varies between at least two states according to a magnetization direction, the method comprising:
providing a clock signal;
inputting/outputting as a data input/output signal (referred to as a DQ signal) data read from or written to the magnetic memory cell in accordance with a rising edge and a falling edge of a clock signal;
generating a data strobe signal along with the DQ signal; and
latching the DQ signal in response to the data strobe signal, wherein an edge of the clock signal occurs in a window center of the latched DQ signal.

27. The method of claim 26, further comprising:
sampling the DQ signal by using a differential data clock signal whose frequency is two times a frequency of the clock signal that samples a command and an address signal.

28. The method of claim 26, further comprising:
inputting/outputting a command packet, a write data packet, or a read data packet which is synchronized with the rising and falling edges of the clock signal as the DQ signal.

29. The method of claim 26, further comprising:
single-ended signaling that compares a voltage level of the DQ signal received through one channel with that of a reference voltage.

30. A method of operating a magnetic random access memory (MRAM) including magnetic memory cells each of which varies between at least two states according to a magnetization direction, the method comprising:
generating a first internal clock signal whose frequency is two times that of a clock signal, a second internal clock signal whose phase is delayed by 90 degrees from that of the first internal clock signal, a third internal clock signal that is obtained by inverting the first internal clock signal, and a fourth internal clock signal that is obtained by inverting the second internal clock signal;
inputting/outputting as a data input/output signal (referred to as a DQ signal) data read from or written to the magnetic memory cell in accordance with rising edges of the first through fourth internal clock signals; and
latching the DQ signal in response to a data strobe signal that is generated along with the DQ signal, wherein an edge of each of the first through fourth clock signals occurs in a window center of the latched DQ signal.
